(19) United States
(12) Patent Application Publication
(10) Pub. No.: US 2025/0096801 A1
(43) Pub. Date: Mar. 20, 2025

(54) Characterizing Noisy Non-Clifford Gates Through Partial Pauli Twirling or Through Alternating Pauli Twirling

(71) Applicant: International Business Machines Corporation, Armonk, NY (US)

(72) Inventors: David LAYDEN, San Jose, CA (US); Bradley K MITCHELL, San Jose, CA (US); Andrew EDDINS, Washington, DC (US)

(21) Appl. No.: 18/468,473

(22) Filed: Sep. 15, 2023

(51) Int. Cl. H03K 17/92; B82Y 10/00; G06N 10/20; G06N 10/40; G06N 10/70

(52) U.S. Cl. CPC H03K 17/92; G06N 10/20; G06N 10/40; G06N 10/70; B82Y 10/00

(57) ABSTRACT

A system to characterize noise of a quantum gate can comprise a memory that stores, and a processor that executes, computer executable components that perform operations comprising generating a quantum circuit comprising one or more instances of a quantum gate of interest, and that generates the quantum circuit having each instance of the quantum gate of interest being bounded by a pair of Pauli gates, wherein each pair of Pauli gates comprises two of the same bounding Pauli gate, inserting, according to a determined probability, an initial Pauli gate, that is based on an initial quantum state of the quantum circuit, into the quantum circuit prior to the one or more instances, and, based on one or more parameters of a curve, to which an expectation value, resulting from a measurement outcome of execution of the quantum circuit, is fitted, generating an element characterizing the noise.

### TECHNICAL FIELD

The present disclosure generally relates to a processes to determine Pauli transfer matrix elements for a quantum channel, in particular where the quantum channel is and/or comprises a non-Clifford gate.

### BACKGROUND

In quantum computing systems execution of a quantum circuit can comprise the application of a series of quantum gates. Due to hardware and/or software aspects, some gates can be applied imperfectly, resulting in measurement outcomes being incorrect and/or having error attributed thereto. In one or more cases, error can be due to experimental imperfections such as miscalibration and/or undesired interactions between the quantum computer and the environment.

### SUMMARY

The following presents a summary to provide a basic understanding of one or more embodiments described herein. This summary is not intended to identify key or critical elements, and/or to delineate scope of particular embodiments or scope of claims. Its sole purpose is to present concepts in a simplified form as a prelude to the more detailed description that is presented later. In one or more embodiments, systems, computer-implemented methods, apparatuses and/or computer program products described herein can provide a process to characterize noise for a quantum channel that comprises a non-Clifford gate.

In accordance with an embodiment, a system can comprise a memory that stores computer executable components and a processor that executes the computer executable components stored in the memory. The computer executable components comprise a quantum circuit generation component that generates a quantum circuit comprising a series of one or more instances of a quantum gate of interest, wherein the quantum circuit generation component further generates the quantum circuit having each instance of the quantum gate of interest being bounded by a pair of Pauli gates, and wherein each pair of Pauli gates comprises two of the same bounding Pauli gate, a selection component that randomly selects, separately for each instance of the quantum gate of interest, the bounding Pauli gate to employ for each instance of the quantum gate of interest, an insertion component that inserts, according to a determined probability, an initial Pauli gate, that is based on an initial quantum state of the quantum circuit, into the quantum circuit prior to the series of one or more instances of the quantum gate of interest, and a finalization component that, based on one or more parameters of a curve, to which an expectation value, resulting from a measurement outcome of execution of the quantum circuit at a quantum system, is fitted, generates an element characterizing noise of the quantum gate of interest.

In accordance with another embodiment, a computer-implemented method can comprise generating, by a system comprising a processor, a quantum circuit comprising a series of one or more instances of a quantum gate of interest, and having each instance of the quantum gate of interest being bounded by a pair of Pauli gates, wherein each pair of Pauli gates comprises two of the same bounding Pauli gate, randomly selecting, by the system, separately for each instance of the quantum gate of interest, the bounding Pauli gate to employ for each instance of the quantum gate of interest, inserting, by the system, according to a determined probability, an initial Pauli gate, that is based on an initial quantum state of the quantum circuit, into the quantum circuit prior to the series of one or more instances of the quantum gate of interest, and, based on one or more parameters of a curve, to which an expectation value, resulting from a measurement outcome of execution of the quantum circuit at a quantum system, is fitted, generating, by the system, an element characterizing noise of the quantum gate of interest.

In accordance with still another embodiment, a computer program product, facilitating a process to characterize a noisy quantum gate, can comprise a computer readable storage medium having program instructions embodied therewith, the program instructions executable by a processor to cause the processor to generate, by the processor, a quantum circuit comprising a series of one or more instances of a quantum gate of interest, and having each instance of the quantum gate of interest being bounded by a pair of Pauli gates, wherein each pair of Pauli gates comprises two of the same bounding Pauli gate, randomly select, by the processor, separately for each instance of the quantum gate of interest, the bounding Pauli gate to employ for each instance of the quantum gate of interest, insert, by the processor, according to a determined probability, an initial Pauli gate, that is based on an initial quantum state of the quantum circuit, into the quantum circuit prior to the series of one or more instances of the quantum gate of interest, and, based on one or more parameters of a curve, to which an expectation value, resulting from a measurement outcome of execution of the quantum circuit at a quantum system, is fitted, generate, by the processor, an element characterizing noise of the quantum gate of interest.

A benefit of the system, computer-implemented method and/or computer program product can be accurate determination of Pauli transfer matrix elements corresponding to a quantum channel comprising a non-Clifford gate, such as an n-qubit non-Clifford gate. These Pauli transfer matrix elements can be employed to characterize the noisy non-Clifford gate, thus allowing for operation of the respective quantum channel.

Another benefit of the system, computer-implemented method and/or computer program product can be an ability to characterize non-Clifford gates, such as partial CNOT gates or partially-entangling R_{ZZ}(θ)=e^{-iθ/2 z⊗z} gates for arbitrary angles θ in a quantum circuit, through use of the Pauli transfer matrix elements for such non-Clifford gates being determinable through use of the one or more embodiments described herein. These gates can be employed in a variety of applications, such as simulating quantum dynamics. These gates can be realized on a quantum computer with the realization having higher fidelity than realization of 2-qubit Clifford gates, such as CNOTs, because such non-Clifford gates are shorter than CNOTs. Accordingly, the system, computer-implemented method and/or computer program product can provide for use of previously inaccessible, native gates.

Still another benefit of the system, computer-implemented method and/or computer program product can be an ability to generate one or more elements characterizing noise of the quantum gate of interest, from which one or more Pauli transfer matrix (PTM) elements of a Pauli transfer matrix of the quantum gate of interest. That is, based on one or more parameters of the curve to which the expectation values are fitted, the one or more embodiments described herein can then yield combinations of Pauli transfer matrix elements for the noisy gate of interest. An amplitude a of the curve is the only fit parameter that depends on state preparation and measurement (SPAM) noise, and this parameter gets discarded due to non-use in equations representing the Pauli transfer matrix (PTM) elements for the noisy quantum gate of interest, which are instead based on one or more of the decay rate (r), frequency (ω) and/or phase (δ). Accordingly, the PTM element results are not biased by SPAM noise.

### DESCRIPTION OF THE DRAWINGS

FIG. 1 illustrates a block diagram of an example, non-limiting system that can provide a process to characterize a noisy non-Clifford quantum gate, in accordance with one or more embodiments described herein.

FIG. 2 illustrates a block diagram of another example, non-limiting system that can provide a process to characterize a noisy non-Clifford quantum gate, in accordance with one or more embodiments described herein.

FIG. 3 provides an illustration of processes that can be performed by the non-limiting system of FIG. 2, in accordance with one or more embodiments described herein.

FIG. 4 provides an illustration of a quantum circuit that can be executed by a quantum system during the processes of FIG. 3 relative to the non-limiting system of FIG. 2, in accordance with one or more embodiments described herein.

FIG. 5 illustrates a table of 8 pairs of Paulis that can be employed in the processes of FIG. 3 or FIG. 13 relative to the non-limiting systems of FIGS. 1, 2, 11 and 12, in accordance with one or more embodiments described herein.

FIG. 6 illustrates a block diagram of a quantum system that can be employed in connection with the non-limiting systems of any of FIGS. 1, 2, 11 and 12, in accordance with one or more embodiments described herein.

FIG. 7 illustrates a flow diagram of one or more outcomes/results and/or elements employed by the non-limiting systems of any of FIGS. 1, 2, 11 and 12, in accordance with one or more embodiments described herein.

FIG. 8 illustrates a flow diagram of one or more processes that can be performed by the non-limiting system of FIG. 2, in accordance with one or more embodiments described herein.

FIG. 9 illustrates a continuation of the flow diagram of FIG. 8 of one or more processes that can be performed by the non-limiting system of FIG. 2, in accordance with one or more embodiments described herein.

FIG. 10 illustrates a continuation of the flow diagram of FIG. 9 of one or more processes that can be performed by the non-limiting system of FIG. 2, in accordance with one or more embodiments described herein.

FIG. 11 illustrates a block diagram of an example, non-limiting system that can provide a process to characterize a noisy non-Clifford quantum gate, in accordance with one or more embodiments described herein.

FIG. 12 illustrates a block diagram of another example, non-limiting system that can provide a process to characterize a noisy non-Clifford quantum gate, in accordance with one or more embodiments described herein.

FIG. 13 provides an illustration of processes that can be performed by the non-limiting system of FIG. 12, in accordance with one or more embodiments described herein.

FIG. 14 provides an illustration of a quantum circuit that can be executed by a quantum system during the processes of FIG. 13 relative to the non-limiting system of FIG. 12, in accordance with one or more embodiments described herein.

FIG. 15 illustrates a flow diagram of one or more processes that can be performed by the non-limiting system of FIG. 12, in accordance with one or more embodiments described herein.

FIG. 16 illustrates a continuation of the flow diagram of FIG. 15 of one or more processes that can be performed by the non-limiting system of FIG. 12, in accordance with one or more embodiments described herein.

FIG. 17 illustrates a continuation of the flow diagram of FIG. 16 of one or more processes that can be performed by the non-limiting system of FIG. 12, in accordance with one or more embodiments described herein.

FIG. 18 illustrates a flow diagram of one or more processes that can be performed by the non-limiting systems of FIG. 2 or 12, in accordance with one or more embodiments described herein.

FIG. 19 illustrates a continuation of the flow diagram of FIG. 18 of one or more processes that can be performed by the non-limiting systems of FIG. 2 or 12, in accordance with one or more embodiments described herein.

FIG. 20 illustrates a continuation of the flow diagram of FIG. 19 of one or more processes that can be performed by the non-limiting systems of FIG. 2 or 12, in accordance with one or more embodiments described herein.

FIG. 21 illustrates a block diagram of example, non-limiting, computer environment in accordance with one or more embodiments described herein.

### DETAILED DESCRIPTION

The following detailed description is merely illustrative and is not intended to limit embodiments and/or application or utilization of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

In practice, many quantum gates cannot be applied perfectly on quantum computers. That is, quantum computation can involve a set of three steps: (I) initializing qubits in some desired state, (II) applying a series of quantum logic gates, each of which typically acts on one or more qubits, and (II) measuring the qubits. Generally, none of these steps can be implemented perfectly on current quantum computers. Rather, each step is therefore said to be noisy, and the imperfections are often called “noise” or “errors.” Some of the most damaging errors (i.e., those which can most severely limit performance) in current quantum computers can be those exhibited on the two-qubit gates.

As used herein, noise can refer to noise attributable to the discrete and/or probabilistic natures of quantum interactions. Noise in two-qubit gates can be a limiting source of error in existing quantum computers.

Error mitigation techniques can be employed to reduce the impact of these two-qubit gate errors. To use these techniques, noisy gates are to first be characterized accurately and in detail through carefully designed learning procedures. For these learning procedures to be accurate, they are to be able to distinguish noise in the relevant two-qubit gates from noise in steps I and III above the noise in the steps I to III above are collectively called state preparation and measurement, or “SPAM”, noise/errors.

Existing error mitigation techniques, and corresponding learning procedures, apply only to noisy Clifford gates (e.g., CNOTs). However, many current quantum computers can also implement non-Clifford two-qubit gates like

$${R}_{ZZ} ( θ ) = exp ( - \frac{i θ}{2} Z ⊗ Z ) ,$$

for arbitrary angles θ, with relatively low noise compared to two-qubit Clifford gates. These non-Clifford gates can arise in many quantum algorithms, e.g., for simulating quantum dynamics. Moreover, error mitigation typically performs better with lower gate noise. There is therefore a strong incentive to develop learning procedures and error mitigation techniques for these non-Clifford two-qubit gates.

Accordingly, to account for one or more of these deficiencies of existing quantum algorithm operation frameworks, one or more embodiments described herein can provide for a learning procedure to characterize different parameters of the noise exhibited by noisy Clifford and non-Clifford gates. That is, the one or more embodiments described herein can provide for characterizing noisy gates by providing for determination of quantum Pauli matrix transfer elements for a quantum gate (e.g., a non-Clifford gate), which can then be employed for error mitigation purposes of other purposes relative to the quantum gate.

As used herein, the term “Clifford gate” refers to a quantum gate described by unitary matrix U with the property that if P is an n-qubit Pauli, then either UPU^{†} or −UPU^{†} is also an n-qubit Pauli. Clifford gates include all Pauli gates as well as other gates, such as, but not limited to CNOT and CZ gates.

Differently, a “non-Clifford gate” refers to a quantum gate that is not a Clifford gate. Non-Clifford gates include, but are not limited to quantum gates such as R_{Z}(θ)=e^{-iθ/2 z} (for arbitrary angles θ) or partially-entangling R_{ZZ}(θ)=e^{-iθ/2 Z⊗Z} gates for arbitrary angles θ.

Generally, the one or more embodiments described herein can employ processes than can be referred to in two parts. Part 1 can comprise a set of random quantum circuits to be run on a noisy quantum computer, and Part 2 can be a classical data processing step to extract information about the noisy R_{ZZ}(θ) gate of interest from the results of Part 1. These two parts are designed so that SPAM errors in Part 1 do not bias the results from Part 2.

Part 1: Preparation of quantum circuits can start by preparing a simple initial state that depends on the noisy gate parameters desired to be learned for the noisy R_{ZZ}(θ) gate of interest. (The whole procedure of Parts 1 and 2 can be repeated with different initial states to learn different parameters.) The quantum circuits comprise d layers of gates for a depth d, where each layer consists of a noisy R_{ZZ}(θ) gate between Pauli gates selected with a degree of randomness from a selected set of Pauli gates. After execution of the quantum circuits, qubits employed in the execution can be measured using partial readout twirling or alternating readout twirling in a measurement basis that depends on the initial state.

These quantum circuits can be run repeatedly for the same value of d to gather statistics, and the measurement results can be averaged to yield a Pauli expectation value f(d) corresponding to the measurement basis.

The above elements of Part 1 can then repeated for different values of depth d (e.g., for different numbers of layers), producing a series of measured Pauli expectation values {f(d)}.

Part 2: This series of measured Pauli expectation values {f(d)} can be fit to a decaying exponential f(d)=a r^{d} or to a decaying sinusoid f(d)=a r^{d} cos(ωd−δ), using a standard curve-fitting algorithm for either approach. The decay rate (r), frequency (ω) and/or phase (δ) resulting from this fit can then yield combinations of Pauli transfer matrix elements for the noisy gate of interest. The amplitude a of the respective curve is the only fit parameter that depends on state preparation and measurement (SPAM) noise, and this parameter gets discarded due to non-use in equations representing the Pauli transfer matrix (PTM) elements for the noisy quantum gate of interest, which are instead based on one or more of the decay rate (r), frequency (ω) and/or phase (δ). Accordingly, the PTM element results are not biased by SPAM noise.

As used herein, the term “twirling” can refer to performing random quantum gates before and after a fixed noisy gate of interest. “Partial twirling” refers to performing only a random quantum gate before a fixed noisy gate of interest, where the randomness is limited to a selection of gates. “Alternating twirling” refers to twirling that alternates between sets of commuting and anti-commuting Paulis for different layers d of a quantum circuit.

As used herein, the term “data” can comprise metadata.

As used herein, the terms “entity,” “requesting entity,” and “user entity” can refer to a machine, device, component, hardware, software, smart device, party, organization, individual and/or human.

One or more embodiments are now described with reference to the drawings, where like referenced numerals are used to refer to like elements throughout. In the following description, for purposes of explanation, numerous specific details are set forth in order to provide a more thorough understanding of the one or more embodiments. It is evident in various cases, however, that the one or more embodiments can be practiced without these specific details.

Further, it should be appreciated that the embodiments depicted in one or more figures described herein are for illustration only, and as such, the architecture of embodiments is not limited to the systems, devices and/or components depicted therein, nor to any particular order, connection and/or coupling of systems, devices and/or components depicted therein.

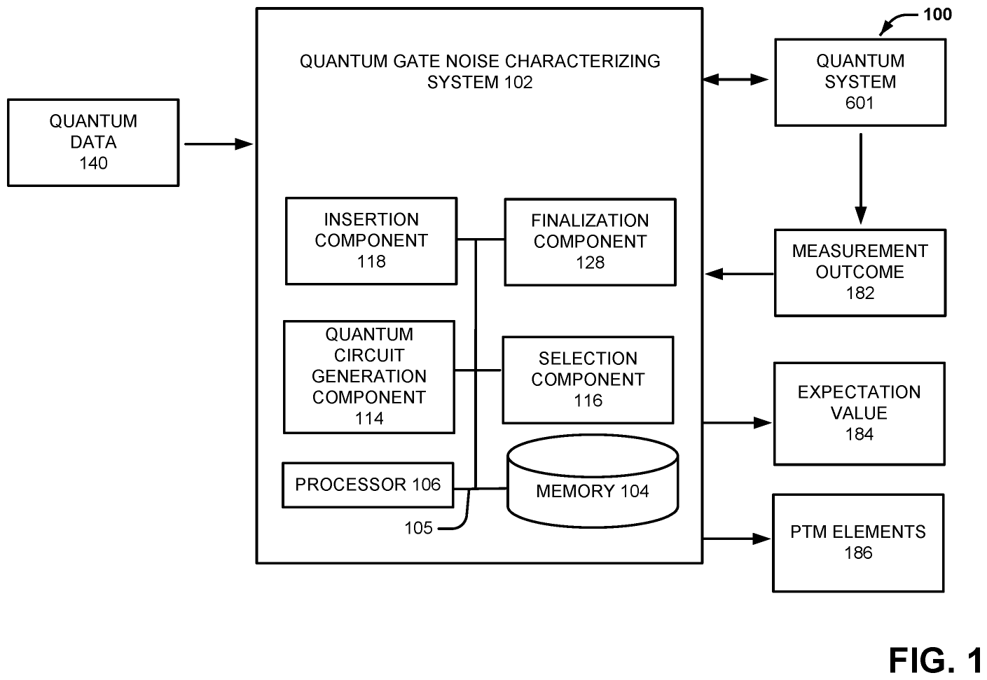

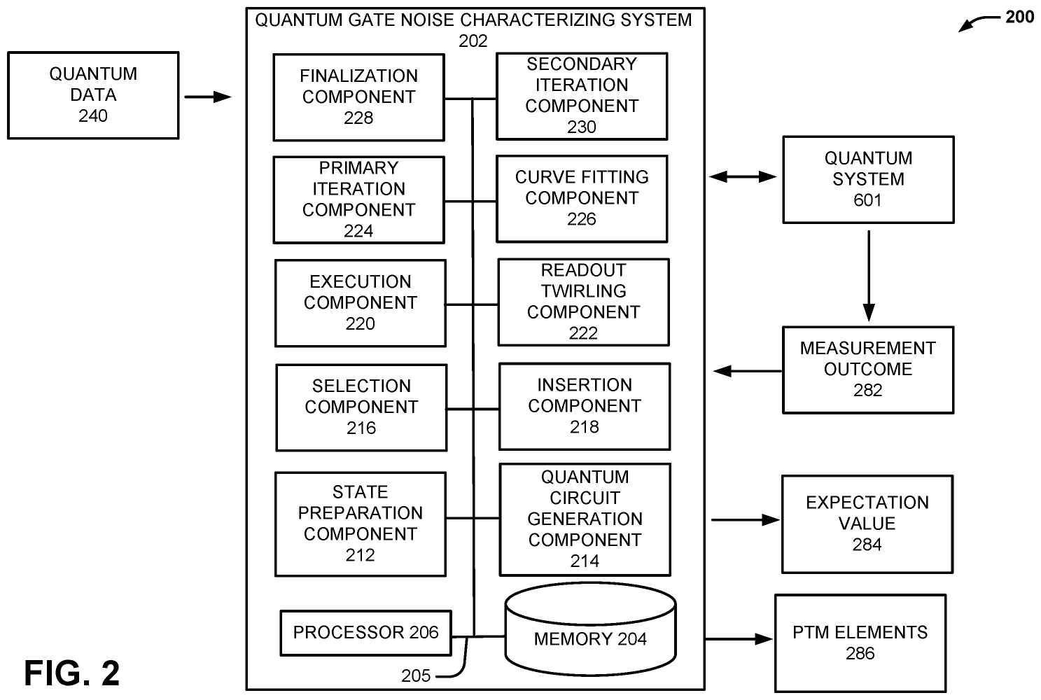

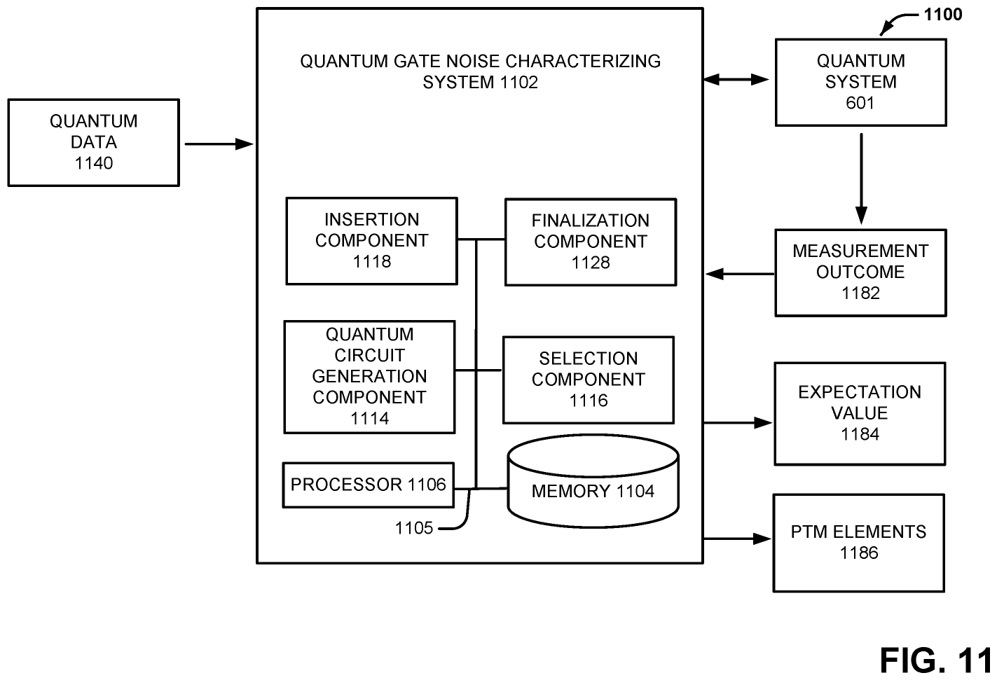

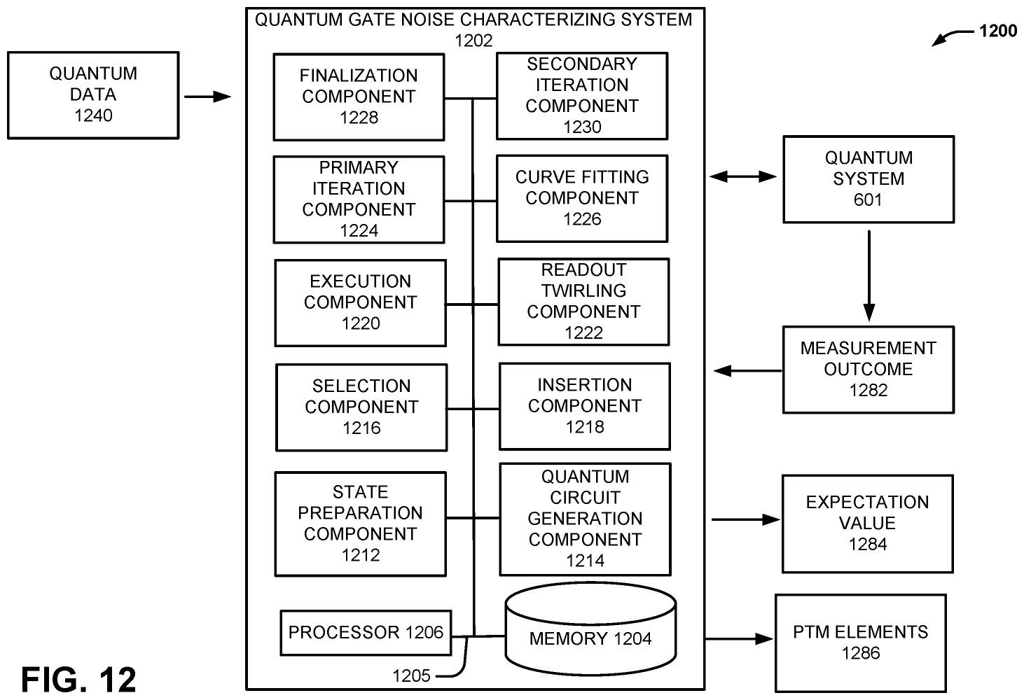

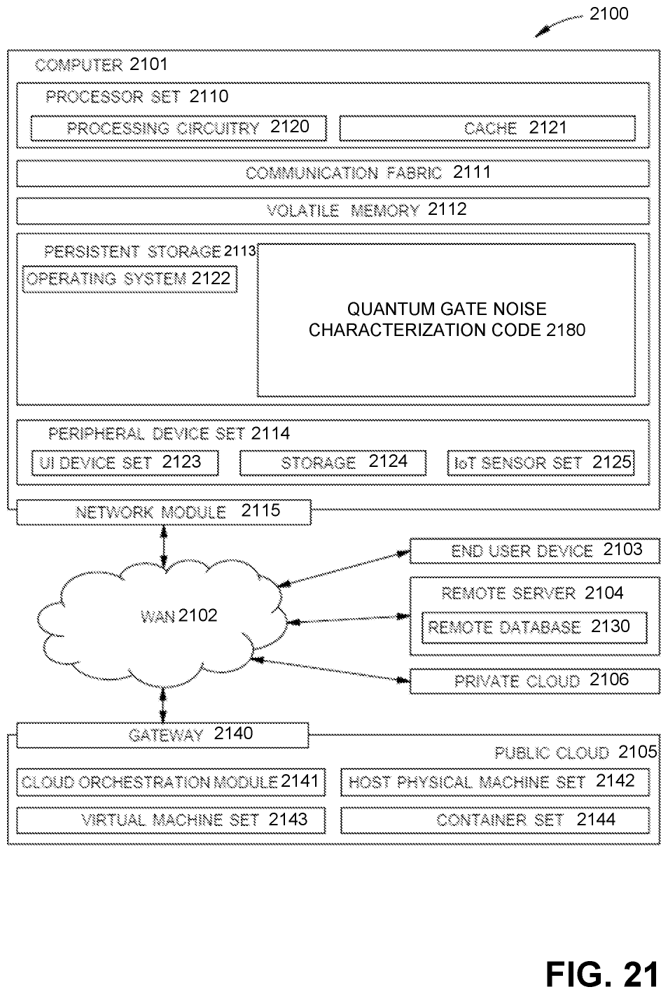

For example, in one or more embodiments, the non-limiting systems 100 and/or 200 illustrated at FIGS. 1 and 2, and/or systems thereof, can further comprise one or more computer and/or computing-based elements described herein with reference to a computing environment, such as the computing environment 2100 illustrated at FIG. 21. For another example, in one or more embodiments, the non-limiting systems 1100 and/or 1200 illustrated at FIGS. 11 and 12, and/or systems thereof, can further comprise one or more computer and/or computing-based elements described herein with reference to a computing environment, such as the computing environment 2100 illustrated at FIG. 21. In one or more described embodiments, computer and/or computing-based elements can be used in connection with implementing one or more of the systems, devices, components and/or computer-implemented operations shown and/or described in connection with FIGS. 1, 2, 11 and/or 12 and/or with one or more other figures described herein.

### Description—Characterizing Noisy Non-Clifford Gates Through Partial Pauli Twirling

Turning now in particular to one or more figures, and first to FIG. 1, the figure illustrates a block diagram of an example, non-limiting system 100 that can facilitate a process to shape and execute a quantum circuit to obtain noise characterization parameters for the quantum circuit therefrom, in accordance with one or more embodiments described herein. That is, the non-limiting system 100 can facilitate the process to shape and direct execution of a quantum circuit to obtain noise characterization parameters for the quantum circuit therefrom, in combination with employment of a quantum system 601.

The non-limiting system 100 can comprise a quantum gate noise characterizing system 102. It is noted that the quantum gate noise characterizing system 102 is only briefly detailed to provide but a lead-in to a more complex and/or more expansive quantum gate noise characterizing system 202 as illustrated at FIG. 2. That is, further detail regarding processes that can be performed by one or more embodiments described herein will be provided below relative to the non-limiting system 200 of FIG. 2.

Still referring to FIG. 1, the quantum gate noise characterizing system 102 can comprise at least a memory 104, bus 105, processor 106, quantum circuit generation component 114, selection component 116, insertion component 118 and finalization component 128. Using these components and the quantum system 601, the quantum gate noise characterizing system 102 can shape a quantum circuit comprising a quantum gate, execute the quantum circuit at the quantum system 601, direct performance of readout twirling by the quantum system 601, perform curve fitting and employ parameters from the curve fitting to generate one or more parameters that can be employed to characterize noise of the quantum gate. The one or more parameters can be employed to generate one or more Pauli transfer matrix (PTM) elements for the quantum gate while dropping state preparation and measurement (SPAM) noise from this generation of the one or more PTM elements.

For example, the quantum gate noise characterizing system 102 can obtain a set of quantum data 140, which can comprise a quantum gate (e.g., referred here to as a quantum gate of interest). It can be desired to learn noise characterizing parameters for the quantum gate of interest to enable use of the quantum gate in an error mitigated process and/or for one or more other processes. For example, in one or more embodiments, it can be the case that the quantum gate cannot be executed without undesirable error, and/or cannot be executed as quickly as desired, such as due to hardware imperfections, including unwanted interactions with the environment or with other qubits, or due to imperfectly calibrated control operations. In one or more embodiments, the quantum gate can be an n-qubit non-Clifford gate.

For this reason, the quantum circuit generation component 114 can generate a quantum circuit for the purpose of being executed at a quantum system (e.g., quantum system 601) in a manner that can result in a measurement outcome 182 being employed to generate an expectation value 184, where the expectation value 184 can be employed to generate one or more noise characterizing elements such as and/or allowing for subsequent generation of one or more PTM elements 186 for the quantum gate of interest.

That is, the quantum circuit generation component 114 can generate a quantum circuit comprising a series of one or more instances of a quantum gate of interest. The quantum circuit generation component 114 further generates the quantum circuit having each instance of the quantum gate of interest being bounded by a pair of Pauli gates, and wherein each pair of Pauli gates comprises two of the same bounding Pauli gate. Part of this process can comprise the quantum circuit generation component determining a depth level for the quantum circuit, wherein the depth level d corresponds directly to the number of instances of the quantum gate of interest provided in series in the quantum circuit.

In parallel, subsequent to, and/or prior to the process of the quantum generation component 114, the selection component 116 can determine the bounding Pauli gate to employ for each instance of the quantum gate of interest. That is, the selection component 116 can randomly select, separately for each different instance of the quantum gate of interest, the bounding Pauli gate from a selected set of Pauli gates. This set of Pauli gates can comprise only Pauli gates that commute with a rotation axis of the quantum gate of interest.

Also in parallel, subsequent to, and/or prior to the process of the quantum generation component 114, the insertion component 118 can insert, into the quantum circuit, an initial Pauli gate prior to the series of one or more instances of the quantum gate of interest. The insertion component 118 can insert the initial Pauli gate based on a determined probability. For example, the insertion component 118 can employ a 50% probability of insertion (and thus a 50% probability of non-insertion). The insertion component 118 can randomly select the initial Pauli gate from a second set of Pauli gates that anti-commute with the rotation axis of the quantum gate of interest.

Based on execution of the completed quantum circuit at a quantum system (e.g., the quantum system 601), a measurement outcome 182 can be obtained. Based on one or more parameters of a curve, to which an expectation value 184, resulting from the measurement outcome 182, is fitted, the finalization component 128 can generate an element characterizing noise of the quantum gate of interest. This element can be and/or can be employed to subsequently generate, by the finalization component 128, one or more PTM elements 186 for the PTM of the quantum gate of interest. That is, the finalization component 128 can provide for generation of the one or more PTM elements 186 based on the measurement outcome 182.

As used herein, a “Pauli transfer matrix” can be employed to describe a quantum channel C, such as the G channel. Any quantum channel C can be fully described by 4ⁿ×4ⁿ Pauli transfer matrix elements cᵢⱼ; =Tr[PᵢC(Pⱼ)]/2ⁿ, where i and j are are indices (e.g., describing height and width of the Pauli transfer matrix from row 1 to row (4ⁿ×4ⁿ) and column 1 to column (4ⁿ×4ⁿ)). Thus, each i and j as a pair is used to label a particular element from the Pauli transfer matrix elements cᵢⱼ. That is, there are 4ⁿ×4ⁿ pairs of i and j, where each pair of i and j represents two n-qubit Pauli gates of a set of n-qubit Pauli gates represented by the Pauli transfer matrix. For example, a quantum channel C that is a 2-qubit quantum channel can be fully described by 4²×4² Pauli transfer matrix elements (i.e., 256 different Pauli transfer matrix elements) which represent 4²×4² Pauli gates (e.g., 256 different Pauli gates).

It is noted that the quantum circuit generation component 114, selection component 116, insertion component 118 and finalization component 128 each can operate at a classical system of and/or comprising the quantum gate noise characterizing system 102.

In general, the non-limiting system 100 can employ any suitable method of communication (e.g., electronic, communicative, internet, infrared, fiber, etc.) to provide communication between the quantum gate noise characterizing system 102 and the quantum system 601.

Turning next to FIG. 2, a non-limiting system 200 is illustrated that can comprise a quantum gate noise characterizing system 202. Repetitive description of like elements and/or processes employed in respective embodiments is omitted for sake of brevity. Description relative to an embodiment of FIG. 1 can be applicable to an embodiment of FIG. 2. Likewise, description relative to an embodiment of FIG. 2 can be applicable to an embodiment of FIG. 1.

Generally, the quantum gate noise characterizing system 202 can shape a quantum circuit comprising a quantum gat of interest, execute the quantum circuit at the quantum system 601, and based on the execution, generate one or more elements characterizing noise of the quantum gate.

The quantum gate of interest (e.g., quantum gate of interest 401) can be one for which noise characterization is desired. That is, in one or more embodiments, it can be the case that the quantum gate of interest 401 (also herein referred to as the quantum gate 401) cannot be executed without undesirable error, and/or cannot be executed as quickly as desired, such as due to hardware imperfections, including unwanted interactions with the environment or with other qubits, or due to imperfectly calibrated control operations. In one or more embodiments, the quantum gate of interest 401 can be an n-qubit non-Clifford gate.

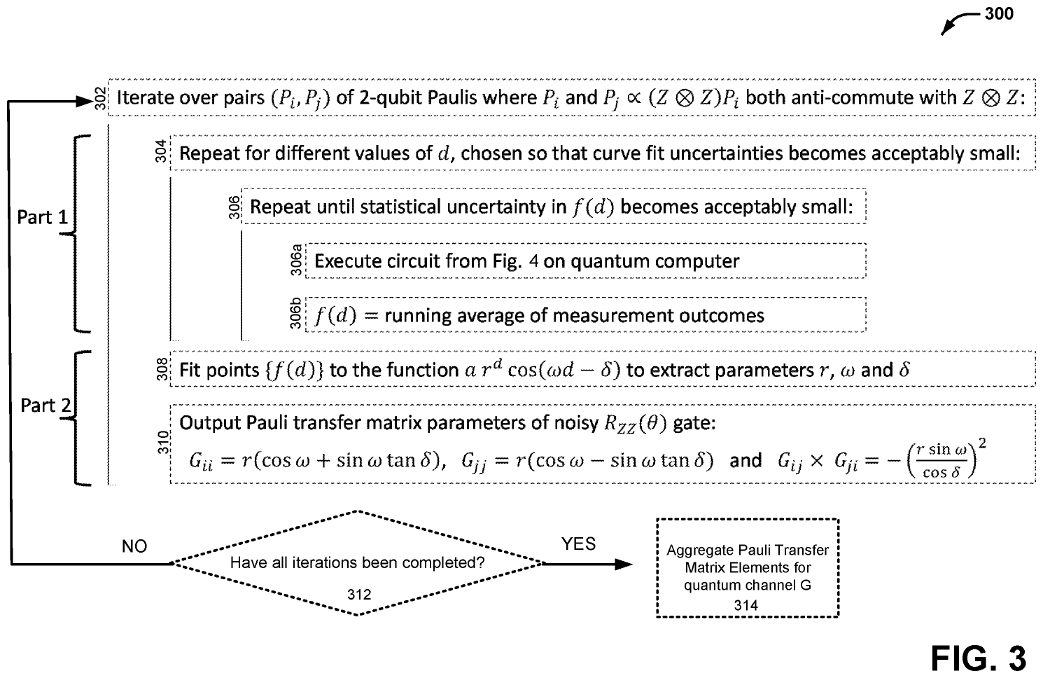

The quantum gate of interest 401 can have the form R_{AB}(θ)=exp(−iθ/2 A⊗B), for any single-qubit Paulis A, B∈{X, Y, Z} and an arbitrary angle θ. That is, A can independently be any of X, Y or Z, and B can independently be any of X, Y or Z. In connection with the quantum gate noise characterizing system 202 of FIG. 2, the example employed at FIGS. 3, 4 and 5 employs a quantum gate of interest 401 being an R_{ZZ}(θ), gate, wherein A=B=Z. However, such quantum gate of interest can take any other form of any other values X, Y or Z for A and B.

That is, X, Y and Z denote Pauli σₓ, σ_{y} and σ_{z} matrices, respectively. An n-qubit Pauli is an n-fold tensor product of I, X, Y and Z of which there are 4ⁿ. Any two n-qubit Paulis P₁ and P₂ either commute [P₁, P₂]=P₁P₂−P₂P₁=0 or anti-commute {P₁, P₂}=P₁P₂+P₂P₁=0. Pauli gates can be employed to describe quantum gates (an n-qubit Pauli means single-qubit Pauli gates are applied to n qubits in parallel), or measurement operators (whose possible outcomes are ±1).

Relative to an initial quantum state of Z⊗Z for the quantum gate of interest 401, the following rules key 511 can be employed to transform each of the processes herein, as will be described below. That is, this rules key 511 employs Z⊗Z as a starting basis for changing the rotation axis of the processes herein from of Z⊗Z to another of A⊗B, based on the rotation axis of any different gate of interest 401 having the form R_{AB}(θ)=exp(−i θ/2 A⊗B), for any single-qubit Paulis A, B∈{X, Y, Z} and an arbitrary angle θ.

### Rules Key 511:

For example, If A=X, all the Paulis on the first qubit should be changed as X→Y, Y→Z and Z→X. (“I” does not change.)

If A=Y, all the Paulis on the first qubit should be changed as X→Z, Y→X and Z→Y. (“I” does not change.)

If A=Z, all the Paulis on the first qubit stay as they are.

The term “Paulis on the first qubit” refers to the first “letter” in a 2-qubit Pauli such as XY.

The second qubit works similarly:

If B=X, all the Paulis on the second qubit should be changed as X→Y, Y→Z and Z→X. (“I” does not change.)

If B=Y, all the Paulis on the second qubit should be changed as X→Z, Y→X and Z→Y. (“I” does not change.)

If B=Z, all the Paulis on the second qubit stay as they are.

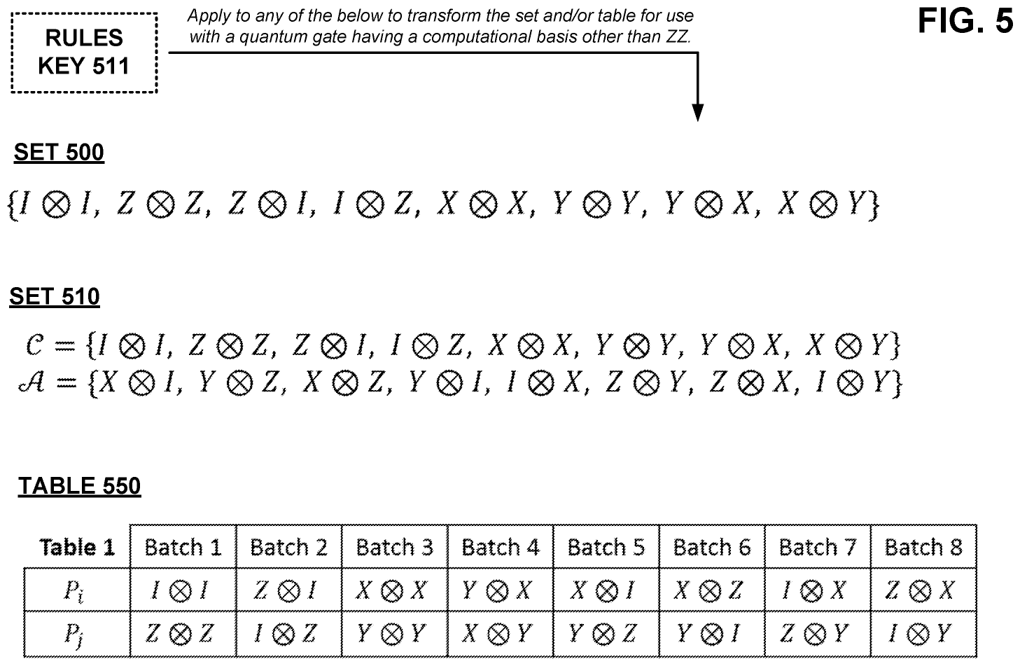

It is noted that the rules key 511 applies to set 500, set 510 and table 550 of FIG. 5.

For example, Batch 8 at Table 550 has Pᵢ=ZX and Pj=IY, but if used with respect to a quantum gate of interest R_{XY}(θ), where A=X and B=Y, Batch 8 at Table 550 would be transformed to Pᵢ=XZ and Pⱼ=IX.

**End of Rules Key 511**

Turning again more particularly to the quantum gate noise characterizing system 202, one or more communications between one or more components of the non-limiting system 200 can be provided by wired and/or wireless means including, but not limited to, employing a cellular network, a wide area network (WAN) (e.g., the Internet), and/or a local area network (LAN). Suitable wired or wireless technologies for supporting the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra-mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an advanced and/or adaptive network technology (ANT), an ultra-wideband (UWB) standard protocol and/or other proprietary and/or non-proprietary communication protocols.

The quantum gate noise characterizing system 202 can be associated with, such as accessible via, a cloud computing environment.

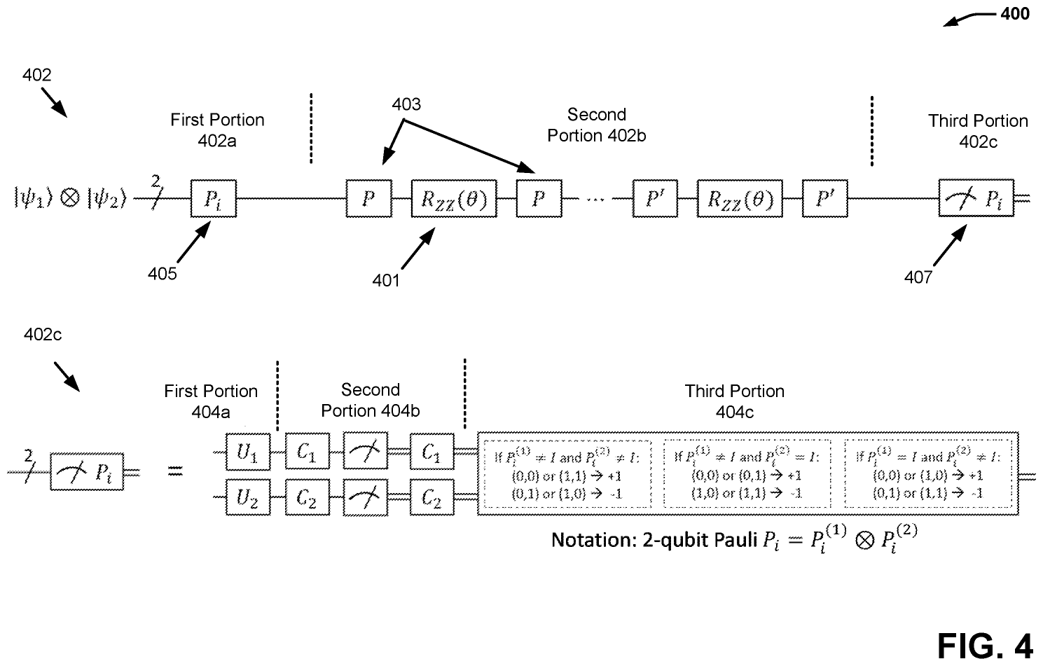

The quantum gate noise characterizing system 202 can comprise a plurality of components. The components can comprise a memory 204, processor 206, bus 205, state preparation component 212, quantum circuit generation component 214, selection component 216, insertion component 218, execution component 220, readout twirling component 222, primary iteration component 224, curve fitting component 226, finalization component 228 and secondary iteration component 230. Using these components, the quantum gate noise characterizing system 202 can perform the shaping of a quantum circuit 402 (FIG. 4) (e.g., comprising the quantum gate 401), execution of the quantum circuit 402 (FIG. 4), and subsequent processing of one or more measurement outcomes 282 resulting from the execution to obtain one or more elements characterizing noise of the quantum gate 401. As noted above, the subsequent processing steps can allow for dropping of SPAM noise/error, thus allowing for characterization of noise solely attributable to the quantum gate 401.

Discussion next turns briefly to the processor 206, memory 204 and bus 205 of the quantum gate noise characterizing system 202. For example, in one or more embodiments, the quantum gate noise characterizing system 202 can comprise the processor 206 (e.g., computer processing unit, microprocessor, classical processor, quantum processor and/or like processor). In one or more embodiments, a component associated with quantum gate noise characterizing system 202, as described herein with or without reference to the one or more figures of the one or more embodiments, can comprise one or more computer and/or machine readable, writable and/or executable components and/or instructions that can be executed by processor 206 to provide performance of one or more processes defined by such component and/or instruction. In one or more embodiments, the processor 206 can comprise the state preparation component 212, quantum circuit generation component 214, selection component 216, insertion component 218, execution component 220, readout twirling component 222, primary iteration component 224, curve fitting component 226, finalization component 228 and secondary iteration component 230.

In one or more embodiments, the quantum gate noise characterizing system 202 can comprise the computer-readable memory 204 that can be operably connected to the processor 206. The memory 204 can store computer-executable instructions that, upon execution by the processor 206, can cause the processor 206 and/or one or more other components of the quantum gate noise characterizing system 202 (e.g., state preparation component 212, quantum circuit generation component 214, selection component 216, insertion component 218, execution component 220, readout twirling component 222, primary iteration component 224, curve fitting component 226, finalization component 228 and secondary iteration component 230) to perform one or more actions. In one or more embodiments, the memory 204 can store computer-executable components (e.g., state preparation component 212, quantum circuit generation component 214, selection component 216, insertion component 218, execution component 220, readout twirling component 222, primary iteration component 224, curve fitting component 226, finalization component 228 and secondary iteration component 230).

The quantum gate noise characterizing system 202 and/or a component thereof as described herein, can be communicatively, electrically, operatively, optically and/or otherwise coupled to one another via a bus 205. Bus 205 can comprise one or more of a memory bus, memory controller, peripheral bus, external bus, local bus, quantum bus and/or another type of bus that can employ one or more bus architectures. One or more of these examples of bus 205 can be employed.

In one or more embodiments, the quantum gate noise characterizing system 202 can be coupled (e.g., communicatively, electrically, operatively, optically and/or like function) to one or more external systems (e.g., a non-illustrated electrical output production system, one or more output targets and/or an output target controller), sources and/or devices (e.g., classical and/or quantum computing devices, communication devices and/or like devices), such as via a network. In one or more embodiments, one or more of the components of the quantum gate noise characterizing system 202 and/or of the non-limiting system 200 can reside in the cloud, and/or can reside locally in a local computing environment (e.g., at a specified location).

In general, the non-limiting system 200 can employ any suitable method of communication (e.g., electronic, communicative, internet, infrared, fiber, etc.) to provide communication between the quantum gate noise characterizing system 202 and the quantum system 601.

In addition to the processor 206 and/or memory 204 described above, the quantum gate noise characterizing system 202 can comprise one or more computer and/or machine readable, writable and/or executable components and/or instructions that, when executed by processor 206, can provide performance of one or more operations defined by such component and/or instruction.

Discussion next turns to the additional components of the quantum gate noise characterizing system 202 (e.g., state preparation component 212, quantum circuit generation component 214, selection component 216, insertion component 218, execution component 220, readout twirling component 222, primary iteration component 224, curve fitting component 226, finalization component 228 and secondary iteration component 230).

Turning first to the state preparation component 212, the state preparation component 212 can generally identify, search, receive, transfer and/or otherwise obtain input data from one or more databases, online resources, entities and/or information caches. The input data can comprise a set of quantum data 240. This input data can be made available to and/or transmitted to the other components of the quantum gate noise characterizing system 202.

The set of quantum data 240 can be obtained from classical data, quantum simulation, quantum transducers, etc. The set of quantum data 240 can result from and/or be based on output of the quantum system 601 or of another quantum system. In one or more embodiments, classical data can be transformed into quantum data, such as one or more quantum states, such as by the state preparation component 212.

The state preparation component 212 further can determine a quantum state for the quantum circuit 402 based on the rotation axis of the quantum gate 401 (e.g., relative to step 302 of the schematic 300 of FIG. 3). For example, where the quantum gate 401 has the form R_{AB}(θ), the quantum state can be an AB state. In the running example employed in FIGS. 3-5, the quantum gate 401 is an R_{ZZ}(θ) gate, and thus the state preparation component 212 can determine the quantum state for the respective quantum circuit 402 to be a ZZ state. For example, a first qubit (relative to an 2-qubit gate) can be prepared in a state |ψ₁ [symbol] , where |ψ₁ [symbol] =|0 [symbol] if Pᵢ¹=I, or where |ψ₁ [symbol] is an eigenstate of Pᵢ⁽¹⁾ with eigenvalue +1 otherwise. A second qubit can be prepared in state |ψ₁ [symbol] , similarly defined for Pᵢ⁽²⁾ in place of Pᵢ⁽¹⁾. Relative to different computational bases and/or [symbol] different quantum gates R_{AB}(θ), the rules key 511 provided above can be employed. It is noted that the notation Pᵢ=Pᵢ⁽¹⁾⊗Pᵢ⁽²⁾ is employed when needed to refer to the single-qubit Paulis Pᵢ⁽¹⁾ and Pᵢ⁽²⁾ that make up a two-qubit Pauli Pᵢ.

Turning now to FIGS. 3 and 4, along with FIG. 2, based on the quantum gate 401 and quantum state, the quantum circuit generation component 214 can generate the quantum circuit 402 aided by the selection component 216 and the insertion component 218, to satisfy Part 1 of the process schematic 300 of FIG. 3 that can be performed by the quantum gate noise characterizing system 202.

The quantum circuit generation component 214 can generate a quantum circuit 402 comprising a series of one or more instances of a quantum gate of interest 401. The quantum circuit generation component 214 further generates the quantum circuit 402 having each instance of the quantum gate of interest 401 being bounded by a pair of Pauli gates 403. Each pair of Pauli gates 403 comprises two of the same bounding Pauli gate (e.g., P, P′, P″, etc.).

Part of this process can comprise the quantum circuit generation component 214 determining a depth level d for the quantum circuit 402, where the depth level d corresponds directly to the number of instances of the quantum gate of interest 401 provided in series in the quantum circuit 402. That is, a depth level d of 2 corresponds to two instances of the quantum gate of interest 401 being provided in series in the quantum circuit 402 by the quantum circuit generation component 214. The depth level d can be selected randomly by the quantum circuit generation component 214, and/or historical data can be employed, such as historical data defining historical depth level use relative to a depth level sufficient to allow for a desirably low statistical uncertainty of a measurement outcome 282 from operation of one or more quantum circuits.

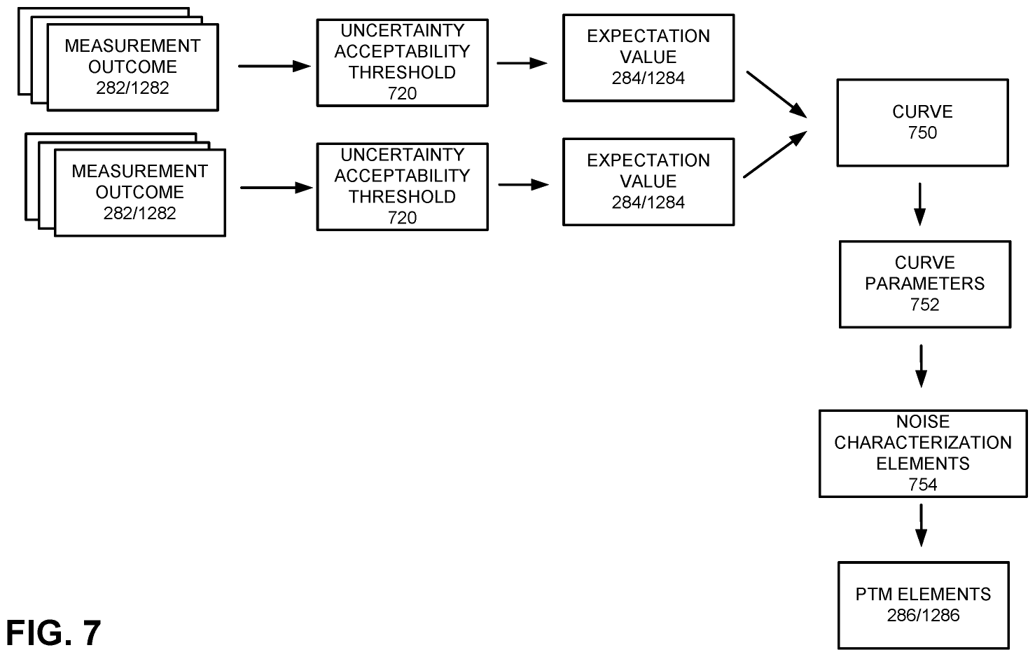

It is noted that in one or more embodiments, d can be selected such that a sufficiently large portion of a curve 750 (FIG. 7), to which expectation values 284 are later fitted, is visible to enable reliable curve fitting. In one or more embodiments, d can be selected adaptively based on error in fitting of expectation values 284 from previous values of d.

Briefly, it is noted that other depth levels d are to be employed during a second set of iterations of further quantum circuits, as will be explained below relative to the secondary iteration component 230 and one or more processes performed thereby.

In parallel, subsequent to, and/or prior to the one or more processes of the quantum circuit generation component 214, the selection component 216 can determine the bounding Pauli gate to employ for each instance of the quantum gate of interest 401. That is, the selection component 216 can randomly select, separately for each different instance of the quantum gate of interest 401, the bounding Pauli gate from a selected set of Pauli gates. For example, at the illustrated quantum circuit 402 of FIG. 4, the bounding Pauli gate P is selected by the selection component 216 separately from the bounding Pauli gate P′. Generally, the set of Pauli gates employed can comprise only Pauli gates that commute with a rotation axis of the quantum gate of interest. Turning to FIG. 5, in the running case of the quantum gate of interest 401 being an R_{ZZ}(θ) gate, the set of Pauli gates that commute with ZZ are provided at set 500. Relative to different computational bases and/or different quantum gates R_{AB}(θ), the rules key 511 provided above can be employed.

For each different selection of a bounding Pauli gate, the selection is performed randomly, based on a uniform probability distribution, from the set of Pauli gates that commute with the rotation axis of the quantum gate of interest 401. That is, each Pauli gate of the set 500 has associated therewith an equal probability of being selected by the selection component 216.

It is noted that any selection of a Pauli gate can be performed at least partially in parallel with any other selection of a Pauli gate, and need not necessarily be performed in any order of the series of instances.

Accordingly, the one or more processes performed by the quantum circuit generation component 214 and the selection component 216 can allow for generation of the second portion 402b of the quantum circuit 402.

Also in parallel, subsequent to, and/or prior to the one or more processes of the quantum circuit generation component 214 and/or selection component 216, the insertion component 218 can insert, into the quantum circuit 402, an initial Pauli gate Pᵢ prior to the series of one or more instances of the quantum gate of interest. The insertion component 218 can insert the initial Pauli gate Pᵢ(of the first portion 402a of the quantum circuit 402) based on a determined probability. For example, the insertion component 218 can employ a 50% probability of insertion (and thus a 50% probability of non-insertion).

The insertion component 218 can select the initial Pauli gate Pᵢ from a second set of Pauli gates that anti-commute with the rotation axis of the quantum gate of interest. For example, relative to the quantum gate 401 being an R_{ZZ}(θ) gate, the set of Pauli gates that anti-commute with ZZ are provided for Pᵢ(e.g., at row Pᵢ) at batches 5-8 of Table 550.

It is noted that batches 1-4 for both Pᵢ and Pⱼ commute with ZZ and that batches 5-8 for Pⱼ anti-commute with ZZ. Relative to different computational bases and/or different quantum gates R_{AB}(θ), the rules key 511 provided above can be employed.

More particularly, the initial Pauli gate Pᵢ selected is the initial Pauli gate Pᵢ corresponding to the quantum state determined by the state preparation component 212. That is, the quantum state is selected by the state preparation component 212 as one which is a +1 eigenstate of Pᵢ. Accordingly the initial Pauli gate Pᵢ is not randomly selected, but is selected as the one from batch 5, 6, 7 or 8 that corresponds to the quantum state selected by the state preparation component 212.

In connection with selection and insertion of the initial Pauli gate Pᵢ, the insertion component 218 can insert the third portion 402c into the quantum circuit 402, and/or can provide information corresponding to the quantum circuit 402 to the execution component 220, to perform readout twirling of the Pauli gate Pᵢ subsequent to execution of the first and second portions 402a and 402b of the quantum circuit 402. For sake of completeness, the initial gate Pᵢ of the first portion 402a and the Pauli gate Pᵢ of the third portion 402c for which readout twirling is to be performed, are the same Pauli gate Pᵢ for each different quantum circuit 402 employed by the quantum gate noise characterizing system 202.

Accordingly, the one or more processes performed by the quantum circuit generation component 214, the selection component 216 and the insertion component 218 can allow for generation of a complete quantum circuit 402 by the quantum gate noise characterizing system 202.

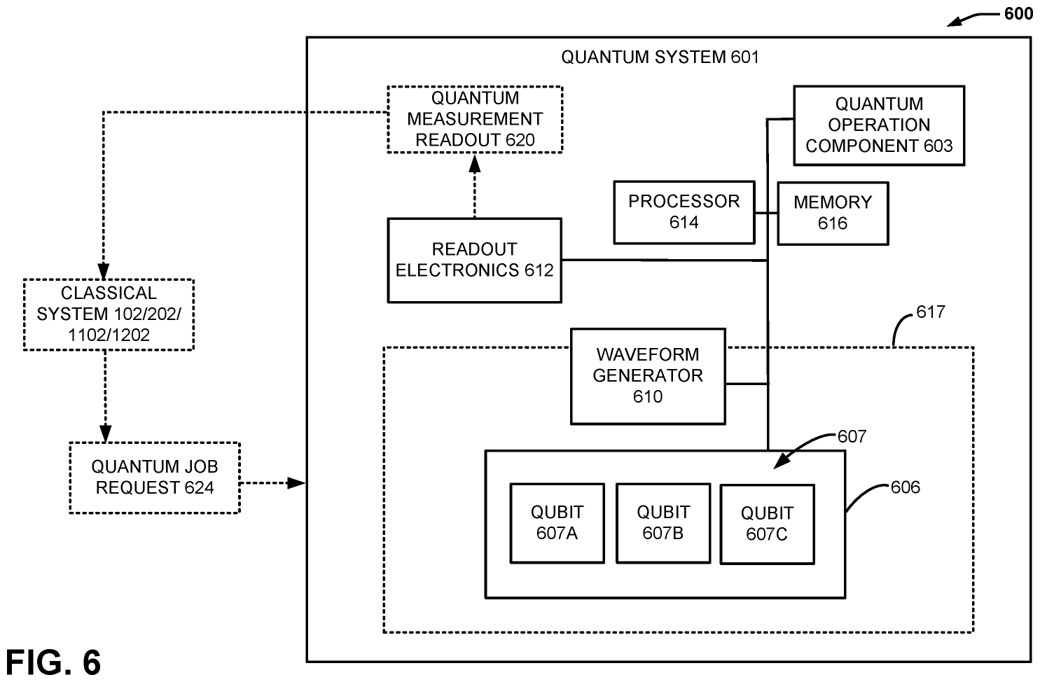

Using the completed quantum circuit 402, the execution component 220 can execute the completed quantum circuit 402 at a quantum processor 606, such as of the quantum system 601 by directing the quantum system 601 to execute the quantum circuit 402. For example, the execution component 220 can send a quantum job request 624 (FIG. 6) to the quantum system 601 or can make the quantum job request 624 available to the quantum system 601 for the quantum system 601 to obtain the quantum job request 624.

In connection with the one or more processes performed by the execution component 220, the readout twirling component 222 can provide further information relative to the third portion 402c of the quantum circuit 402 (e.g., defining the third portion 402c) and/or can direct performance of readout twirling of the initial Pauli gate Pᵢ by the quantum system 601 (e.g., at the quantum processor 606).

It is noted that each of the state preparation component 212, quantum circuit generation component 214, selection component 216, insertion component 218, execution component 220, readout twirling component 222 can operate at a classical system of and/or comprising the quantum gate noise characterizing system 202.

Accordingly, as a result of execution of the quantum circuit 402 at the quantum system 601, comprising execution of the first and second portions 402a and 402b of the quantum circuit 402 and subsequent readout twirling of the initial Pauli gate Pᵢ relative to the third portion 402c of the quantum circuit 402, a measurement outcome 282 (e.g., quantum measurement readout 620) can be obtained, such as by the primary iteration component 224 of the quantum gate noise characterizing system 202, from the quantum system 601.

Next, prior to discussion of use of the measurement outcome 282 of each iteration of the quantum circuit 402, and prior to the discussion of determination of a resultant expectation value 284 and subsequent processing of the measurement outcome 282, discussion first turns to the execution of the quantum circuit 402 at the quantum system 601 and to the readout twirling performed by the quantum system 601 relative to the quantum circuit 402. That is, the operation of the quantum system 601 can allow for the output of the quantum measurement readouts 282 and thus allow for the determination of an individual expectation value f(d) from each iteration.

Turning to FIG. 6, one or more embodiments described herein can include one or more devices, systems and/or apparatuses that can provide a process to generate one or more waveforms for a quantum-based operation (e.g., using a quantum device), such as for operating one or more qubits of a quantum device. Accordingly, at FIG. 6, illustrated is a block diagram of an example, non-limiting system 600 that can at least partially facilitate such a process. While referring here to one or more processes, facilitations and/or uses of the non-limiting system 600, description provided herein, both above and below, also can be relevant to one or more other non-limiting systems described herein, such as the non-limiting systems 100 and/or 200.

As illustrated at FIG. 6, the non-limiting system 600 can comprise a quantum system 601 that can be employed with or separate from the classical systems 102/202.

Generally, the quantum system 601 (e.g., quantum computer system, superconducting quantum computer system and/or the like) can employ quantum algorithms and/or quantum circuitry, including computing components and/or devices, to perform quantum operations and/or functions on input data to produce results that can be output to an entity. The quantum circuitry can comprise quantum bits (qubits), such as multi-bit qubits, physical circuit level components, high level components and/or functions. The quantum circuitry can comprise physical pulses that can be structured (e.g., arranged and/or designed) to perform desired quantum functions and/or computations on data (e.g., input data and/or intermediate data derived from input data) to produce one or more quantum results as an output. The quantum results, e.g., quantum measurement readout 620, can be responsive to the quantum job request 624 and associated input data and can be based at least in part on the input data, quantum functions and/or quantum computations.

In one or more embodiments, the quantum system 601 can comprise components, such as a quantum operation component 603, a quantum processor 606, pulse component 610 (e.g., a waveform generator) and/or a readout electronics 612 (e.g., readout component). In one or more other embodiments, the readout electronics 612 can be comprised at least partially by the classical system 102/202 and/or be external to the quantum system 601. The quantum processor 606 can comprise one or more, such as plural, qubits 607. Individual qubits 607A, 607B and 607C, for example, can be fixed frequency and/or single junction qubits, such as transmon qubits.

In one or more embodiments, a memory 616 and/or processor 614 can be associated with the quantum operation component 603, where suitable. The processor 614 can be any suitable processor. The processor 614 can generate one or more instructions for controlling the one or more processes of the quantum operation component 603.

The quantum operation component 603 can obtain (e.g., download, receive, search for and/or the like) a quantum job request 624 requesting execution of one or more quantum programs and/or a physical qubit layout. The quantum job request 624 can be provided in any suitable format, such as a text format, binary format and/or another suitable format. In one or more embodiments, the quantum job request 624 can be obtained by a component other than of the quantum system 601, such as a by a component of the classical systems 102/202.

The quantum operation component 603 can determine mapping of one or more quantum logic circuits for executing a quantum program. In one or more embodiments, the quantum operation component 603 and/or quantum processor 606 can direct the waveform generator 610 to generate one or more pulses, tones, waveforms and/or the like to affect one or more qubits 607, such as in response to a quantum job request 624.

The waveform generator 610 can generally cause the quantum processor 606 to perform one or more quantum processes, calculations and/or measurements by creating a suitable electro-magnetic signal. For example, the waveform generator 610 can operate one or more qubit effectors, such as qubit oscillators, harmonic oscillators, pulse generators and/or the like to cause one or more pulses to stimulate and/or manipulate the state(s) of the one or more qubits 607 comprised by the quantum system 601.

The quantum processor 606 and a portion or all of the waveform generator 610 can be contained in a cryogenic environment, such as generated by a cryogenic environment 617, such as effected by a dilution refrigerator. Indeed, a signal can be generated by the waveform generator 610 to affect one or more of the plurality of qubits 607. Where the plurality of qubits 607 are superconducting qubits, cryogenic temperatures, such as about 4K or lower, can be employed for function of these physical qubits. Accordingly, one or more elements of the readout electronics 612 also can be constructed to perform at such cryogenic temperatures.

The readout electronics 612, or at least a portion thereof, can be contained in the cryogenic environment 617, such as for reading a state, frequency and/or other characteristic of qubit, excited, decaying or otherwise.

It is noted that the aforementioned description(s) refer(s) to the operation of a single set of instructions run on a single qubit. However, scaling can be achieved. For example, instructions can be calculated, transmitted, employed and/or otherwise used relative to one or more qubits (e.g., non-neighbor qubits) in parallel with one another, one or more quantum circuits in parallel with one another, and/or one or more qubit mappings in parallel with one another.

In connection with the execution of the quantum circuit 402 by the quantum processor 606 of the quantum system 601, the quantum processor 606, such as directed by the quantum operation component 603, can direct performance of readout twirling of the initial Pauli gate Pᵢ based on the prior direction by the readout twirling component 222.

For example, for completeness, direction turns briefly to the detailed illustration of the portion 402c of the quantum circuit 402 provided at FIG. 4.

For readout twirling, the quantum systems 601 and/or the readout twirling component 222 can first select C₁ and C₂ independently (e.g., first portion 404a and second portion 404b) and uniformly at random from {I, X} in each repetition, where X on a classical register denotes a NOT gate. It is noted that a change of basis can be performed depending on a rotation axis of the quantum gate of interest 401 and on a rotation axis of the quantum system 601. That is, for an 2-qubit preparation relative to the quantum gate R_{ZZ}(θ), the quantum system 601 can apply a gate U₁ to qubit 1 that rotates eigenstates of Pᵢ⁽¹⁾ into corresponding eigenstates of Z. If Pᵢ⁽¹⁾=I use U₁=I. Likewise, apply U₂ to qubit 2, similarly defined for Pᵢ⁽²⁾ in place of Pᵢ⁽¹⁾.

To conduct the subsequent measuring of n qubits using readout twirling, the quantum system 601 can, for each qubit, apply an X gate with 50% probability, then measure the qubit, and if an X gate had been applied, also apply a classical NOT gate to the resulting bit.

Based on an outcome of the readout twirling of the n qubits, the measurement outcome 282 can be determined based on the rules set forth at third portion 404c at FIG. 4. (e.g., as +1 or −1). That is, measuring Pᵢ yields an outcome of +1 if the quantum state is found to be an eigenvector of Pᵢ with eigenvalue +1, or an outcome of −1 if it is found to be an eigenvector of Pᵢ with eigenvalue −1. This measurement of Pᵢ can be performed by measuring the qubits individually and processing the resulting bits. The processing step depends on whether Pᵢ comprises an I on any qubit as this determines its eigenvectors. Again, relative to a different quantum gate R_{AB}(θ), the rules key 511 discussed above can be employed.

As a result, a measurement outcome 282 (e.g., quantum measurement readout 620) output by the readout electronics 612 can be based on execution of portions 402a and 402b of the quantum circuit 402 and on subsequent readout twirling performed relative to the portion 402c of the quantum circuit 402.

Turning back to FIGS. 2 to 4, and also now to FIG. 7, description of one or more processes performed post-quantum execution by the quantum gate noise characterizing system 202 (e.g., by the curve fitting component 226, finalization component 228, primary iteration component 224, secondary iteration component 230 and state preparation component 212) are now described.

Generally, based on execution of the completed quantum circuit at a quantum system (e.g., the quantum system 601), a measurement outcome 182 can be obtained. The finalization component 228 can employ the measurement outcome 282 to generate an expectation value 284 (f(d)), one or more noise characterizing elements 754 and/or one or more Pauli transfer matrix (PTM) elements 286. The expectation value is generated by taking the running average of the +1 measurement outcomes until the statistical fluctuations become acceptably small, in other words, the fraction of outcomes equal to +1 minus the fraction of outcomes equal to −1. Such expectation values are computed for different circuit depths d, then fit to an appropriate curve. The resulting fit parameters are then processed to give one or more PTM elements.

That is, based on one or more parameters of a curve 750, to which an expectation value 284, resulting from the measurement outcome 282, is fitted, the finalization component 228 can generate an element characterizing noise of the quantum gate of interest. This element can be and/or can be employed to subsequently generate, by the finalization component 228, one or more PTM elements 286 for the PTM of the quantum gate of interest. That is, the finalization component 228 can provide for generation of the one or more PTM elements 286 based on the measurement outcome 282.

In connection with the above general description of post-quantum circuit execution, direction turns first to FIGS. 3 and 7, and to primary iterations, secondary iterations and tertiary iterations of the one or more processes performed by the quantum gate noise characterizing system 202. These various iterations can be performed based on direction by the primary iteration component 224, secondary iteration component 230 and state preparation component 212, respectively.

For example, primary iterations of the quantum gate noise characterizing (QGNC) system 202 can comprise employing step 306 to repeat the above-described processes until statistical uncertainty in a final expectation value 284 (f(d)) obtained from aggregation (e.g., averaging) of a plurality of expectation values 284 (e.g., generated by the finalization component 228 from respective measurement outcomes 282) becomes acceptably small.

More particularly, the primary iteration component 224 can direct the quantum circuit generation component 214, selection component 216, insertion component 218, execution component 220, readout twirling component 222 and finalization component 228 to perform their respective operations for one or more additional quantum circuits 402 having a series of a same number of one or more instances of the quantum gate of interest (e.g., a same d) as the quantum circuit 402.

These one or more primary iterations can result in output (e.g., from steps 306a) of a plurality of measurement outcomes 282 and resulting expectation values 284 for a same d. It is noted that for each one or more additional quantum circuits 402, the processes performed by the selection component 216 and insertion component 218 include re-selecting the Pauli gates P, P′, etc. and Pᵢ for each different one of the one or more additional quantum circuits 402.

The number of primary iterations directed by the primary iteration component 224 can be driven by averaging of the expectation values 284, at any selected frequency (e.g., after each expectation value 284 is output for a running average, after more than one expectation values 284 are output, based on the dynamically changing statistical uncertainty in an averaged f(d), etc.) and determination (e.g., by the finalization component 228) of a statistical uncertainty in the averaged f(d). That is, the finalization component 228 can determine whether the statistical uncertainty in the averaged expectation value 284 satisfies (e.g., meets and/or exceeds) a selected threshold, such as an uncertainty acceptability threshold 720. The threshold 720 can be determined by the finalization component 228, another component of the QGNC system 202 and/or by an administrating entity associated with the QGNC system 202.

As a result of these one or more primary iterations, the finalization component 228 can average the resulting set of expectation values 284, determine that the threshold 720 is satisfied, and output a final resultant expectation value 284 (e.g., step 306b) relative to a single depth d.

The curve fitting component 226 can fit the resultant expectation value 284 to a curve 750 and/or such fitting can be performed when one or more resultant expectation values 284 from one or more secondary iterations are performed (e.g., step 308). The curve 750 can be a decaying sinusoidal curve having the function α r^{d} cos(ωd−δ), having amplitude α, decay rate r, frequency ω, phase δ and depth d. That is, an oscillating, exponentially decaying shape would be formed, visually, when the points f(d) (final expectation values 284 from each value of d) are all plotted against d.

It is noted that any suitable curve-fitting algorithm can be employed. An initial guess for the free parameters of amplitude α, decay rate r, frequency ω and phase δ that can be employed can be α=r=1, ω=θ and δ=0, which are ideal fit values that would be theoretically obtained in the absence of noise.

The one or more secondary iterations can be directed by the secondary iteration component 230 for different values of d (e.g., step 304), but for the same quantum state of the quantum circuit previously determined (e.g., relative to the same batch of Table 550). That is, the secondary iteration component 230 can direct the quantum circuit generation component 214, selection component 216, insertion component 218, execution component 220, readout twirling component 222, finalization component 228 and primary iteration component 224 to perform their respective operations for one or more further quantum circuits 402 each having a series of a second same number of one or more instances of the quantum gate of interest as the quantum circuit, where the second same number (e.g., d) is different than the same number (e.g., the d of a prior set of one or more primary iterations).

As such, a set of one or more primary iterations can be directed for each one or more secondary iterations directed. That is, for each different value of d, a resultant expectation value 284 can be determined.

As a result, these plural expectation values 284 can be fit, by the curve fitting component 226, to the same curve 750.

The number of secondary iterations directed by the secondary iteration component 230 can be driven by whether enough expectation values 284 are fit to the curve 750 to fully define the curve 750 (e.g., step 308). That is, “fully defined” can be determined based on a respective statistical uncertainty associated with one or more curve parameters 752 (e.g., decay rate, frequency and/or phase) defined by the curve 750, such as based on whether a respective uncertainty acceptability threshold has been satisfied. If not yest satisfied, and/or if the curve 750 is not fully defined to one or more selected specifications, additional secondary iterations can be directed by the secondary iteration component 230.

As a result of definition of the curve 750, from performance of plural secondary iterations, the one or more curve parameters 752 can be determined, thus resulting in generation of one or more Pauli transfer matrix (PTM) elements 286 for the quantum gate of interest 401, where the one or more PTM elements 286 are those elements corresponding to the same quantum state identified above by the state preparation component 212, prior to any one or more sets of primary iterations being performed. For example, these one or more PTM elements 286 can be a gᵢᵢ, gⱼⱼ, gᵢⱼ and/or gᵢⱼ relative to a quantum channel G (e.g., relative to a quantum gate of interest G).

As used herein, the term “quantum channel” can describe all possible physical operation on a quantum system, which can comprise at least one quantum computer. Mathematically, a quantum channel C can be a completely positive, trace-preserving linear function. The quantum channel C can take a density matrix p as input and return another density matrix ρ′=C(p), through operation of a quantum processor. The quantum channel C can describe a unitary operation (e.g., a quantum gate) or any non-unitary operation, such as an imperfect version of a gate that can be performed in available hardware of an available quantum system (e.g., available quantum processor).

For example, using the decay rate r, frequency a and/or phase δ from the function α r^{d} cos(ωd−δ), the finalization component 228 can determine that the one or more PTM elements 286 can be a gᵢᵢ, gⱼⱼ, gᵢⱼ and/or gᵢⱼ based on Equations 1, 2 and 3, provided below (e.g., step 310).

$${g}_{ii} = r ( cos ω + sin ωtanδ ) . \qquad Equation 1$$

$${g}_{jj} = r ( cos ω - sin ωtanδ ) . \qquad Equation 2$$

$${g}_{ij} \times {g}_{ji} = - {( \frac{r sin ω}{cos δ} )}^{2} . \qquad Equation 3$$

It is noted that amplitude a is the only fit parameter that depends on SPAM noise, and this parameter gets discarded (e.g., not employed by any of Equations 1-3). As such, the PTM element results are not biased by SPAM noise.

As referred to herein, one or more of the noise characterization elements gᵢᵢ, gᵢⱼ and (gᵢⱼ×gᵢⱼ) (754) can also be a PTM element 286 (e.g., the elements gᵢᵢ, gⱼⱼ). Alternatively, one or more of the PTM elements 286 can be generated (e.g., interpolated) based on one or more noise characterization elements 754 (e.g., where the elements gᵢⱼ, gᵢᵢ can be determined based on (gᵢⱼ×gᵢⱼ).

One possible way to resolve the ambiguity in gᵢⱼ and gⱼᵢ is to simply assume that |gᵢⱼ|=|gⱼᵢ|. Another possibility is to complement the one or more processes described herein with a different process, e.g., that of quantum process tomography, the sole purpose of which can be to isolate Pauli transfer matrix elements gᵢⱼ and gⱼᵢ.

To generate one or more different PTM elements 286 (e.g., different values for gᵢᵢ, gⱼⱼ, gᵢⱼ and/or gᵢⱼ) for one or more different quantum states (e.g., for different ones of the batches 5 to 8 of Table 550), and still relative to the same quantum gate of interest 401, one or more tertiary iterations can be performed, as directed by the state preparation component 212.

For example, the state preparation component 212 can select a different quantum state that anti-commutes with the rotation axis of the quantum gate of interest 401 (e.g., a different one of the batches 5 to 8 of Table 550). It is noted that a tertiary iteration, comprising a set of secondary iterations, which each in turn comprise a set of primary iterations, is performed generally only once per relative quantum state (e.g., here, four quantum states anti-commute with the rotation axis of the quantum gate of interest 401).

Put another way, iteration by way of different tertiary operations is by way of iteration over pairs (Pᵢ, Pⱼ) of 2-qubit Paulis where Pᵢ and Pⱼ∝(Z⊗Z)Pᵢ both anti-commute with Z⊗Z, where the quantum gate 401 is an R_{ZZ}(θ) gate.

Accordingly, the state preparation component 212 can determine (e.g., at step 312) whether an additional tertiary operation is to be directed based on the one or more quantum states already employed at step 302. Then, as a result of further performance of the QGNC system 202 and quantum system 601, the PTM for the quantum gate of interest 401 can be further defined (e.g., at step 314), thus further characterizing noise of the quantum gate of interest 401 without characterization of SPAM noise related to operation of the quantum gate of interest 401.

Finally, the one or more embodiments described herein can be limited to output of PTM elements 286 where the Pauli transfer matrix elements {gᵢᵢ, gᵢⱼ, gⱼᵢ, gⱼⱼ} satisfy 4gᵢⱼgⱼᵢ+(gᵢᵢ−ggⱼⱼ)²<0. This mathematical condition is what leads to the oscillations in f(d) that underlie the curve-fitting. If these oscillations are observed in f(d), then the condition above is met. If these oscillations are not observed in f(d), then the condition above is not met. Whether or not the condition is met depends on the nature of the R_{AB}(θ) gate noise and on the angle θ. For example, the condition can be met for noiseless gates 4gᵢⱼgⱼᵢ+(gᵢᵢ−gⱼⱼ)²=−4 sin(θ)², which satisfies the condition for all angles θ besides the trivial ones of θ=0 and π.

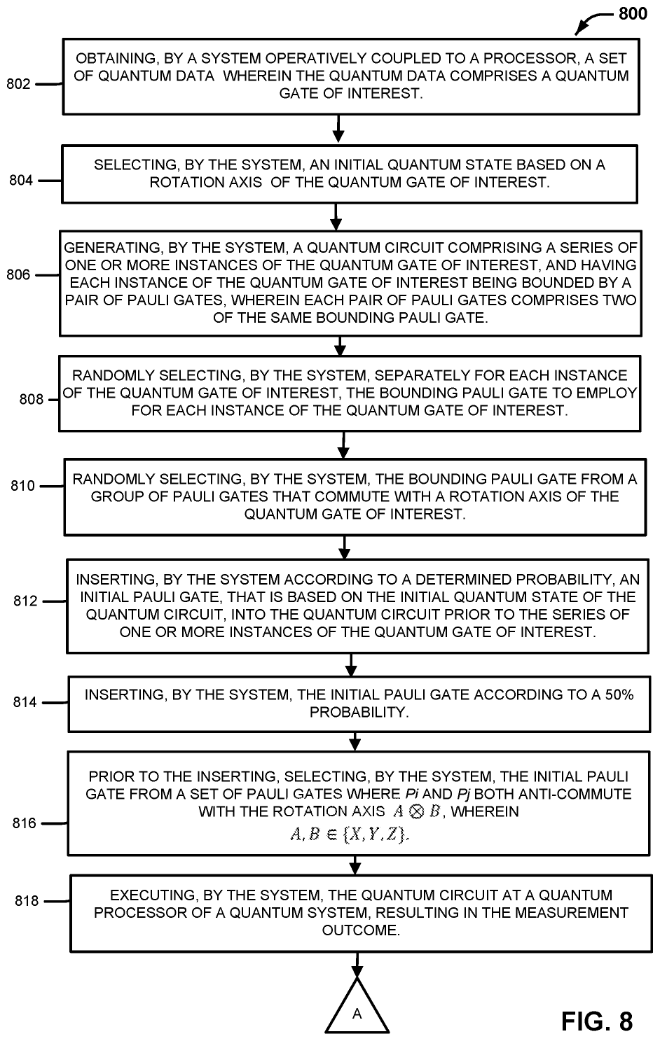

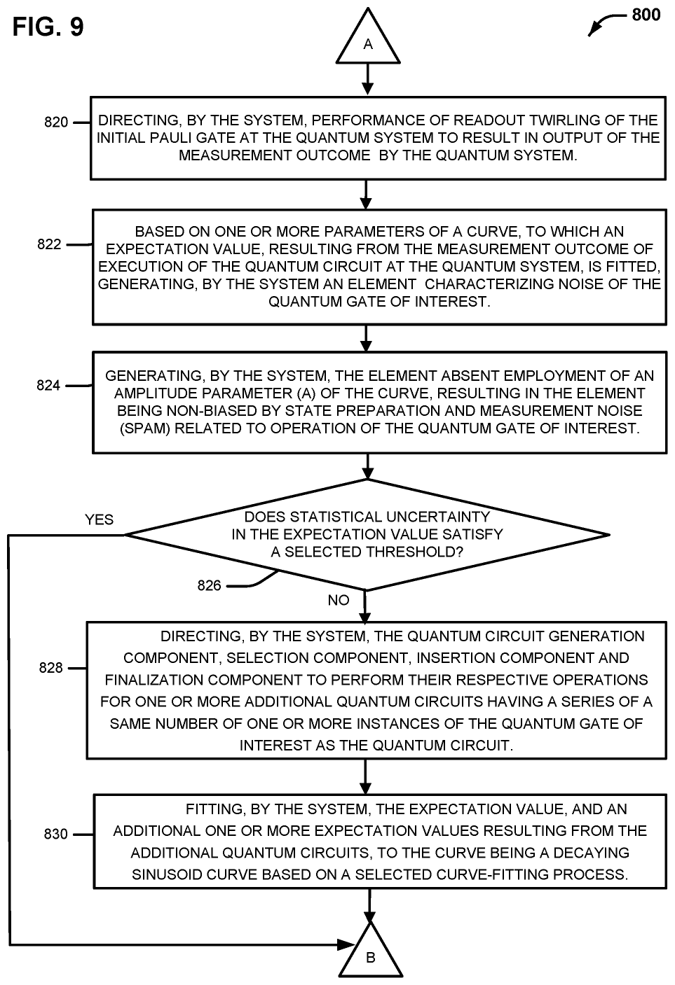

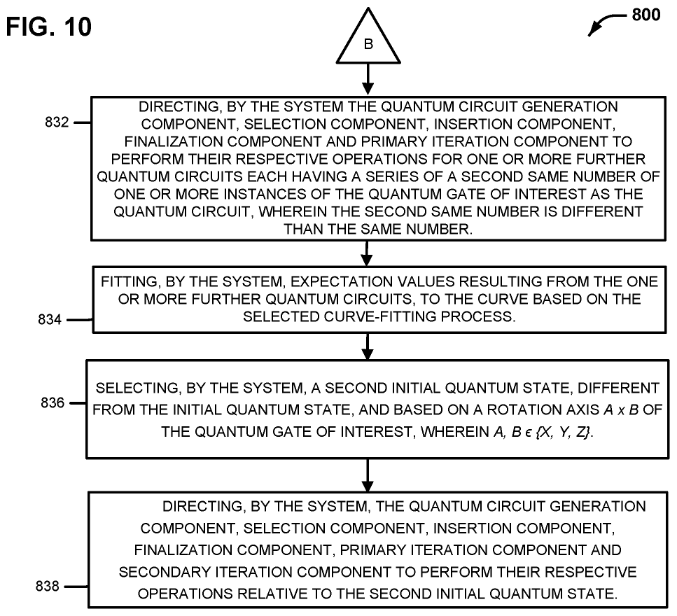

As a summary, referring next to FIGS. 8-10, illustrated is a flow diagram of an example, non-limiting method 800 that can provide a process to obtain an error mitigated measurement outcome of operation of a quantum processor, in accordance with one or more embodiments described herein, such as the non-limiting system 200 of FIG. 2. While the non-limiting method 800 is described relative to the non-limiting system 200 of FIG. 2, the non-limiting method 800 can be applicable also to other systems described herein, such as the non-limiting system 100 of FIG. 1. Repetitive description of like elements and/or processes employed in respective embodiments is omitted for sake of brevity.

At 802, the non-limiting method 800 can comprise obtaining, by a system operatively coupled to a processor (e.g., state preparation component 212), a set of quantum data (e.g., set of quantum data 240) wherein the quantum data comprises a quantum gate of interest (e.g., quantum gate 401).

At 804, the non-limiting method 800 can comprise selecting, by the system (e.g., state preparation component 212), an initial quantum state based on a rotation axis A⊗B of the quantum gate of interest.

At 806, the non-limiting method 800 can comprise generating, by the system (e.g., quantum circuit generation component 214), a quantum circuit (e.g., quantum circuit 402) comprising a series of one or more instances of the quantum gate of interest, and having each instance of the quantum gate of interest being bounded by a pair of Pauli gates (e.g., pair 403 of Pauli gates), wherein each pair of Pauli gates comprises two of the same bounding Pauli gate (e.g., bounding Pauli gate P, P′, etc. of FIG. 4).

At 808, the non-limiting method 800 can comprise randomly selecting, by the system (e.g., selection component 216), separately for each instance of the quantum gate of interest, the bounding Pauli gate to employ for each instance of the quantum gate of interest.

At 810, the non-limiting method 800 can comprise randomly selecting, by the system (e.g., selection component 216), the bounding Pauli gate from a group of Pauli gates (e.g., set 500) that commute with the rotation axis of the quantum gate of interest (e.g., A⊗B, or particularly Z⊗Z in the example of the quantum gate of interest being R_{ZZ}(θ)).

At 812, the non-limiting method 800 can comprise inserting, by the system (e.g., insertion component 218) according to a determined probability (e.g., 50%), an initial Pauli gate (e.g., initial Pauli gate 405), that is based on the initial quantum state of the quantum circuit, into the quantum circuit (e.g., at first portion 402a) prior to the series of one or more instances of the quantum gate of interest.

At 814, the non-limiting method 800 can comprise inserting, by the system (e.g., insertion component 218), the initial Pauli gate according to a 50% probability.

At 816, the non-limiting method 800 can comprise, prior to the inserting, selecting, by the system (e.g., insertion component 218), the initial Pauli gate (Pᵢ) from a set of Pauli gates (e.g., row Pᵢ of Table 550) where Pᵢ and Pⱼ∝(A⊗B)Pᵢ both anti-commute with the rotation axis A⊗B, wherein A, B E {X, Y,Z}.

At 818, the non-limiting method 800 can comprise executing, by the system (e.g., execution component 220), the quantum circuit at a quantum processor (e.g., quantum processor 606) of a quantum system (e.g., quantum system 601), (generally) resulting in the measurement outcome (e.g., measurement outcome 282).

At 820, the non-limiting method 800 can comprise directing, by the system (e.g., readout twirling component 222), performance of readout twirling of the initial Pauli gate at the quantum system to result in output of the measurement outcome (e.g., measurement outcome 282) by the quantum system.

At 822, the non-limiting method 800 can comprise, based on one or more parameters (e.g., curve parameters 752) of a curve (e.g., curve 750), to which an expectation value (e.g., expectation value 284), resulting from the measurement outcome of execution of the quantum circuit at the quantum system, is fitted, generating, by the system (e.g., finalization component 228) an element (e.g., noise characterization element 754) characterizing noise of the quantum gate of interest.

At 824, the non-limiting method 800 can comprise generating, by the system (e.g., finalization component 228), the element absent employment of an amplitude parameter (α) of the curve, resulting in the element being non-biased by state preparation and measurement noise (SPAM) related to operation of the quantum gate of interest.

At 826, the non-limiting method 800 can comprise determining, by the system (e.g., primary iteration component 224), whether statistical uncertainty in the expectation value (e.g., expectation value 284; f(d)) satisfies an uncertainty acceptability threshold (e.g., uncertainty acceptability threshold 720). If yes, the non-limiting method 800 can proceed to step 832. If no, the non-limiting method 800 can proceed to step 828.

At 828, the non-limiting method 800 can comprise directing, by the system (e.g., primary iteration component 224), the quantum circuit generation component, selection component, insertion component and finalization component to perform their respective operations for one or more additional quantum circuits having a series of a same number of one or more instances of the quantum gate of interest as the quantum circuit.

At 830, the non-limiting method 800 can comprise, fitting, by the system (e.g., curve fitting component 226), the expectation value, and an additional one or more expectation values resulting from the additional quantum circuits, to the curve being a decaying sinusoid curve based on a selected curve-fitting process.

At 832, the non-limiting method 800 can comprise directing, by the system (e.g., secondary iteration component 230), the quantum circuit generation component, selection component, insertion component, finalization component and primary iteration component to perform their respective operations for one or more further quantum circuits each having a series of a second same number of one or more instances of the quantum gate of interest as the quantum circuit, wherein the second same number is different than the same number.

At 834, the non-limiting method 800 can comprise fitting, by the system (e.g., curve fitting component 226), expectation values resulting from the one or more further quantum circuits, to the curve based on the selected curve-fitting process.

At 836, the non-limiting method 800 can comprise selecting, by the system (e.g., state preparation component 212), a second initial quantum state, different from the initial quantum state, and based on a rotation axis A⊗B of the quantum gate of interest, wherein A, B∈{X, Y, Z}.

At 838, the non-limiting method 800 can comprise directing, by the system (e.g., state preparation component 212), the quantum circuit generation component, selection component, insertion component, finalization component, primary iteration component and secondary iteration component to perform their respective operations relative to the second initial quantum state.

Direction next turns to additional underlying support, such as proofs, for one or more of the concepts and/or processes discussed above.

First, relative to the preparation of a quantum state by the state preparation component 212, if a quantum state |ψ [symbol] ≡|ψ₁ [symbol] |ψ₂ [symbol] defined in terms of the 2-qubit Paulis Pᵢ and Pᵢ ∝Pᵢ(Z⊗Z) were prepared theoretically perfectly, then [symbol] Pᵢ [symbol] = [symbol] ψ|Pᵢ|ψ [symbol] =1 and [symbol] Pⱼ [symbol] = [symbol] ψ|Pⱼ|ψ [symbol] =0 by design. However, state preparation errors can cause [symbol] Pᵢ [symbol] ≡αᵢ<1 and [symbol] Pⱼ [symbol] ≠0. Thus, [symbol] Pⱼ [symbol] =0 can be enforced without affecting [symbol] Pᵢ [symbol] by applying Pᵢ with 50% probability, as described above relative to the one or more processes that can be performed by the insertion component 216.

As proof of concept of the above preparation of a quantum state, it can be supposed that a noisy state preparation produces a state ρ. By applying Pᵢ with 50% probability ρ can be transformed into

$${ρ}^{′} = \frac{1}{2} ( ρ + {P}_{i} ρ {P}_{i} ) .$$

As a result of standard algebra, it can be shown that tr(Pᵢ ρ′)=tr(Pᵢ ρ) ≡αᵢ, whereas tr(Pⱼ PᵢρPᵢ)=−tr(Pⱼρ) since {Pᵢ, Pⱼ}=0, so tr(Pⱼ ρ′)=0 as claimed, regardless of any state preparation noise/errors.

Second, relative to the preparation of the initial Pauli gate Pᵢ and the direction of readout twirling of the initial Pauli gate Pᵢ, if the measurement readout for the expectation value of a Pauli operator Pᵢ for a quantum state ρ were perfect, the measured value would approach the true value [symbol] Pᵢ [symbol] =tr(Pᵢρ) in the limit of many shots (and would equal [symbol] Pᵢ [symbol] on average for any finite number of shots). If the readout is imperfect, the measured value could deviate from the true value in complicated ways, even asymptotically. However, if readout twirling is employed, as directed by the readout twirling component 222 and as at least partially prepared for by the insertion component 218, the measured expectation value can instead be βᵢ [symbol] Pᵢ [symbol] on average (or asymptotically) for some coefficient βᵢ that depends on Pᵢ but not on ρ.

As proof of concept of the above-described use of readout twirling, where measurement is ultimately performed in the computational basis, it can suffice to consider Paulis Pᵢ composed only of Zs and Is.

Let

$$W = {( \begin{matrix}1 & 1 \\ 1 & - 1\end{matrix} )}^{⊗ n}$$

be a 2ⁿ dimensional Walsh-Hadamard matrix, then W²=2ⁿ I.

Let Xₖ=X^{k}^{₁}⊗ . . . ⊗X^{k}^{ₙ} and [symbol] ₖ=Z^{k}^{₁} ⊗ . . . ⊗Z^{k}^{ₙ}≡diag(\vec{z}ₖ) for k∈{0,1}ⁿ, then \vec{z}ₖ=Wêₖ where êₖ is a standard basis vector.

For an n-qubit quantum state ρ, define the vector \vec{p} of ideal measurement probabilities pₖ= [symbol] k|ρ|k [symbol] , and a vector \vec{v} of ideal expectation values vₖ=tr( [symbol] ₖρ). Then, standard algebra can give \vec{v}=W \vec{p}.

Readout errors can be described by a stochastic matrix A, where Aᵢⱼ is the probability of a j outcome being misclassified as an i. Such errors can result in measurement probabilities of \vec{p}′=A\vec{p} and expectation values of \vec{v}′=2⁻ⁿWAW \vec{v}.

Use of readout twirling replaces A with A″=2⁻ⁿ Σ_{k∈{0,1}n} XₖAXₖ. Using the identities above, plus diag(\vec{x})Mdiag(\vec{x})=(\vec{x}\vec{x}^{T})∘M for any matrix M and vector \vec{x}, where ∘ denotes the Hadamard (i.e., element-wise) product, and Σₖ êₖêₖ^{T} I, A″ can be rewritten as:

$${A}^{″} = {2}^{- 3 n} {\sum }_{k} ( W {𝒵}_{k} W ) A ( W {𝒵}_{k} W ) = {2}^{- 3 n} W [ ( {\sum }_{k} {\vec{z}}_{k} {\vec{z}}_{k}^{T} ) ∘ ( WAW ) ] W = {2}^{- 2 n} W [ I ∘ ( WAW ) ] W .$$

The resulting, erroneous expectation values can therefore be \vec{v}″=2⁻ⁿ[I∘(WAW)]\vec{v}, i.e., vₖ″=βₖ [symbol] [symbol] ₖ [symbol] where βₖ=2⁻ⁿ(WAW)ₖₖ.

Third relative to one or more of the processes performed by the finalization component 228 and/or curve-fitting component 226, for transforming one or more measurement readouts 282 into one or more PTM elements 286, the expected value of f(d), which describes the measurement outcomes of the random quantum circuits in Part 1 of FIG. 3, is αᵢβᵢ (B^{d})₀₀ where

$$B = ( \begin{matrix}{G}_{ii} & {G}_{ij} \\ {G}_{ji} & {G}_{jj}\end{matrix} )$$

and the coefficients αᵢ and βᵢ (defined above) depend on the state preparation and measurement errors, respectively.

As proof of concept of the above-described post-quantum circuit execution processes, a quantum channel for a noisy R_{ZZ}(θ) gate can be denoted as [symbol] . Every such gate in the quantum circuits 402 described above can be performed between two Pₖ gates, where each Pₖ is a random 2-qubit Pauli drawn uniformly and independently from [symbol] ={I⊗I, Z⊗Z, Z⊗I, I⊗ [symbol] Z, X⊗X, Y⊗Y, Y⊗X, X⊗Y}, the set of 2-qubit Paulis that commute with Z⊗Z. This results in an overall channel

$$ρ ↦ \frac{1}{8} {\sum }_{{P}_{k} ∈ 𝒞} {P}_{k} 𝒢 ( {P}_{k} ρ {P}_{k} ) {P}_{k}$$

whose (i,j)^{th} Pauli transfer matrix (PTM) element is:

$$tr [ {P}_{i} \frac{1}{8} {\sum }_{{P}_{k} ∈ 𝒞} {P}_{k} 𝒢 ( {P}_{k} {P}_{j} {P}_{k} ) {P}_{k} ] / 4 = \frac{1}{8} {\sum }_{{P}_{k} ∈ 𝒞} tr [ {P}_{k} {P}_{i} {P}_{k} 𝒢 ( {P}_{k} {P}_{j} {P}_{k} ) ] / 4 = ( \frac{1}{8} {\sum }_{k \vert {P}_{k} ∈ 𝒞} {s}_{ik} {s}_{kj} ) {G}_{ij} ,$$

where Sᵢₖ=1 (or −1) if Pᵢ and Pₖ commute (anti-commute).

Direct computation can show that the last bracketed sum above equals 1 if i=j or if PᵢPⱼ∝Z⊗Z, and 0 otherwise. The average PTM of such a cycle is therefore block-diagonal, comprising 2×2 blocks with the form of B above, for indices i and j corresponding to pairs of Paulis (Pᵢ, Pⱼ) where Pⱼ∝(Z⊗Z)Pᵢ.

Note also that since Pₖ is sampled independently in each such cycle, the average overall PTM for d cycles is just the single-cycle average PTM to the d^{th} power. This follows from the fact that [symbol] (xy)= [symbol] (x) [symbol] (y) for any independent random variables x and y.

In the absence of SPAM errors, the ultimate expectation value would therefore be (B^{d})₀₀. In the presence of SPAM errors, the ultimate expectation value could, in principle, depend on all four elements of B^{d}. However, because of the randomization imbued to the state preparation by the insertion component 218, and because of the readout twirling directed by the readout twirling component 222, the ultimate expectation value instead equals αᵢβᵢ(B^{d})₀₀ as claimed above. And importantly, αᵢβᵢ is independent of d.

Fourth, relative also to one or more of the processes performed by the finalization component 228 and/or curve-fitting component 226, for transforming one or more measurement readouts 282 into one or more PTM elements 286, the expected value of f(d) is αᵢβᵢ(B^{d})₀₀=a r^{d} cos(ωd−δ) where the amplitude is a=αᵢβᵢ×2\sqrt{−GᵢⱼGⱼᵢ}/Ω, the decay rate is r=\sqrt{GᵢᵢGⱼⱼ−GᵢⱼGⱼᵢ}, the frequency is given by cot ω=(Gᵢᵢ+Gⱼⱼ)/Ω, and the phase by tan δ=(Gᵢᵢ−Gⱼⱼ)/Ω, where Ω=\sqrt{−(Gᵢᵢ−Gⱼⱼ)²−4 GᵢⱼGⱼᵢ} is defined to simplify the notation. Only the amplitude a depends on the coefficients αᵢ and βᵢ, which arise due to SPAM errors.

As proof of concept of the above described post-quantum circuit execution processes, it can be supposed that

$$B = ( \begin{matrix}{G}_{ii} & {G}_{ij} \\ {G}_{ji} & {G}_{jj}\end{matrix} )$$

has eigenvectors

$${\vec{v}}_{\pm } = ( \begin{matrix}( {G}_{ii} - {G}_{jj} \pm i Ω ) / 2 \\ {G}_{ji}\end{matrix} )$$

and eigenvalues λ_{±}=(Gᵢᵢ+Gⱼⱼ+iΩ)/2. The expression for (B^{d})₀₀ is qualitatively different depending on whether λ_{±} are real or complex. The one or more embodiments described herein can employ the eigenvalues being complex, i.e., it assumes 4GᵢⱼGⱼᵢ+(Gᵢᵢ−Gⱼⱼ)²<0 (the condition on slide 12) so that Ω is real and positive. This can lead to an oscillating decay in (B^{d})₀₀ vs. d (which can be easier to curve fit), rather than a sum of exponential decays (which can be harder to curve fit).

Under this assumption, the eigenvalues as λ_{±}=re^{±iω} can be expressed using the expressions above, where r, ω∈ [symbol] and r>0. After noting that

$$( {\vec{v}}_{+} - {\vec{v}}_{-} ) / i Ω = ( \begin{matrix}1 \\ 0\end{matrix} ) ,$$

a straightforward calculation can provide all of the other expressions above for this fourth point.

Finally, a similar calculation can provide the functions used by the finalization component 228 to generate gᵢᵢ, gⱼⱼ and gᵢⱼ×g in terms of r, ω, and δ, all of which carry information about the Pauli transfer matrix of the noisy R_{ZZ}(θ) gate, but are independent of SPAM errors.

### Additional Summary—Characterizing Noisy Non-Clifford Gates Through Partial Pauli Twirling

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

In summary, the one or more embodiments described herein can provide a system, computer-implemented method and/or computer program product to characterize noise of a quantum gate can comprise a memory that stores, and a processor that executes, computer executable components that perform operations comprising generating a quantum circuit comprising one or more instances of a quantum gate of interest, and that generates the quantum circuit having each instance of the quantum gate of interest being bounded by a pair of Pauli gates, wherein each pair of Pauli gates comprises two of the same bounding Pauli gate, inserting, according to a determined probability, an initial Pauli gate, that is based on an initial quantum state of the quantum circuit, prior to the one or more instances, and, based on one or more parameters of a curve, to which an expectation value, resulting from a measurement outcome of execution of the quantum circuit, is fitted, generating an element characterizing the noise.

A benefit of the system, computer-implemented method and/or computer program product can be accurate determination of Pauli transfer matrix elements corresponding to a quantum channel comprising a non-Clifford gate, such as an n-qubit non-Clifford gate and/or for gates of the form R_{ZZ}(θ) for angle |θ|<π/2 natively. Further, many Trotter/Floquet circuits for simulating quantum dynamics naturally call for such R_{ZZ}(θ) gates. These Pauli transfer matrix elements can be employed to characterize the noisy non-Clifford gate, thus allowing for operation of the respective quantum channel.

Another benefit of the system, computer-implemented method and/or computer program product can be an ability to characterize non-Clifford gates, such as partial CNOT gates or partially-entangling R_{ZZ}(θ)=e^{-iθ/2 z⊗z} gates for arbitrary angles θ in a quantum circuit, through use of the Pauli transfer matrix elements for such non-Clifford gates being determinable through use of the one or more embodiments described herein. These gates can be employed in a variety of applications, such as simulating quantum dynamics. These gates can be realized on a quantum computer with the realization having higher fidelity than realization of 2-qubit Clifford gates, such as CNOTs, because such non-Clifford gates are shorter than CNOTs. Accordingly, the system, computer-implemented method and/or computer program product can provide for use of previously inaccessible, native gates.

Still another benefit of the system, computer-implemented method and/or computer program product can be an ability to generate one or more elements characterizing noise of the quantum gate of interest, from which one or more Pauli transfer matrix (PTM) elements of a Pauli transfer matrix of the quantum gate of interest. That is, based on one or more parameters of the curve to which the expectation values are fitted, the one or more embodiments described herein can then yield combinations of Pauli transfer matrix elements for the noisy gate of interest. An amplitude a of the curve is the only fit parameter that depends on state preparation and measurement (SPAM) noise, and this parameter gets discarded due to non-use in equations representing the Pauli transfer matrix (PTM) elements for the noisy quantum gate of interest, which are instead based on one or more of a decay rate (r), frequency (ω) and/or phase (δ). Accordingly, the PTM element results are not biased by SPAM noise.

Yet another benefit of the system, computer-implemented method and/or computer program product can generally be an improvement in the functioning of a quantum computer. This improvement over existing computerized technologies and/or quantum computerized technologies improves the function of a quantum computer with respect to noise caused by execution of the quantum computer. Indeed, for to a non-limiting system comprising both a classical system as described herein and a quantum system as described herein (e.g., comprising a quantum computer), such non-limiting system can be self-improving through primary characterization of noise that is caused by execution of a selected quantum gate and through secondary use of one or more aspects of the characterization to further execute the selected quantum gate with no such noise or reduced such noise.

More particularly, the benefit can comprise an ability to improve the efficiency of using a quantum computer by reducing the noise being caused by employment of the quantum computer. That is, through use of the system, computer-implemented method and/or computer program product, noise that is caused by execution of a particular quantum gate can be characterized. Using the characterization of the noise, operation of that same selected quantum gate can be transformed to operate at the same quantum computer with less noise that was characterized and/or absent one or more elements of the noise that was characterized. Such amended operation can comprise, but is not limited to, use of one or more different waveforms defined by one or more additional and/or altered quantum gates, order of quantum gates, etc. to cause one or more different changes (e.g., of energy states, rotations, etc.) of one or more physical qubits of a quantum processor of the quantum computer.

As a result, the speed of a use, efficiency of use, and/or accuracy and/or precision of one or more states and/or rotations to which one or more qubits of the quantum computer are caused to enter, can be increased by use of the characterizations resulting from use of the system, computer-implemented method and/or computer program product. As a secondary result, the measurement readouts obtained from the quantum computer, based directly on readout of the one or more states and/or rotations to which the one or more qubits of the quantum computer are caused to enter, can in turn be improved to be more accurate and/or precise, in turn leading to one or more expectation values being determined with improved speed, efficiency, accuracy and/or precision.

Indeed, in view of the one or more embodiments described herein, a practical application of the one or more systems, computer-implemented methods and/or computer program products described herein can be the obtaining of one or more elements characterizing noise of a quantum gate, such as a non-Clifford gate, based on execution of a shaped quantum circuit at a quantum processor and subsequent measurement readout twirling by the one or more systems, computer-implemented methods and/or computer program products described herein. Accordingly, based on use of measurement outcomes, an expectation value can be obtained that can define a curve, wherein one or more parameters of the curve can be employed to obtain the one or more elements characterizing the noise of the quantum gate, with SPAM noise being dropped from the one or more parameters. These processes can be useful in fields of finance, biology, chemistry, materials science, pharmacology and/or drug-delivery using a quantum processor, without being limited thereto. More particularly, in one or more embodiments, these processes can be employed to define a PTM of the quantum gate, thus allowing for error mitigation of a result of execution of the quantum gate (which again can be an n-qubit non-Clifford gate). Accordingly, the one or more embodiments described herein provide useful and practical applications of computers, thus providing enhanced (e.g., improved and/or optimized) quantum circuit execution at a quantum processor and enhanced measurement outcomes from the quantum processor. Overall, such computerized tools can constitute a concrete and tangible technical improvement in the fields of quantum processing and/or quantum dynamics, without being limited thereto.

Furthermore, one or more embodiments described herein can be employed in a real-world system based on the disclosed teachings. For example, one or more embodiments described herein can function in combination with a physical quantum computer having a physical quantum processor. In response to one or more waveforms generated by a waveform generator of the quantum computer, physical quantum qubit hardware of the quantum processor can produce signals and/or changes in state of the qubit hardware, resulting in ability to measure such signals and/or changes in state of the qubit hardware. The measurements, e.g., the measurement outcomes, can be thereafter employed for various inference actions relative to sample quantum data corresponding to one or more quantum circuits having been executed on the quantum computer by way of operation of the waveform generator.

Moreover, one or more embodiments described herein can be implemented in one or more domains to enable scaled quantum processing. Indeed, use of a system, computer-implemented method and/or computer program product as described herein can be scalable, such as where plural quantum gates (e.g., input quantum gates) can be evaluated, processed (e.g., modified) and/or executed at a quantum processor at least partially at a same time as one another. These plural quantum gates can arise from one or more quantum circuits. Accordingly, scaling can be enabled for more than one quantum circuit at least partially in parallel with one another.

These scalings can be made possible by use of independent sets of physical qubits for each first quantum gate. That is, a quantum processor can comprise hardware for plural physical qubits. In view thereof, a qubit mapping can be determined for a single quantum processor for operation of various quantum circuits (e.g., relative to various quantum gates) at least partially in parallel with one another. Furthermore, the classical processing employed corresponding to the plural quantum gates also can be performed at least partially in parallel with one another. That is, the processing for pre-execution modification of quantum circuits, post-measurement outcome curve fitting, and post-curve fitting noise characterization element determination can be performed at a classical computer and can be performed relative to plural quantum gates at least partially in parallel with one another.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to execution of non-Clifford quantum gates, as compared to existing systems and/or techniques. Systems, computer-implemented methods and/or computer program products providing performance of these processes are of great utility in the fields of quantum circuit operation and/or quantum computing more generally and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically perform quantum circuit encoding, load a quantum register, perform quantum calculations, generate a waveform and/or measure a state of qubit as the one or more embodiments described herein can provide these processes. Moreover, neither can the human mind nor a human with pen and paper conduct one or more of these processes, as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is next provided.

A system, comprising: a memory that stores computer executable components; and a processor that executes the computer executable components stored in the memory, wherein the computer executable components comprise: a quantum circuit generation component that generates a quantum circuit comprising a series of one or more instances of a quantum gate of interest, wherein the quantum circuit generation component further generates the quantum circuit having each instance of the quantum gate of interest being bounded by a pair of Pauli gates, and wherein each pair of Pauli gates comprises two of the same bounding Pauli gate; a selection component that randomly selects, separately for each instance of the quantum gate of interest, the bounding Pauli gate to employ for each instance of the quantum gate of interest; an insertion component that inserts, according to a determined probability, an initial Pauli gate, that is based on an initial quantum state of the quantum circuit, into the quantum circuit prior to the series of one or more instances of the quantum gate of interest; and a finalization component that, based on one or more parameters of a curve, to which an expectation value, resulting from a measurement outcome of execution of the quantum circuit at a quantum system, is fitted, generates an element characterizing noise of the quantum gate of interest.

The system of the preceding paragraph, further comprising: an execution component that executes the quantum circuit at a quantum processor of the quantum system, resulting in the measurement outcome.

The system of any preceding paragraph, wherein the quantum gate of interest is a 2-qubit, non-Clifford quantum gate.

The system of any preceding paragraph, wherein the selection component randomly selects the bounding Pauli gate from a group of Pauli gates that commute with a rotation axis of the quantum gate of interest, and wherein the insertion component inserts the initial Pauli gate according to a 50% probability.

The system of any preceding paragraph, further comprising: a state preparation component that selects the initial quantum state based on a rotation axis A⊗B of the quantum gate of interest, wherein the insertion component selects the initial Pauli gate (Pᵢ) from a set of Pauli gates where Pᵢ and Pᵢ∝(A⊗B)Pᵢ both anti-commute with the rotation axis A⊗B, and wherein A, B∈{X, Y,Z}.

The system of any preceding paragraph, further comprising: a readout twirling component that directs performance of readout twirling of the initial Pauli gate at the quantum system to result in output of the measurement outcome by the quantum system.

The system of any preceding paragraph, wherein the finalization component generates the element absent employment of an amplitude parameter of the curve, resulting in the element being non-biased by state preparation and measurement noise related to operation of the quantum gate of interest.

The system of any preceding paragraph, further comprising: a primary iteration component that directs the quantum circuit generation component, selection component, insertion component and finalization component to perform their respective operations for one or more additional quantum circuits having a series of a same number of one or more instances of the quantum gate of interest as the quantum circuit.

The system of any preceding paragraph, further comprising: a curve fitting component that fits the expectation value, and an additional one or more expectation values resulting from the additional quantum circuits, to the curve being a decaying sinusoid curve based on a selected curve-fitting process.

The system of any preceding paragraph, further comprising: a secondary iteration component that directs the quantum circuit generation component, selection component, insertion component, finalization component and primary iteration component to perform their respective operations for one or more further quantum circuits each having a series of a second same number of one or more instances of the quantum gate of interest as the quantum circuit, wherein the second same number is different than the same number; and a state preparation component that selects a second initial quantum state, different from the initial quantum state, and, based on a rotation axis A⊗B of the quantum gate of interest, wherein A, B∈{X, Y, Z}, and wherein the state preparation component further directs the quantum circuit generation component, selection component, insertion component, finalization component, primary iteration component and secondary iteration component to perform their respective operations relative to the second initial quantum state.

A computer-implemented method, comprising: generating, by a system comprising a processor, a quantum circuit comprising a series of one or more instances of a quantum gate of interest, and having each instance of the quantum gate of interest being bounded by a pair of Pauli gates, wherein each pair of Pauli gates comprises two of the same bounding Pauli gate; randomly selecting, by the system, separately for each instance of the quantum gate of interest, the bounding Pauli gate to employ for each instance of the quantum gate of interest; inserting, by the system, according to a determined probability, an initial Pauli gate, that is based on an initial quantum state of the quantum circuit, into the quantum circuit prior to the series of one or more instances of the quantum gate of interest; and, based on one or more parameters of a curve, to which an expectation value, resulting from a measurement outcome of execution of the quantum circuit at a quantum system, is fitted, generating, by the system, an element characterizing noise of the quantum gate of interest.

The computer-implemented method of the preceding paragraph, further comprising: executing, by the system, the quantum circuit at a quantum processor of the quantum system; and directing, by the system, performance of readout twirling of the initial Pauli gate at the quantum system to result in output of the measurement outcome by the quantum system.

The computer-implemented method of any preceding paragraph, further comprising: randomly selecting, by the system, the bounding Pauli gate from a group of Pauli gates that commute with a rotation axis of the quantum gate of interest; and inserting, by the system, the initial Pauli gate according to a 50% probability.

The computer-implemented method of any preceding paragraph, further comprising: selecting, by the system, the initial quantum state based on a rotation axis A⊗B of the quantum gate of interest; and selecting, by the system, the initial Pauli gate (Pᵢ) from a set of Pauli gates where Pᵢ and Pⱼ∝(A⊗B)Pᵢ both anti-commute with the rotation axis A⊗B, wherein A, B∈{X, Y,Z}.

The computer-implemented method of any preceding paragraph, further comprising: generating, by the system, the element absent employment of an amplitude parameter of the curve, resulting in the element being non-biased by state preparation and measurement noise related to operation of the quantum gate of interest.

A computer program product facilitating a process to characterize a noisy quantum gate, the computer program product comprising a computer readable storage medium having program instructions embodied therewith, the program instructions executable by a processor to cause the processor to: generate, by the processor, a quantum circuit comprising a series of one or more instances of a quantum gate of interest, and having each instance of the quantum gate of interest being bounded by a pair of Pauli gates, wherein each pair of Pauli gates comprises two of the same bounding Pauli gate; randomly select, by the processor, separately for each instance of the quantum gate of interest, the bounding Pauli gate to employ for each instance of the quantum gate of interest; insert, by the processor, according to a determined probability, an initial Pauli gate, that is based on an initial quantum state of the quantum circuit, into the quantum circuit prior to the series of one or more instances of the quantum gate of interest; and, based on one or more parameters of a curve, to which an expectation value, resulting from a measurement outcome of execution of the quantum circuit at a quantum system, is fitted, generate, by the processor, an element characterizing noise of the quantum gate of interest.

The computer program product of any preceding paragraph, wherein the program instructions are further executable by the processor to cause the processor to: execute, by the processor, the quantum circuit at a quantum processor of the quantum system; and direct, by the processor, performance of readout twirling of the initial Pauli gate at the quantum system to result in output of the measurement outcome by the quantum system.

The computer program product of any preceding paragraph, wherein the program instructions are further executable by the processor to cause the processor to: randomly select, by the processor, the bounding Pauli gate from a group of Pauli gates that commute with a rotation axis of the quantum gate of interest; and insert, by the processor, the initial Pauli gate according to a 50% probability.

The computer program product of any preceding paragraph, wherein the program instructions are further executable by the processor to cause the processor to: select, by the processor, the initial quantum state based on a rotation axis A⊗B of the quantum gate of interest; and select, by the processor, the initial Pauli gate (Pᵢ) from a set of Pauli gates where Pᵢ and Pᵢ∝(A⊗B)Pᵢ both anti-commute with the rotation axis A⊗B, wherein A, B∈{X, Y, Z}.

The computer program product of any preceding paragraph, wherein the program instructions are further executable by the processor to cause the processor to: generate, by the processor, the element absent employment of an amplitude parameter of the curve, resulting in the element being non-biased by state preparation and measurement noise related to operation of the quantum gate of interest.

### Description—Characterizing Noisy Non-Clifford Gates Through Alternating Pauli Twirling

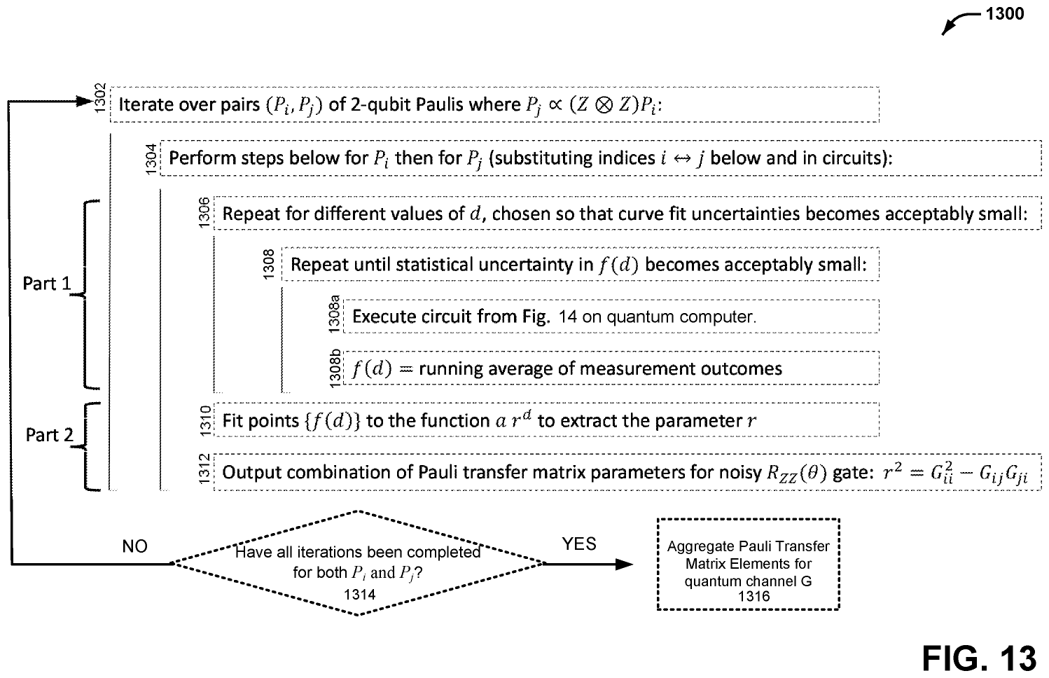

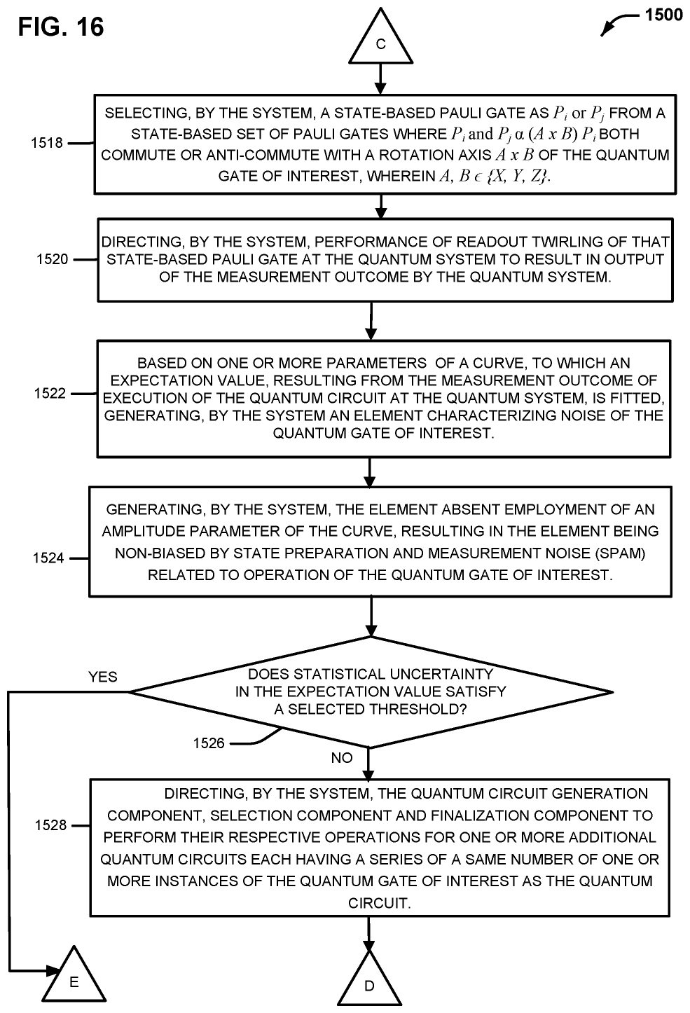

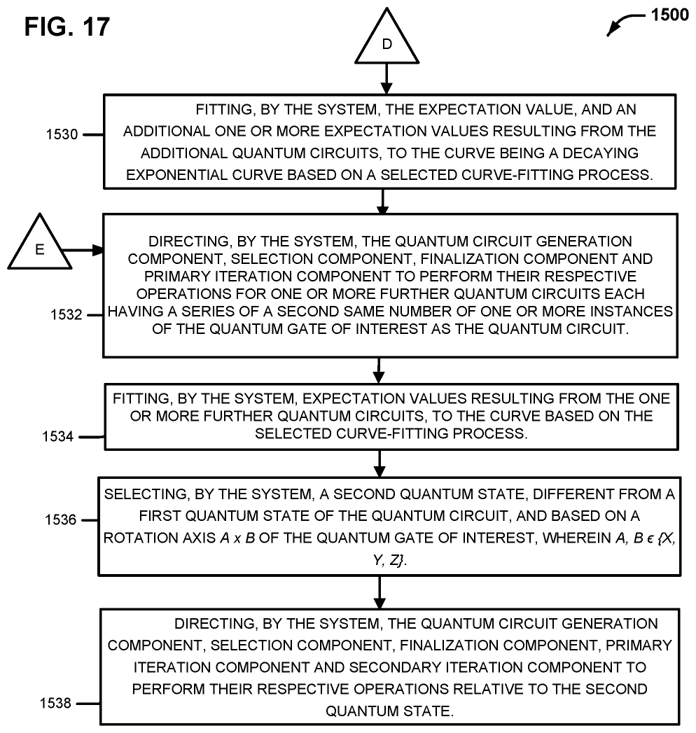

Discussion now turns to a summary applicable to characterization of noise of quantum gates, such as non-Clifford gates, through alternating Pauli twirling. That is, discussion turns now more generally to one or more embodiments encompassing any of the non-limiting systems of FIGS. 11 and 12 and associated processes of the respective FIGS. 13-17 related to these non-limiting systems.

Turning now in particular to one or more figures, and first to FIG. 11, the figure illustrates a block diagram of an example, non-limiting system 1100 that can facilitate a process to shape and execute a quantum circuit to obtain noise characterization parameters for the quantum circuit therefrom, in accordance with one or more embodiments described herein. That is, the non-limiting system 1100 can facilitate the process to shape and direct execution of a quantum circuit to obtain noise characterization parameters for the quantum circuit therefrom, in combination with employment of a quantum system 601.

The non-limiting system 1100 can comprise a quantum gate noise characterizing system 1102. It is noted that the quantum gate noise characterizing system 1102 is only briefly detailed to provide but a lead-in to a more complex and/or more expansive quantum gate noise characterizing system 1202 as illustrated at FIG. 12. That is, further detail regarding processes that can be performed by one or more embodiments described herein will be provided below relative to the non-limiting system 1200 of FIG. 12.

Still referring to FIG. 11, the quantum gate noise characterizing system 1102 can comprise at least a memory 1104, bus 1105, processor 1106, quantum circuit generation component 1114, selection component 1116, insertion component 1118 and finalization component 1128. Using these components and the quantum system 601, the quantum gate noise characterizing system 1102 can shape a quantum circuit comprising a quantum gate, execute the quantum circuit at the quantum system 601, direct performance of readout twirling by the quantum system 601, perform curve fitting and employ parameters from the curve fitting to generate one or more parameters that can be employed to characterize noise of the quantum gate. The one or more parameters can be employed to generate one or more Pauli transfer matrix (PTM) elements for the quantum gate while dropping state preparation and measurement (SPAM) noise from this generation of the one or more PTM elements.

For example, the quantum gate noise characterizing system 1102 can obtain a set of quantum data 1140, which can comprise a quantum gate (e.g., referred here to as a quantum gate of interest). It can be desired to learn noise characterizing parameters for the quantum gate of interest to enable use of the quantum gate in an error mitigated process and/or for one or more other processes. For example, in one or more embodiments, it can be the case that the quantum gate cannot be executed without undesirable error, and/or cannot be executed as quickly as desired, such as due to hardware imperfections, including unwanted interactions with the environment or with other qubits, or due to imperfectly calibrated control operations. In one or more embodiments, the quantum gate can be an n-qubit non-Clifford gate.

For this reason, the quantum circuit generation component 1114 can generate a quantum circuit for the purpose of being executed at a quantum system (e.g., quantum system 601) in a manner that can result in a measurement outcome 1182 being employed to generate an expectation value 1184, where the expectation value 1184 can be employed to generate one or more noise characterizing elements such as and/or allowing for subsequent generation of one or more PTM elements 1186 for the quantum gate of interest.

That is, the quantum circuit generation component 1114 can generate a quantum circuit comprising a series of one or more instances of a quantum gate of interest. The quantum circuit generation component 1114 further generates the quantum circuit having each instance of the quantum gate of interest being bounded by a pair of Pauli gates, wherein each pair of Pauli gates comprises two of the same bounding Pauli gate. Part of this process can comprise the quantum circuit generation component determining a depth level for the quantum circuit, wherein the depth level d corresponds directly to the number of instances of the quantum gate of interest provided in series in the quantum circuit.

In parallel, subsequent to, and/or prior to the process of the quantum circuit generation component 1114, the selection component 1116 can determine the bounding Pauli gate to employ for each instance of the quantum gate of interest. That is, the selection component 1116 can select, separately for various instances of the quantum gate of interest, employing an aspect of randomness, the bounding Pauli gate from a selected set of Pauli gates.

More particularly, the selection component 1116 can randomly select, separately for each odd-numbered instance, of the series of one or more instances of the quantum gate of interest, the respective bounding Pauli gate to employ from a set of Pauli gates of a random set selection of a first set of Pauli gates or a second set of Pauli gates, and randomly select, separately for each even numbered instance, of the series of one or more instances of the quantum gate of interest, the respective bounding Pauli gate from the other of the first set of Pauli gates or the second set of Pauli gates that was not randomly selected for the directly preceding odd-numbered instance in the series of one or more instances of the quantum gate of interest.

One of the first set or the second set of Pauli gates can comprise only Pauli gates that commute with a rotation axis of the quantum gate of interest. The other of the first set or the second set of Pauli gates can comprise only Pauli gates that anti-commute with a rotation axis of the quantum gate of interest.

Based on execution of the completed quantum circuit at a quantum system (e.g., the quantum system 601), a measurement outcome 1182 can be obtained. Based on one or more parameters of a curve, to which an expectation value 1184, resulting from the measurement outcome 1182, is fitted, the finalization component 1128 can generate an element characterizing noise of the quantum gate of interest. This element can be and/or can be employed to subsequently generate, by the finalization component 1128, one or more PTM elements 1186 for the PTM of the quantum gate of interest. That is, the finalization component 1128 can provide for generation of the one or more PTM elements 1186 based on the measurement outcome 1182.

As used herein, a “Pauli transfer matrix” can be employed to describe a quantum channel C, such as the G channel. Any quantum channel C can be fully described by 4ⁿ×4ⁿ Pauli transfer matrix elements cᵢⱼ; =Tr[PᵢC(Pⱼ)]/2ⁿ, where i and j are are indices (e.g., describing height and width of the Pauli transfer matrix from row 1 to row (4ⁿ×4ⁿ) and column 1 to column (4ⁿ×4ⁿ)). Thus, each i and j as a pair is used to label a particular element from the Pauli transfer matrix elements cᵢⱼ. That is, there are 4ⁿ×4ⁿ pairs of i and j, where each pair of i and j represents two n-qubit Pauli gates of a set of n-qubit Pauli gates represented by the Pauli transfer matrix. For example, a quantum channel C that is a 2-qubit quantum channel can be fully described by 4²×4² Pauli transfer matrix elements (i.e., 256 different Pauli transfer matrix elements) which represent 4²×4² Pauli gates (e.g., 256 different Pauli gates).

It is noted that the quantum circuit generation component 1114, selection component 1116 and finalization component 1128 each can operate at a classical system of and/or comprising the quantum gate noise characterizing system 1102.

In general, the non-limiting system 1100 can employ any suitable method of communication (e.g., electronic, communicative, internet, infrared, fiber, etc.) to provide communication between the quantum gate noise characterizing system 1102 and the quantum system 601.

Turning next to FIG. 12, a non-limiting system 1200 is illustrated that can comprise a quantum gate noise characterizing system 1202. Repetitive description of like elements and/or processes employed in respective embodiments is omitted for sake of brevity. Description relative to an embodiment of FIG. 11 can be applicable to an embodiment of FIG. 12. Likewise, description relative to an embodiment of FIG. 12 can be applicable to an embodiment of FIG. 11.

Generally, the quantum gate noise characterizing system 1202 can shape a quantum circuit comprising a quantum gat of interest, execute the quantum circuit at the quantum system 601, and based on the execution, generate one or more elements characterizing noise of the quantum gate.

The quantum gate of interest (e.g., quantum gate of interest 1401) can be one for which noise characterization is desired. That is, in one or more embodiments, it can be the case that the quantum gate of interest 1401 (also herein referred to as the quantum gate 1401) cannot be executed without undesirable error, and/or cannot be executed as quickly as desired, such as due to hardware imperfections, including unwanted interactions with the environment or with other qubits, or due to imperfectly calibrated control operations. In one or more embodiments, the quantum gate of interest 1401 can be an n-qubit non-Clifford gate.

The quantum gate of interest 1401 can have the form R_{AB}(θ)=exp(−iθ/2 A⊗B), for any single-qubit Paulis A, B∈{X, Y, Z} and an arbitrary angle θ. That is, A can independently be any of X, Y or Z, and B can independently be any of X, Y or Z. In connection with the quantum gate noise characterizing system 1202 of FIG. 12, the example employed at FIGS. 13, 14 and 5 employs a quantum gate of interest 1401 being an R_{ZZ}(θ), gate, wherein A=B=Z. However, such quantum gate of interest can take any other form of any other values X, Y or Z for A and B.

That is, X, Y and Z denote Pauli σₓ, σ_{y} and σ_{z} matrices, respectively. An n-qubit Pauli is an n-fold tensor product of I, X, Y and Z of which there are 4ⁿ. Any two n-qubit Paulis P₁ and P₂ either commute [P₁, P₂]=P₁P₂−P₂P₁=0 or anti-commute {P₁, P₂}=P₁P₂+P₂P₁=0. Pauli gates can be employed to describe quantum gates (an n-qubit Pauli means single-qubit Pauli gates are applied to n qubits in parallel), or measurement operators (whose possible outcomes are ±1).

Relative to an initial quantum state of Z⊗Z for the quantum gate of interest 1401, the following rules key 511 can be employed to transform each of the processes herein, as will be described below. That is, this rules key 511 employs Z⊗Z as a starting basis for changing the rotation axis of the processes herein from of Z⊗Z to another of A⊗B, based on the rotation axis of any different gate of interest 401 having the form R_{AB}(θ)=exp(−iθ/2 A⊗B), for any single-qubit Paulis A, B∈{X, Y, Z} and an arbitrary angle θ.

### Rules Key 511

For example, If A=X, all the Paulis on the first qubit should be changed as X→Y, Y→Z and Z→X. (“I” does not change.)

If A=Y, all the Paulis on the first qubit should be changed as X→Z, Y→X and Z→Y. (“I” does not change.)

If A=Z, all the Paulis on the first qubit stay as they are.

The term “Paulis on the first qubit” refers to the first “letter” in a 2-qubit Pauli such as XY.

The second qubit works similarly:

If B=X, all the Paulis on the second qubit should be changed as X→Y, Y→Z and Z→X. (“I” does not change.)

If B=Y, all the Paulis on the second qubit should be changed as X→Z, Y→X and Z→Y. (“I” does not change.)

If B=Z, all the Paulis on the second qubit stay as they are.

It is noted that the rules key 511 applies to set 500, set 510 and table 550 of FIG. 5.

For example, Batch 8 at Table 550 has Pᵢ=ZX and Pⱼ=IY, but if used with respect to a quantum gate of interest R_{XY}(B), where A=X and B=Y, Batch 8 at Table 550 would be transformed to Pᵢ=XZ and Pⱼ=IX.

Turning again more particularly to the quantum gate noise characterizing system 1202, one or more communications between one or more components of the non-limiting system 1200 can be provided by wired and/or wireless means including, but not limited to, employing a cellular network, a wide area network (WAN) (e.g., the Internet), and/or a local area network (LAN). Suitable wired or wireless technologies for supporting the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra-mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an advanced and/or adaptive network technology (ANT), an ultra-wideband (UWB) standard protocol and/or other proprietary and/or non-proprietary communication protocols.

The quantum gate noise characterizing system 1202 can be associated with, such as accessible via, a cloud computing environment.

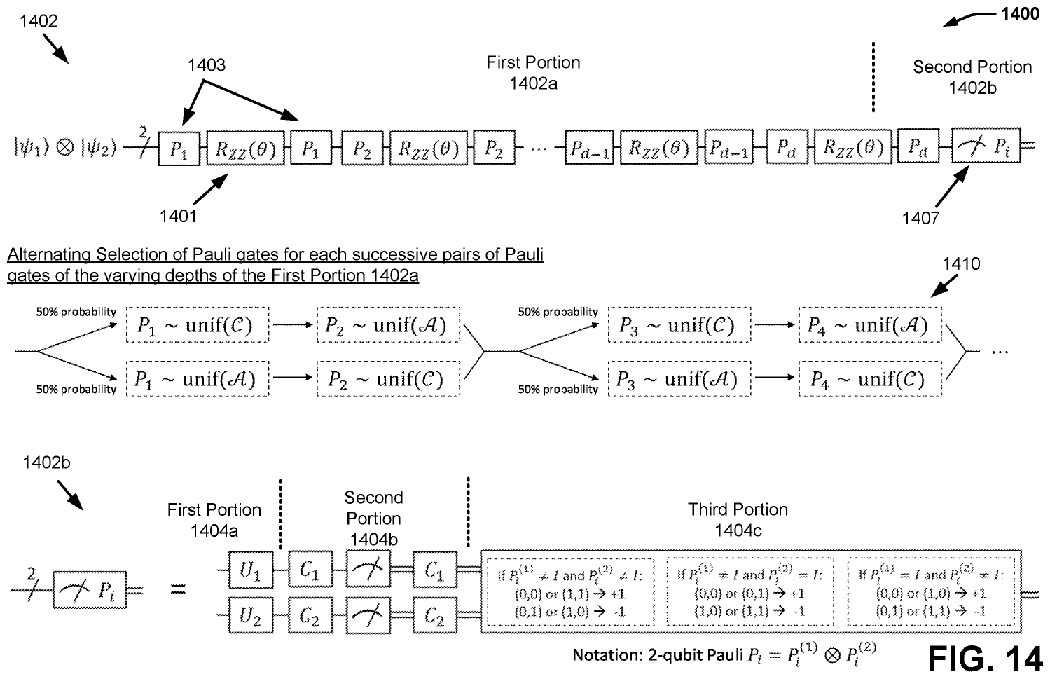

The quantum gate noise characterizing system 1202 can comprise a plurality of components. The components can comprise a memory 1204, processor 1206, bus 1205, state preparation component 1212, quantum circuit generation component 1214, selection component 1216, insertion component 1218, execution component 1220, readout twirling component 1222, primary iteration component 1224, curve fitting component 1226, finalization component 1228 and secondary iteration component 1230. Using these components, the quantum gate noise characterizing system 1202 can perform the shaping of a quantum circuit 1402 (FIG. 14) (e.g., comprising the quantum gate 1401), execution of the quantum circuit 1402 (FIG. 14), and subsequent processing of one or more measurement outcomes 1282 resulting from the execution to obtain one or more elements characterizing noise of the quantum gate 1401. As noted above, the subsequent processing steps can allow for dropping of SPAM noise/error, thus allowing for characterization of noise solely attributable to the quantum gate 1401.

Discussion next turns briefly to the processor 1206, memory 1204 and bus 1205 of the quantum gate noise characterizing system 1202. For example, in one or more embodiments, the quantum gate noise characterizing system 1202 can comprise the processor 1206 (e.g., computer processing unit, microprocessor, classical processor, quantum processor and/or like processor). In one or more embodiments, a component associated with quantum gate noise characterizing system 1202, as described herein with or without reference to the one or more figures of the one or more embodiments, can comprise one or more computer and/or machine readable, writable and/or executable components and/or instructions that can be executed by processor 1206 to provide performance of one or more processes defined by such component and/or instruction. In one or more embodiments, the processor 1206 can comprise the state preparation component 1212, quantum circuit generation component 1214, selection component 1216, insertion component 1218, execution component 1220, readout twirling component 1222, primary iteration component 1224, curve fitting component 1226, finalization component 1228 and secondary iteration component 1230.

In one or more embodiments, the quantum gate noise characterizing system 1202 can comprise the computer-readable memory 1204 that can be operably connected to the processor 1206. The memory 1204 can store computer-executable instructions that, upon execution by the processor 1206, can cause the processor 1206 and/or one or more other components of the quantum gate noise characterizing system 1202 (e.g., state preparation component 1212, quantum circuit generation component 1214, selection component 1216, insertion component 1218, execution component 1220, readout twirling component 1222, primary iteration component 1224, curve fitting component 1226, finalization component 1228 and secondary iteration component 1230) to perform one or more actions. In one or more embodiments, the memory 1204 can store computer-executable components (e.g., state preparation component 1212, quantum circuit generation component 1214, selection component 1216, insertion component 1218, execution component 1220, readout twirling component 1222, primary iteration component 1224, curve fitting component 1226, finalization component 1228 and secondary iteration component 1230).

The quantum gate noise characterizing system 1202 and/or a component thereof as described herein, can be communicatively, electrically, operatively, optically and/or otherwise coupled to one another via a bus 1205. Bus 1205 can comprise one or more of a memory bus, memory controller, peripheral bus, external bus, local bus, quantum bus and/or another type of bus that can employ one or more bus architectures. One or more of these examples of bus 1205 can be employed.

In one or more embodiments, the quantum gate noise characterizing system 1202 can be coupled (e.g., communicatively, electrically, operatively, optically and/or like function) to one or more external systems (e.g., a non-illustrated electrical output production system, one or more output targets and/or an output target controller), sources and/or devices (e.g., classical and/or quantum computing devices, communication devices and/or like devices), such as via a network. In one or more embodiments, one or more of the components of the quantum gate noise characterizing system 1202 and/or of the non-limiting system 1200 can reside in the cloud, and/or can reside locally in a local computing environment (e.g., at a specified location).

In general, the non-limiting system 1200 can employ any suitable method of communication (e.g., electronic, communicative, internet, infrared, fiber, etc.) to provide communication between the quantum gate noise characterizing system 1202 and the quantum system 601.

In addition to the processor 1206 and/or memory 1204 described above, the quantum gate noise characterizing system 202 can comprise one or more computer and/or machine readable, writable and/or executable components and/or instructions that, when executed by processor 1206, can provide performance of one or more operations defined by such component and/or instruction.

Discussion next turns to the additional components of the quantum gate noise characterizing system 1202 (e.g., state preparation component 1212, quantum circuit generation component 1214, selection component 1216, insertion component 1218, execution component 1220, readout twirling component 1222, primary iteration component 1224, curve fitting component 1226, finalization component 1228 and secondary iteration component 1230).

Turning first to the state preparation component 1212, the state preparation component 1212 can generally identify, search, receive, transfer and/or otherwise obtain input data from one or more databases, online resources, entities and/or information caches. The input data can comprise a set of quantum data 1240. This input data can be made available to and/or transmitted to the other components of the quantum gate noise characterizing system 1202.

The set of quantum data 2140 can be obtained from classical data, quantum simulation, quantum transducers, etc. The set of quantum data 1240 can result from and/or be based on output of the quantum system 601 or of another quantum system. In one or more embodiments, classical data can be transformed into quantum data, such as one or more quantum states, such as by the state preparation component 1212.

The state preparation component 1212 further can determine a quantum state for the quantum circuit 1402 based on the rotation axis of the quantum gate 1401 (e.g., relative to step 1302 of the schematic 1300 of FIG. 13). For example, where the quantum gate 1401 has the form R_{AB}(θ), the quantum state can be an AB state. In the running example employed in FIGS. 13, 14 and 5, the quantum gate 1401 is an R_{ZZ}(θ) gate, and thus the state preparation component 1212 can determine the quantum state for the respective quantum circuit 1402 to be a ZZ state. For example, [symbol] a first qubit (relative to an 2-qubit gate) can be prepared in a state |ψ₁ [symbol] , where |ψ₁ [symbol] =|0 [symbol] if Pᵢ⁽¹⁾=I, or where |ψ₁ [symbol] is an eigenstate of Pᵢ⁽¹⁾ with eigenvalue +1 otherwise. A second qubit can be prepared in state |ψ₂ [symbol] , similarly defined for Pᵢ⁽²⁾ in place of Pᵢ⁽¹⁾. Relative to different computational bases and/or different quantum gates R_{AB}(θ), the rules key 511 provided above can be employed. It is noted that the notation Pᵢ=Pᵢ⁽¹⁾⊗Pᵢ⁽²⁾ is employed when needed to refer to the single-qubit Paulis Pᵢ⁽¹⁾ and Pᵢ⁽²⁾ that make up a two-qubit Pauli Pᵢ.

Turning now to FIGS. 13 and 14, along with FIG. 12, based on the quantum gate 1401 and quantum state, the quantum circuit generation component 1214 can generate the quantum circuit 1402 aided by the selection component 1216 and the insertion component 1218, to satisfy Part 1 of the process schematic 1300 of FIG. 13 that can be performed by the quantum gate noise characterizing system 1202.

The quantum circuit generation component 1214 can generate a quantum circuit 1402 comprising a series of one or more instances of a quantum gate of interest 1401. The quantum circuit generation component 1214 further generates the quantum circuit 1402 having each instance of the quantum gate of interest 1401 being bounded by a pair of Pauli gates 1403. Each pair of Pauli gates 1403 comprises two of the same bounding Pauli gate (e.g., P₁, P₂, P₃, etc.).

Part of this process can comprise the quantum circuit generation component 1214 determining a depth level d for the quantum circuit 1402, where the depth level d corresponds directly to the number of instances of the quantum gate of interest 1401 provided in series in the quantum circuit 1402. That is, a depth level d of 2 corresponds to two instances of the quantum gate of interest 1401 being provided in series in the quantum circuit 1402 by the quantum circuit generation component 1214. The depth level d can be selected randomly by the quantum circuit generation component 1214, and/or historical data can be employed, such as historical data defining historical depth level use relative to a depth level sufficient to allow for a desirably low statistical uncertainty of a measurement outcome 1282 from operation of one or more quantum circuits.

It is noted that in one or more embodiments, d can be selected such that a sufficiently large portion of a curve 750 (FIG. 7), to which expectation values 1284 are later fitted, is visible to enable reliable curve fitting. In one or more embodiments, d can be selected adaptively based on error in fitting of expectation values 1284 from previous values of d.

Briefly, it is noted that other depth levels d are to be employed during a second set of iterations of further quantum circuits, as will be explained below relative to the secondary iteration component 1230 and one or more processes performed thereby.

In parallel, subsequent to, and/or prior to the one or more processes of the quantum circuit generation component 1214, the selection component 1216 can determine the bounding Pauli gate to employ for each instance of the quantum gate of interest 1401. That is, the selection component 1216 can select, employing an aspect of randomness, for various instances of the quantum gate of interest 401, the bounding Pauli gate from a selected set of Pauli gates.

More particularly, the selection component 1216 can randomly select, separately for each odd-numbered instance, of the series of one or more instances of the quantum gate of interest, the respective bounding Pauli gate to employ from a first set of Pauli gates C or a second set of Pauli gates A. Whether from the set C or A is an aspect that can be selected randomly with an equal probability (e.g., 50%) for each set. Likewise, the selection component 1216 can randomly select, separately for each even numbered instance, of the series of one or more instances of the quantum gate of interest, the respective bounding Pauli gate from the other of the first set of Pauli gates or the second set of Pauli gates that was not randomly selected for the directly preceding odd-numbered instance in the series of one or more instances of the quantum gate of interest.

For example, turning to the schematic 1410 of FIG. 14, the schematic 1410 visually illustrates the selection of the pairs 403 of Pauli gates P₁, P₂, P₃, etc. for the first portion 1402a of the quantum circuit 1402. The terms “odd” and “even” refer to order of the series of instances of the quantum gate 1401, in a direction from left to right across the quantum circuit 1402 as illustrated at FIG. 14. That is, the first bounding Pauli gate P₁ is selected first. Selection is first made, by the selection component 1216 of the set C or set A of Pauli gates, using uniform probability for each set of Pauli gates. After selection of the set C or set A of Pauli gates, uniform selection of a Pauli gate is made from that selected set. That is, within the selected set, each Pauli gate has an equal probability of being selected.

The set C (e.g., first et) of Pauli gates comprises only Pauli gates that commute (C for commute) with a rotation axis of the quantum gate of interest. The other set A (e.g., second set) of Pauli gates can comprise only Pauli gates that anti-commute (A for anti-commute) with a rotation axis of the quantum gate of interest. Accordingly, relative to the quantum gate of interest 401 being an R_{ZZ}(θ) gate, the set C (e.g., first set) of Pauli gates comprises {I⊗I, Z⊗Z, Z⊗I, I⊗Z, X⊗X, Y⊗Y, Y⊗X, X⊗Y} and the set A comprises {X⊗I, Y⊗ Z, X⊗Z, Y⊗I, I⊗X, Z⊗Y, Z⊗X, I⊗Y}. Relative to different computational bases and/or different quantum gates R_{AB}(θ), the rules key 511 provided above can be employed.

To summarize the one or more processes of the selection component 1216 for the bounding Pauli gates Pᵢ, P₂, P₃, and P₄, the set of Pauli gates is selected first for the bounding Pauli gate P₁ (an odd gate) and then the set of Pauli gates for the second bounding Pauli gate P₂ (an even gate) is whichever set was not chosen for the bounding Pauli gate P₁. Likewise, the set of Pauli gates is selected first for the bounding Pauli gate P₃ (an odd gate) and then the set of Pauli gates for the fourth bounding Pauli gate P₄ (an even gate) depends therefrom (e.g., is whichever set was not chosen for the bounding Pauli gate P).

It is noted that any selection of a set of Pauli gates or any selection of a Pauli gate from a set of Pauli gates can be performed at least partially parallel with any other selection, and need not necessarily be performed in any order of the series of instances other than each respective odd-numbered instance have a set of Pauli gates selected prior to a set of Pauli gates being selected for the respective even-numbered instance that immediately follows the respective odd-numbered instance (e.g., because the set of Pauli gates being selected for the respective even-numbered instance directly depends upon the set of Pauli gates selected for the respective prior odd-numbered instance).

Further, again, after selection of any set of Pauli gates, the selection of a Pauli gate therefrom is performed randomly, based on a uniform probability distribution, from the set of Pauli gates.

Accordingly, the one or more processes performed by the quantum circuit generation component 1214 and the selection component 1216 can allow for generation of the second portion 4102b of the quantum circuit 1402.

Also in parallel, subsequent to, and/or prior to the one or more processes of the quantum circuit generation component 1214 and/or selection component 1216, the insertion component 1218 can select, for use relative to the quantum circuit 1402, a state-based Pauli gate Pᵢ. The insertion component 1218 can select the state-based Pauli gate Pᵢ from a set of Pauli gates that includes Pauli gates that both commute or anti-commute with the rotation axis of the quantum gate of interest. For example, relative to the quantum gate 1401 being an R_{ZZ}(θ) gate, the set of Pauli gates that either commute or anti-commute with ZZ are provided for Pᵢ(e.g., at row Pᵢ) at batches 1-8 of Table 550.

It is noted that batches 1-4 for both Pᵢ and Pⱼ commute with ZZ and that batches 5-8 for both Pᵢ and Pⱼ anti-commute with ZZ. Relative to different computational bases and/or different quantum gates R_{AB}(θ), the rules key 511 provided above can be employed.

More particularly, the state-based Pauli gate Pᵢ selected is the state-based Pauli gate Pᵢ corresponding to the quantum state determined by the state preparation component 1212. That is, the quantum state is selected by the state preparation component 1212 as one which is a +1 eigenstate of Pᵢ. Accordingly the state-based Pauli gate Pᵢ is not randomly selected, but is selected as the one from batches 1-8 that corresponds to the quantum state selected by the state preparation component 1212.

The state-based Pauli gate selected is to be measured using readout twirling (e.g. at the second portion 1402b of the quantum circuit 1402) after execution of the first portion 1402a of the quantum circuit 1402. In connection with selection, the insertion component 1218 can insert the second portion 4102b into the quantum circuit 1402, and/or can provide information corresponding to the quantum circuit 1402 to the execution component 1220, to perform readout twirling of the Pauli gate Pᵢ subsequent to execution of the first portion 1402a of the quantum circuit 1402.

Accordingly, the one or more processes performed by the quantum circuit generation component 1214, the selection component 1216 and the insertion component 1218 can allow for generation of a complete quantum circuit 1402 by the quantum gate noise characterizing system 1202.

Using the completed quantum circuit 1402, the execution component 1220 can execute the completed quantum circuit 1402 at a quantum processor 606, such as of the quantum system 601 by directing the quantum system 601 to execute the quantum circuit 1402. For example, the execution component 1220 can send a quantum job request 624 (FIG. 6) to the quantum system 601 or can make the quantum job request 624 available to the quantum system 601 for the quantum system 601 to obtain the quantum job request 624.

In connection with the one or more processes performed by the execution component 1220, the readout twirling component 1222 can provide further information relative to the second portion 402b of the quantum circuit 1402 (e.g., defining the second portion 1402b) and/or can direct performance of readout twirling of the state-based Pauli gate Pᵢ by the quantum system 601 (e.g., at the quantum processor 606).

It is noted that each of the state preparation component 1212, quantum circuit generation component 1214, selection component 1216, insertion component 1218, execution component 1220, readout twirling component 1222 can operate at a classical system of and/or comprising the quantum gate noise characterizing system 1202.

Accordingly, as a result of execution of the quantum circuit 1402 at the quantum system 601, comprising execution of the first portion 1402a of the quantum circuit 1402 and subsequent readout twirling of the state-based Pauli gate Pᵢ relative to the second portion 1402b of the quantum circuit 1402, a measurement outcome 1282 (e.g., quantum measurement readout 620) can be obtained, such as by the primary iteration component 1224 of the quantum gate noise characterizing system 1202, from the quantum system 601.

Next, prior to discussion of use of the measurement outcome 1282 of each iteration of the quantum circuit 1402, and prior to the discussion of determination of a resultant expectation value 1284 and subsequent processing of the measurement outcome 1282, discussion first turns to the execution of the quantum circuit 402 at the quantum system 601 and to the readout twirling performed by the quantum system 601 relative to the quantum circuit 1402. That is, the operation of the quantum system 601 can allow for the output of the quantum measurement readouts 1282 and thus allow for the determination of an individual expectation value f(d) from each iteration.

Turning to FIG. 6, one or more embodiments described herein can include one or more devices, systems and/or apparatuses that can provide a process to generate one or more waveforms for a quantum-based operation (e.g., using a quantum device), such as for operating one or more qubits of a quantum device. Accordingly, at FIG. 6, illustrated is a block diagram of an example, non-limiting system 600 that can at least partially facilitate such a process. While referring here to one or more processes, facilitations and/or uses of the non-limiting system 600, description provided herein, both above and below, also can be relevant to one or more other non-limiting systems described herein, such as the non-limiting systems 1100 and/or 1200.

As illustrated at FIG. 6, the non-limiting system 600 can comprise a quantum system 601 that can be employed with or separate from the classical systems 1102/1202.

Generally, the quantum system 601 (e.g., quantum computer system, superconducting quantum computer system and/or the like) can employ quantum algorithms and/or quantum circuitry, including computing components and/or devices, to perform quantum operations and/or functions on input data to produce results that can be output to an entity. The quantum circuitry can comprise quantum bits (qubits), such as multi-bit qubits, physical circuit level components, high level components and/or functions. The quantum circuitry can comprise physical pulses that can be structured (e.g., arranged and/or designed) to perform desired quantum functions and/or computations on data (e.g., input data and/or intermediate data derived from input data) to produce one or more quantum results as an output. The quantum results, e.g., quantum measurement readout 620, can be responsive to the quantum job request 624 and associated input data and can be based at least in part on the input data, quantum functions and/or quantum computations.

In one or more embodiments, the quantum system 601 can comprise components, such as a quantum operation component 603, a quantum processor 606, pulse component 610 (e.g., a waveform generator) and/or a readout electronics 612 (e.g., readout component). In one or more other embodiments, the readout electronics 612 can be comprised at least partially by the classical system 11021/202 and/or be external to the quantum system 601. The quantum processor 606 can comprise one or more, such as plural, qubits 607. Individual qubits 607A, 607B and 607C, for example, can be fixed frequency and/or single junction qubits, such as transmon qubits.

In one or more embodiments, a memory 616 and/or processor 614 can be associated with the quantum operation component 603, where suitable. The processor 614 can be any suitable processor. The processor 614 can generate one or more instructions for controlling the one or more processes of the quantum operation component 603.

The quantum operation component 603 can obtain (e.g., download, receive, search for and/or the like) a quantum job request 624 requesting execution of one or more quantum programs and/or a physical qubit layout. The quantum job request 624 can be provided in any suitable format, such as a text format, binary format and/or another suitable format. In one or more embodiments, the quantum job request 624 can be obtained by a component other than of the quantum system 601, such as a by a component of the classical systems 1102/1202.

The quantum operation component 603 can determine mapping of one or more quantum logic circuits for executing a quantum program. In one or more embodiments, the quantum operation component 603 and/or quantum processor 606 can direct the waveform generator 610 to generate one or more pulses, tones, waveforms and/or the like to affect one or more qubits 607, such as in response to a quantum job request 624.

The waveform generator 610 can generally cause the quantum processor 606 to perform one or more quantum processes, calculations and/or measurements by creating a suitable electro-magnetic signal. For example, the waveform generator 610 can operate one or more qubit effectors, such as qubit oscillators, harmonic oscillators, pulse generators and/or the like to cause one or more pulses to stimulate and/or manipulate the state(s) of the one or more qubits 607 comprised by the quantum system 601.

The quantum processor 606 and a portion or all of the waveform generator 610 can be contained in a cryogenic environment, such as generated by a cryogenic environment 617, such as effected by a dilution refrigerator. Indeed, a signal can be generated by the waveform generator 610 to affect one or more of the plurality of qubits 607. Where the plurality of qubits 607 are superconducting qubits, cryogenic temperatures, such as about 4K or lower, can be employed for function of these physical qubits. Accordingly, one or more elements of the readout electronics 612 also can be constructed to perform at such cryogenic temperatures.

The readout electronics 612, or at least a portion thereof, can be contained in the cryogenic environment 617, such as for reading a state, frequency and/or other characteristic of qubit, excited, decaying or otherwise.

It is noted that the aforementioned description(s) refer(s) to the operation of a single set of instructions run on a single qubit. However, scaling can be achieved. For example, instructions can be calculated, transmitted, employed and/or otherwise used relative to one or more qubits (e.g., non-neighbor qubits) in parallel with one another, one or more quantum circuits in parallel with one another, and/or one or more qubit mappings in parallel with one another.

In connection with the execution of the quantum circuit 402 by the quantum processor 606 of the quantum system 601, the quantum processor 606, such as directed by the quantum operation component 603, can direct performance of readout twirling of the state-based Pauli gate P; based on the prior direction by the readout twirling component 1222.

For example, for completeness, direction turns briefly to the detailed illustration of the portion 1402c of the quantum circuit 1402 provided at FIG. 14.

For readout twirling, the quantum systems 601 and/or the readout twirling component 1222 can first select C₁ and C₂ independently (e.g., first portion 1404a and second portion 1404b) and uniformly at random from {I, X} in each repetition, where X on a classical register denotes a NOT gate. It is noted that a change of basis can be performed depending on a rotation axis of the quantum gate of interest 1401 and on a computational basis of the quantum system 601. That is, for an 2-qubit preparation relative to the quantum gate R_{ZZ}(θ), the quantum system 601 can apply a gate U₁ to qubit 1 that rotates eigenstates of Pᵢ⁽¹⁾ into corresponding eigenstates of Z. If Pᵢ⁽¹⁾=I use U₁=I. Likewise, apply U₂ to qubit 2, similarly defined for Pᵢ⁽²⁾ in place of Pᵢ⁽¹⁾.

To conduct the subsequent measuring of n qubits using readout twirling, the quantum system 601 can, for each qubit, apply an X gate with 50% probability, then measure the qubit, and if an X gate had been applied, also apply a classical NOT gate to the resulting bit.

Based on an outcome of the readout twirling of the n qubits, the measurement outcome 1282 can be determined based on the rules set forth at third portion 1404c at FIG. 4. (e.g., as +1 or −1). That is, measuring Pᵢ yields an outcome of +1 if the quantum state is found to be an eigenvector of Pᵢ with eigenvalue +1, or an outcome of −1 if it is found to be an eigenvector of Pᵢ with eigenvalue −1. This measurement of Pᵢ can be performed by measuring the qubits individually and processing the resulting bits. The processing step depends on whether Pᵢ comprises an I on any qubit as this determines its eigenvectors. Again, relative to a different quantum gate R_{AB}(θ), the rules key 511 discussed above can be employed.

As a result, a measurement outcome 1282 (e.g., quantum measurement readout 620) output by the readout electronics 612 can be based on execution of portions 1402a of the quantum circuit 1402 and on subsequent readout twirling performed relative to the portion 1402b of the quantum circuit 1402.

Turning back to FIGS. 12 to 14, and also now to FIG. 7, description of one or more processes performed post-quantum execution by the quantum gate noise characterizing system 1202 (e.g., by the curve fitting component 1226, finalization component 1228, primary iteration component 1224, secondary iteration component 1230 and state preparation component 1212) are now described.

Generally, based on execution of the completed quantum circuit at a quantum system (e.g., the quantum system 601), a measurement outcome 1182 can be obtained. The finalization component 1228 can employ the measurement outcome 1282 to generate an expectation value 1284 (f(d)), one or more noise characterizing elements 754 and/or one or more Pauli transfer matrix (PTM) elements 1286. The expectation value is generated by taking the running average of the +1 measurement outcomes until the statistical fluctuations become acceptably small, in other words, the fraction of outcomes equal to +1 minus the fraction of outcomes equal to −1. Such expectation values are computed for different circuit depths d, then fit to an appropriate curve. The resulting fit parameters are then processed to give one or more PTM elements.

That is, based on one or more parameters of a curve 750, to which an expectation value 1284, resulting from the measurement outcome 1282, is fitted, the finalization component 1228 can generate an element characterizing noise of the quantum gate of interest. This element can be and/or can be employed to subsequently generate, by the finalization component 1228, one or more PTM elements 1286 for the PTM of the quantum gate of interest. That is, the finalization component 1228 can provide for generation of the one or more PTM elements 1286 based on the measurement outcome 1282.

In connection with the above general description of post-quantum circuit execution, direction turns first to FIGS. 13 and 7, and to primary iterations, secondary iterations and tertiary iterations of the one or more processes performed by the quantum gate noise characterizing system 1202. These various iterations can be performed based on direction by the primary iteration component 1224, secondary iteration component 1230 and state preparation component 1212, respectively.

For example, primary iterations of the quantum gate noise characterizing (QGNC) system 1202 can comprise employing step 1308 to repeat the above-described processes until statistical uncertainty in a final expectation value 1284 (f(d)) obtained from aggregation (e.g., averaging) of a plurality of expectation values 1284 (e.g., generated by the finalization component 1228 from respective measurement outcomes 1282) becomes acceptably small.

More particularly, the primary iteration component 1224 can direct the quantum circuit generation component 1214, selection component 1216, insertion component 1218, execution component 1220, readout twirling component 1222 and finalization component 1228 to perform their respective operations for one or more additional quantum circuits 1402 having a series of a same number of one or more instances of the quantum gate of interest (e.g., a same d) as the quantum circuit 1402.

These one or more primary iterations can result in output (e.g., from steps 1308a) of a plurality of measurement outcomes 1282 and resulting expectation values 1284 for a same d. It is noted that for each one or more additional quantum circuits 1402, the processes performed by the selection component 1216 and insertion component 1218 include re-selecting the Pauli gates P₁, P₂, P₃, etc. and Pᵢ for each different one of the one or more additional quantum circuits 1402.

The number of primary iterations directed by the primary iteration component 1224 can be driven by averaging of the expectation values 1284, at any selected frequency (e.g., after each expectation value 1284 is output for a running average, after more than one expectation values 1284 are output, based on the dynamically changing statistical uncertainty in an averaged f(d), etc.) and determination (e.g., by the finalization component 1228) of a statistical uncertainty in the averaged f(d). That is, the finalization component 1228 can determine whether the statistical uncertainty in the averaged expectation value 1284 satisfies (e.g., meets and/or exceeds) a selected threshold, such as an uncertainty acceptability threshold 720. The threshold 720 can be determined by the finalization component 1228, another component of the QGNC system 1202 and/or by an administrating entity associated with the QGNC system 1202.

As a result of these one or more primary iterations, the finalization component 1228 can average the resulting set of expectation values 1284, determine that the threshold 720 is satisfied, and output a final resultant expectation value 1284 (e.g., step 1308b) relative to a single depth d.

The curve fitting component 1226 can fit the resultant expectation value 1284 to a curve 750 and/or such fitting can be performed when one or more resultant expectation values 1284 from one or more secondary iterations are performed (e.g., step 1310). The curve 750 can be a decaying exponential curve having the function α r^{d}, having amplitude a, decay rate r and depth d. That is, an oscillating, exponentially decaying shape would be formed, visually, when the points f(d) (final expectation values 1284 from each value of d) are all plotted against d.

It is noted that any suitable curve-fitting algorithm can be employed. An initial guess for the free parameters of amplitude a and decay rate r that can be employed can be a=r=1, which are ideal fit values that would be theoretically obtained in the absence of noise.

The one or more secondary iterations can be directed by the secondary iteration component 1230 for different values of d (e.g., step 1306), but for the same quantum state of the quantum circuit previously determined (e.g., relative to the same batch of Table 550). That is, the secondary iteration component 1230 can direct the quantum circuit generation component 1214, selection component 1216, insertion component 1218, execution component 1220, readout twirling component 1222, finalization component 1228 and primary iteration component 1224 to perform their respective operations for one or more further quantum circuits 1402 each having a series of a second same number of one or more instances of the quantum gate of interest as the quantum circuit, where the second same number (e.g., d) is different than the same number (e.g., the d of a prior set of one or more primary iterations).

As such, a set of one or more primary iterations can be directed for each one or more secondary iterations directed. That is, for each different value of d, a resultant expectation value 1284 can be determined.

As a result, these plural expectation values 1284 can be fit, by the curve fitting component 1226, to the same curve 750.

The number of secondary iterations directed by the secondary iteration component 1230 can be driven by whether enough expectation values 1284 are fit to the curve 750 to fully define the curve 750 (e.g., step 1310). That is, “fully defined” can be determined based on a respective statistical uncertainty associated with one or more curve parameters 752 (e.g., decay rate) defined by the curve 750, such as based on whether a respective uncertainty acceptability threshold has been satisfied. If not yest satisfied, and/or if the curve 750 is not fully defined to one or more selected specifications, additional secondary iterations can be directed by the secondary iteration component 1230.

As a result of definition of the curve 750, from performance of plural secondary iterations, the one or more curve parameters 752 can be determined, thus resulting in generation of one or more Pauli transfer matrix (PTM) elements 1286 for the quantum gate of interest 1401, where the one or more PTM elements 1286 are those elements corresponding to the same quantum state identified above by the state preparation component 1212, prior to any one or more sets of primary iterations being performed. For example, these one or more PTM elements 1286 can be a gᵢᵢ, gⱼⱼ, gᵢⱼ and/or gᵢⱼ relative to a quantum channel G (e.g., relative to a quantum gate of interest G).

As used herein, the term “quantum channel” can describe all possible physical operation on a quantum system, which can comprise at least one quantum computer. Mathematically, a quantum channel C can be a completely positive, trace-preserving linear function. The quantum channel C can take a density matrix ρ as input and return another density matrix ρ′=C(p), through operation of a quantum processor. The quantum channel C can describe a unitary operation (e.g., a quantum gate) or any non-unitary operation, such as an imperfect version of a gate that can be performed in available hardware of an available quantum system (e.g., available quantum processor).

For example, using the decay rate r from the function α r^{d}, the finalization component 1228 can determine that the one or more PTM elements 1286 can be a gᵢᵢ, gⱼⱼ, gᵢⱼ and/or gᵢⱼ based on Equation 4, provided below (e.g., step 1312).

$${g}_{ii}^{2} - {g}_{ij} \times {g}_{ji} = {r}^{2} . \qquad Equation 4$$

It is noted that amplitude a is the only fit parameter that depends on SPAM noise, and this parameter gets discarded (e.g., not employed by Equation 4). As such, the PTM element results are not biased by SPAM noise.

The noise characterization element gᵢᵢ²−gᵢⱼ×gⱼᵢ (754) can be employed, such as by the finalization component 1228 to determine one or more PTM elements 1286 can be a gᵢᵢ, gⱼⱼ, gᵢⱼ and/or gᵢⱼ. It is noted that the noise characterization element gᵢᵢ²−gᵢⱼ×gⱼᵢ (754) does not provide isolated PTM elements gᵢᵢ, gⱼⱼ, g^{ij} and/or gᵢⱼ, but rather a fixed combination of them (e.g., either gᵢᵢ²−gᵢⱼ×gⱼᵢ or gᵢᵢ²−gᵢⱼ×gⱼᵢ, with origination of the second element gⱼⱼ²−gᵢⱼ×gⱼᵢ to be explained below).

To isolate the PTM elements 1286 from one another, one or more of the noise characterization elements 754 can be combined with those from a complementary technique, such as by the finalization component 1228. For instance, gᵢⱼ×gⱼᵢ can be determined by the finalization component 1228 with the technique from the one or more embodiments related to FIGS. 1-10 above related to characterizing noisy non-Clifford gates through partial Pauli twirling to isolate Gᵢᵢ and Gⱼⱼ.

To generate one or more different PTM elements 1286 (e.g., different values for gᵢᵢ, gⱼⱼ, gᵢⱼ and/or gᵢⱼ) for one or more different quantum states (e.g., for different ones of the batches 1 to 8 of Table 550), and still relative to the same quantum gate of interest 1401, one or more tertiary iterations can be performed, as directed by the state preparation component 1212.

For example, the state preparation component 1212 can select a different quantum state that either commutes or anti-commutes with the rotation axis of the quantum gate of interest 1401 (e.g., a different one of the batches 1 to 8 of Table 550). It is noted that a tertiary iteration, comprising a set of secondary iterations, which each in turn comprise a set of primary iterations, is performed generally only once per relative quantum state (e.g., here, eight quantum states either commute or anti-commute with the rotation axis of the quantum gate of interest 1401).

Accordingly, the state preparation component 1212 can determine (e.g., at step 1314) whether an additional tertiary operation is to be directed based on the one or more quantum states already employed at step 1304 for either Pᵢ or Pⱼ. Although, in one or more embodiments, not all quantum states need to be employed for each of Pᵢ or Pⱼ. Additionally, or alternatively, in one or more embodiments, not all quantum states need to be employed for Pᵢ and/or not all quantum states need to be employed for Pⱼ, depending on the PTM elements 1286 desired to be generated.

Put another way, iteration by way of different tertiary operations is by way of iteration over pairs (Pᵢ, Pⱼ) of 2-qubit Paulis where Pⱼ∝(Z⊗Z)Pᵢ, where the quantum gate 401 is an R_{ZZ}(θ) gate and by way of the swapping of indices i↔j for additional iteration over pairs (Pᵢ, Pⱼ) of 2-qubit Paulis where Pⱼ∝(Z⊗Z)Pᵢ.

That is, the state preparation component 1212 can direct one or more additional tertiary operations with use of Pⱼ, e.g., swapping indices i↔j in each of the steps 1306 to 1312, for any one or more same or different quantum states employed with use of Pᵢ. For example, the state-based Pauli gate selected by the insertion component 1218 would be Pⱼ instead of Pᵢ. Readout twirling would thus be directed by the readout twirling component 1222 to be performed for Pⱼ instead of Pᵢ. Additionally, the noise characterizing element 754 determined based on the one or more processes performed by the finalization component 1228 and the curve fitting component 1226 would be gⱼⱼ²−gᵢⱼ×gⱼᵢ instead of gᵢᵢ²−gᵢⱼ×gⱼᵢ.

Then, relative to the one or more additional tertiary operations directed by the state preparation component 1212, as a result of further performance of the QGNC system 1202 and quantum system 601, the PTM for the quantum gate of interest 1401 can be further defined (e.g., at step 1316), thus further characterizing noise of the quantum gate of interest 1401 without characterization of SPAM noise related to operation of the quantum gate of interest 1401.

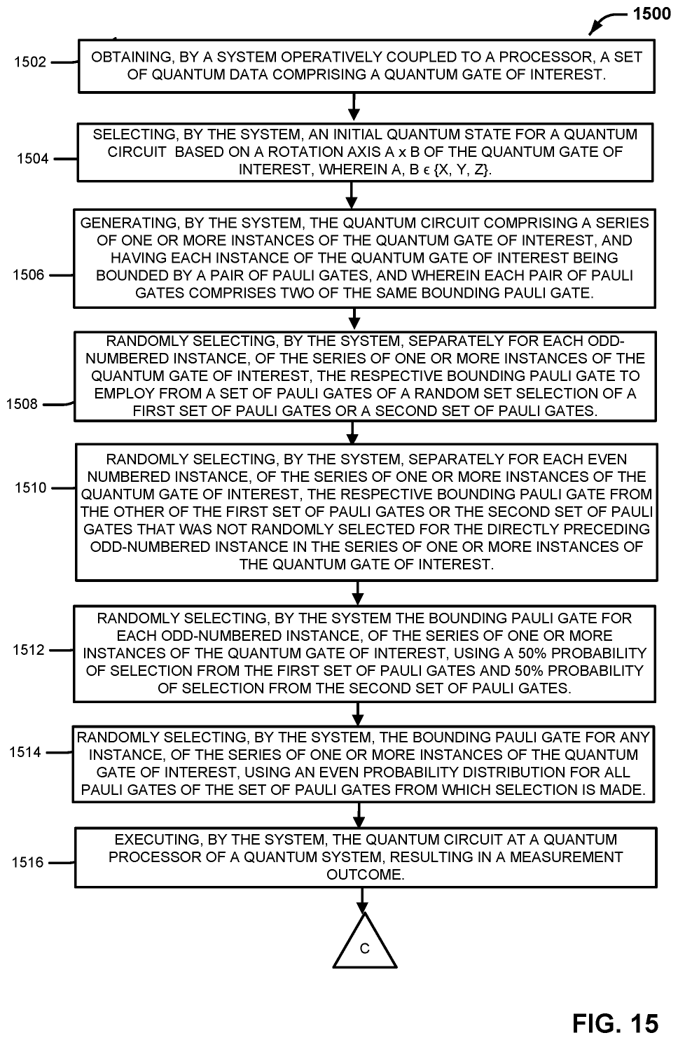

As a summary, referring next to FIGS. 15-17, illustrated is a flow diagram of an example, non-limiting method 1500 that can provide a process to obtain an error mitigated measurement outcome of operation of a quantum processor, in accordance with one or more embodiments described herein, such as the non-limiting system 1200 of FIG. 12. While the non-limiting method 1500 is described relative to the non-limiting system 1200 of FIG. 12, the non-limiting method 1500 can be applicable also to other systems described herein, such as the non-limiting system 1100 of FIG. 11. Repetitive description of like elements and/or processes employed in respective embodiments is omitted for sake of brevity.

At 1502, the non-limiting method 1500 can comprise obtaining, by a system operatively coupled to a processor (e.g., state preparation component 1212), a set of quantum data (e.g., set of quantum data 1240) comprising a quantum gate of interest (e.g., quantum gate of interest 1401).

At 1504, the non-limiting method 1500 can comprise selecting, by the system (e.g., state preparation component 1212), an initial quantum state for a quantum circuit (e.g., quantum circuit 1402) based on a rotation axis A⊗B of the quantum gate of interest, wherein A, B∈{X,Y,Z}.

At 1506, the non-limiting method 1500 can comprise generating, by the system (e.g., quantum circuit generation component 1214), the quantum circuit comprising a series of one or more instances of the quantum gate of interest, and having each instance of the quantum gate of interest being bounded by a pair of Pauli gates (e.g., pair 1403 of Pauli gates), and wherein each pair of Pauli gates comprises two of the same bounding Pauli gate (e.g., as defined by schematic 1410).

At 1508, the non-limiting method 1500 can comprise randomly selecting, by the system (e.g., selection component 1216), separately for each odd-numbered instance, of the series of one or more instances of the quantum gate of interest, the respective bounding Pauli gate to employ from a set of Pauli gates of a random set selection of a first set of Pauli gates (e.g., unif(C) of set 510) or a second set of Pauli gates (e.g., unif(A) of set 510).

At 1510, the non-limiting method 1500 can comprise randomly selecting, by the system (e.g., selection component 1216), separately for each even numbered instance, of the series of one or more instances of the quantum gate of interest, the respective bounding Pauli gate from the other of the first set of Pauli gates or the second set of Pauli gates that was not randomly selected for the directly preceding odd-numbered instance in the series of one or more instances of the quantum gate of interest.

In one or more embodiments, each of the Pauli gates of the first set of Pauli gates commute with a rotation axis of the quantum gate of interest, and each of the Pauli gates of the second set of Pauli gates anti-commute with the rotation axis of the quantum gate of interest.

At 1512, the non-limiting method 1500 can comprise randomly selecting, by the system (e.g., selection component 1216) the bounding Pauli gate for each odd-numbered instance, of the series of one or more instances of the quantum gate of interest, using a 50% probability of selection from the first set of Pauli gates and 50% probability of selection from the second set of Pauli gates.

At 1514, the non-limiting method 1500 can comprise randomly selecting, by the system (e.g., selection component 1216), the bounding Pauli gate for any instance, of the series of one or more instances of the quantum gate of interest, using an even probability distribution for all Pauli gates of the set of Pauli gates from which selection is made.

At 1516, the non-limiting method 1500 can comprise executing, by the system (e.g., execution component 1220), the quantum circuit at a quantum processor (e.g., quantum processor 606) of a quantum system (e.g., quantum system 601), resulting in a measurement outcome (e.g., measurement outcome 1282).

At 1518, the non-limiting method 1500 can comprise, selecting, by the system (e.g., insertion component 1218), a state-based Pauli gate as Pᵢ or Pⱼ from a state-based set of Pauli gates (see, e.g., Table 550) where Pᵢ and Pⱼ∝(A⊗B)Pᵢ both commute or anti-commute with a rotation axis A⊗B of the quantum gate of interest, wherein A, B∈{X, Y, Z}.

At 1520, the non-limiting method 1500 can comprise directing, by the system (e.g., readout twirling component 1222), performance of readout twirling of that state-based Pauli gate at the quantum system to result in output of the measurement outcome by the quantum system.

At 1522, the non-limiting method 1500 can comprise, based on one or more parameters (e.g., curve parameters 752) of a curve (e.g., curve 750), to which an expectation value (e.g., expectation value 1284), resulting from the measurement outcome of execution of the quantum circuit at the quantum system, is fitted, generating, by the system (e.g., finalization component 1228), an element (e.g., noise characterization element 754) characterizing noise of the quantum gate of interest.

At 1524, the non-limiting method 1500 can comprise generating, by the system (e.g., finalization component 1228), the element absent employment of an amplitude (a) parameter of the curve, resulting in the element being non-biased by state preparation and measurement noise (SPAM) related to operation of the quantum gate of interest.

At 1526, the non-limiting method 1500 can comprise determining, by the system (e.g., primary iteration component 1224), whether statistical uncertainty in the expectation value (e.g., expectation value 1284; f(d)) satisfies an uncertainty acceptability threshold (e.g., uncertainty acceptability threshold 720). If yes, the non-limiting method 1500 can proceed to step 1532. If no, the non-limiting method 800 can proceed to step 1528.

At 1528, the non-limiting method 1500 can comprise, directing, by the system (e.g., primary iteration component 1224), the quantum circuit generation component, selection component and finalization component to perform their respective operations for one or more additional quantum circuits each having a series of a same number of one or more instances of the quantum gate of interest as the quantum circuit.

At 1530, the non-limiting method 1500 can comprise, fitting, by the system (e.g., curve fitting component 1226), the expectation value, and an additional one or more expectation values resulting from the additional quantum circuits, to the curve being a decaying exponential curve based on a selected curve-fitting process.

At 1532, the non-limiting method 1500 can comprise directing, by the system (e.g., secondary iteration component 1230), the quantum circuit generation component, selection component, finalization component and primary iteration component to perform their respective operations for one or more further quantum circuits each having a series of a second same number of one or more instances of the quantum gate of interest as the quantum circuit.

At 1534, the non-limiting method 1500 can comprise fitting, by the system (e.g., curve fitting component 1226), expectation values resulting from the one or more further quantum circuits, to the curve based on the selected curve-fitting process.

At 1536, the non-limiting method 1500 can comprise selecting, by the system (e.g., state preparation component 1212), a second quantum state, different from a first quantum state of the quantum circuit, and based on a rotation axis A⊗B of the quantum gate of interest, wherein A, B∈{X,Y,Z}.

At 1538, the non-limiting method 1500 can comprise directing, by the system (e.g., state preparation component 1212), the quantum circuit generation component, selection component, finalization component, primary iteration component and secondary iteration component to perform their respective operations relative to the second initial quantum state.

Direction next turns to additional underlying support, such as proofs, for one or more of the concepts and/or processes discussed above.

First, relative to readout twirling of the state-based Pauli gate Pi, if the measurement readout for the expectation value of a Pauli operator Pᵢ for a quantum state ρ were perfect, the measured value would approach the true value [symbol] Pᵢ [symbol] =tr(Pᵢρ) in the limit of many shots (and would equal [symbol] Pᵢ [symbol] on average for any finite number of shots). If the readout is imperfect, the measured value could deviate from the true value in complicated ways, even asymptotically. However, if readout twirling is employed, as directed by the readout twirling component 1222 and as at least partially prepared for by the insertion component 1218, the measured expectation value is guaranteed to be βᵢ [symbol] Pᵢ [symbol] on average (or asymptotically) for some coefficient βᵢ that depends on Pᵢ but not on ρ.

As proof of concept of the above described use of readout twirling, where measurement is ultimately performed in the computational basis, it can suffice to consider Paulis Pᵢ composed only of Zs and Is.

Let

$$W = {( \begin{matrix}1 & 1 \\ 1 & - 1\end{matrix} )}^{⊗ n}$$

be a 2ⁿ dimensional Walsh-Hadamard matrix, then W²=2n I.

Let Xₖ=X^{k}^{₁}⊗ . . . ⊗X^{k}^{ₙ} and [symbol] ₖ=Z^{k}^{₁}⊗ . . . ⊗Z^{k}^{ₙ}≡diag(\vec{z}ₖ) for k∈{0,1}ⁿ, then \vec{z}ₖ=Wêₖ where êₖ is a standard basis vector.

For an n-qubit quantum state ρ, define the vector \vec{p} of ideal measurement probabilities pₖ= [symbol] k|ρ|k [symbol] , and a vector \vec{v} of ideal expectation values vₖ=tr( [symbol] ₖρ). Then, standard algebra can give \vec{v}=W\vec{p}.

Readout errors can be described by a stochastic matrix A, where Aᵢⱼ is the probability of a j outcome being misclassified as an i. Such errors can result in measurement probabilities of \vec{p}′=A\vec{p} and expectation values of \vec{v}′=2⁻ⁿWAW \vec{v}.

Us of readout twirling replaces A with A″=2⁻ⁿ Σ_{k∈{0,1}}_{ⁿ}XₖAXₖ. Using the identities above, plus diag(\vec{x})Mdiag(\vec{x})=(\vec{x}\vec{x}^{T})∘M for any matrix M and vector \vec{x}, where ∘ denotes the Hadamard i.e., element-wise) product, and Σₖ êₖêₖ=I, A″ can be rewritten as:

$${A}^{″} = {2}^{- 3 n} {\sum }_{k} ( W {k}_{} W ) A ( W {k}_{} W ) = {2}^{- 3 n} W [ ( {\sum }_{k} {\vec{z}}_{k} {\vec{z}}_{k}^{T} ) ∘ ( WAW ) ] W = {2}^{- 2 n} W [ I ∘ ( WAW ) ] W .$$

The resulting, erroneous expectation values are therefore \vec{v}″=2⁻ⁿ[I∘(WAW)]\vec{v}, i.e., vₖ″=βₖ [symbol] [symbol] ₖ [symbol] where βₖ=2⁻ⁿ(WAW)ₖₖ.

Second, relative to the one or more processes performed by the selection component 1216, consider a Pauli Pₖ drawn uniformly at random from [symbol] or from [symbol] (the sets of 2-qubit Paulis that commute or anti-commute with Z⊗Z, respectively). The overall Pauli transfer matrix (PTM) for Pₖ, followed by a noisy R_{ZZ}(θ), then another Pₖ, is block-diagonal with 2×2 blocks labelled by indices i and j such that i=j or Pⱼ∝(Z⊗Z)Pᵢ. Depending on whether Pₖ is sampled from [symbol] or [symbol] , these blocks have the form

$${B}_{𝒞} = ( \begin{matrix}{G}_{ii} & {G}_{ij} \\ {G}_{ji} & {G}_{jj}\end{matrix} ) or {B}_{𝒜} = ( \begin{matrix}{G}_{ii} & - {G}_{ij} \\ - {G}_{ji} & {G}_{jj}\end{matrix} ) ,$$

respectively, where {Gᵢⱼ} are the PTM elements of the noisy R_{ZZ}(θ) gate.

As proof of concept of the above, denote the quantum channel for a noisy R_{ZZ}(θ) gate as [symbol] . Adding random Paulis Pₖ˜unif(C) before and after gives an overall channel

$$ρ ↦ \frac{1}{8} {\sum }_{{P}_{k} ∈ 𝒞} {P}_{k} 𝒢 ( {P}_{k} ρ {P}_{k} ) {P}_{k}$$

whose (i,j)^{th} PTM element is

$$tr [ {P}_{i} \frac{1}{8} {\sum }_{{P}_{k} ∈ 𝒞} {P}_{k} 𝒢 ( {P}_{k} {P}_{j} {P}_{k} ) {P}_{k} ] / 4 = \frac{1}{8} {\sum }_{{P}_{k} ∈ 𝒞} tr [ {P}_{k} {P}_{i} {P}_{k} 𝒢 ( {P}_{k} {P}_{j} {P}_{k} ) ] / 4 = ( \frac{1}{8} {\sum }_{k \vert {P}_{k} ∈ 𝒞} {s}_{ik} {s}_{kj} ) {G}_{ij} ,$$

where sᵢₖ=1 (or −1) if Pᵢ and Pₖ commute (anti-commute). Direct computation shows that the last bracketed sum above equals 1 if i=j or if PᵢPⱼ∝Z⊗Z, and 0 otherwise, giving a block-diagonal PTM with blocks of the form B_{C}, as claimed. The calculation for Pₖ˜unif( [symbol] ) is almost identical, but gives a minus sign on the off-diagonal elements, as in [symbol] above.

Third, relative to a form of the expectation values 1284, let ρ denote the initial quantum state prepared by the state preparation component 1212, and define αᵢ≡tr(Pᵢ ρ). An aim is to prepare |ψ₁ [symbol] |ψ₂ [symbol] , which would give αᵢ=1, but there could be some state preparation errors. Then the expected value of f(d), for even depths d, is αᵢβᵢ(Gᵢᵢ²−GᵢⱼGⱼᵢ)^{d/2} where βᵢ describes measurement error that depends on Pᵢ but not on ρ.

As proof of this concept, as illustrated at the quantum circuit 1402 of FIG. 14, the Pauli conjugating the first noisy R_{ZZ}(θ) gate is sampled from unif( [symbol] ) or from unif( [symbol] ) with equal probabilities. The next conjugating Pauli is then sampled unif( [symbol] ) or unif( [symbol] ) respectively. Since all PTMs involved are block-diagonal, the overall PTM for these two layers is also block-diagonal (it ends up diagonal in fact), with blocks of the form

$$\frac{1}{2} ( {B}_{𝒜} {B}_{𝒞} + {B}_{𝒞} {B}_{𝒜} ) = ( \begin{matrix}{G}_{ii}^{2} - {G}_{ij} {G}_{ji} & 0 \\ 0 & {G}_{jj}^{2} - {G}_{ij} {G}_{ji}\end{matrix} ) .$$

Since the Paulis in different pairs of layers (e.g., instances; e.g., 1ₛₜ and 2^{nd}, 3^{rd} and 4^{th} etc.) are sampled independently, the PTM for d layers is also diagonal with elements given by

$${[ \frac{1}{2} ( {B}_{𝒜} {B}_{𝒞} + {B}_{𝒞} {B}_{𝒜} ) ]}^{d / 2} .$$

This follows from the fact that [symbol] (xy)= [symbol] (x) [symbol] (y) for any independent random variables x and y. Therefore, without SPAM errors, the expectation value of f(d), [symbol] Pᵢ [symbol] , for such circuits with (even) depth d is (Gᵢᵢ²−GᵢⱼGⱼᵢ)^{d/2}. With SPAM errors, the measured expectation values could deviate almost arbitrarily. However, readout twirling and a diagonal PTM ensure that the measure expectation value equal αᵢβᵢ (Gᵢᵢ²−GᵢⱼGⱼᵢ)^{d/2} as indicated above. And importantly, αᵢβᵢ is independent of d.

Additional Summary—Characterizing Noisy Non-Clifford Gates Through Alternating Pauli Twirling

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

In summary, the one or more embodiments described herein can provide a system, computer-implemented method and/or computer program product to characterize noise of a quantum gate can comprise a memory that stores, and a processor that executes, computer executable components that perform operations comprising generating a quantum circuit comprising a series of one or more instances of a quantum gate of interest, and having each instance of the quantum gate of interest being bounded by a pair of Pauli gates, randomly selecting, separately for each odd-numbered instance, the respective bounding Pauli gate from a set of Pauli gates of a random set selection of a first set of Pauli gates or a second set of Pauli gates, and randomly selecting, separately for each even numbered instance, the respective bounding Pauli gate from the other of the first set of Pauli gates or the second set of Pauli gates that was not randomly selected for the directly preceding odd-numbered instance in the series and, characterizing the noise (e.g., based on execution of the quantum circuit and one or more subsequent processes that can be classically-performed).

A benefit of the system, computer-implemented method and/or computer program product can be accurate determination of Pauli transfer matrix elements corresponding to a quantum channel comprising a non-Clifford gate, such as an n-qubit non-Clifford gate and/or for gates of the form R_{ZZ}(θ) for angle |74|<π/2 natively. Further, many Trotter/Floquet circuits for simulating quantum dynamics naturally call for such R_{ZZ}(θ) gates. These Pauli transfer matrix elements can be employed to characterize the noisy non-Clifford gate, thus allowing for operation of the respective quantum channel.

Another benefit of the system, computer-implemented method and/or computer program product can be an ability to characterize non-Clifford gates, such as partial CNOT gates or partially-entangling R_{ZZ}(θ)=e^{-iθ/2 z⊗z} gates for arbitrary angles θ in a quantum circuit, through use of the Pauli transfer matrix elements for such non-Clifford gates being determinable through use of the one or more embodiments described herein. These gates can be employed in a variety of applications, such as simulating quantum dynamics. These gates can be realized on a quantum computer with the realization having higher fidelity than realization of 2-qubit Clifford gates, such as CNOTs, because such non-Clifford gates are shorter than CNOTs. Accordingly, the system, computer-implemented method and/or computer program product can provide for use of previously inaccessible, native gates.

Still another benefit of the system, computer-implemented method and/or computer program product can be an ability to generate one or more elements characterizing noise of the quantum gate of interest, from which one or more Pauli transfer matrix (PTM) elements of a Pauli transfer matrix of the quantum gate of interest. That is, based on one or more parameters of the curve to which the expectation values are fitted, the one or more embodiments described herein can then yield combinations of Pauli transfer matrix elements for the noisy gate of interest. An amplitude a of the curve is the only fit parameter that depends on state preparation and measurement (SPAM) noise, and this parameter gets discarded due to non-use in equations representing the Pauli transfer matrix (PTM) elements for the noisy quantum gate of interest, which are instead based on one or more of a decay rate (r), frequency (ω) and/or phase (δ). Accordingly, the PTM element results are not biased by SPAM noise.

Yet another benefit of the system, computer-implemented method and/or computer program product can generally be an improvement in the functioning of a quantum computer. This improvement over existing computerized technologies and/or quantum computerized technologies improves the function of a quantum computer with respect to noise caused by execution of the quantum computer. Indeed, for to a non-limiting system comprising both a classical system as described herein and a quantum system as described herein (e.g., comprising a quantum computer), such non-limiting system can be self-improving through primary characterization of noise that is caused by execution of a selected quantum gate and through secondary use of one or more aspects of the characterization to further execute the selected quantum gate with no such noise or reduced such noise.

More particularly, the benefit can comprise an ability to improve the efficiency of using a quantum computer by reducing the noise being caused by employment of the quantum computer. That is, through use of the system, computer-implemented method and/or computer program product, noise that is caused by execution of a particular quantum gate can be characterized. Using the characterization of the noise, operation of that same selected quantum gate can be transformed to operate at the same quantum computer with less noise that was characterized and/or absent one or more elements of the noise that was characterized. Such amended operation can comprise, but is not limited to, use of one or more different waveforms defined by one or more additional and/or altered quantum gates, order of quantum gates, etc. to cause one or more different changes (e.g., of energy states, rotations, etc.) of one or more physical qubits of a quantum processor of the quantum computer.

As a result, the speed of a use, efficiency of use, and/or accuracy and/or precision of one or more states and/or rotations to which one or more qubits of the quantum computer are caused to enter, can be increased by use of the characterizations resulting from use of the system, computer-implemented method and/or computer program product. As a secondary result, the measurement readouts obtained from the quantum computer, based directly on readout of the one or more states and/or rotations to which the one or more qubits of the quantum computer are caused to enter, can in turn be improved to be more accurate and/or precise, in turn leading to one or more expectation values being determined with improved speed, efficiency, accuracy and/or precision.

Indeed, in view of the one or more embodiments described herein, a practical application of the one or more systems, computer-implemented methods and/or computer program products described herein can be the obtaining of one or more elements characterizing noise of a quantum gate, such as a non-Clifford gate, based on execution of a shaped quantum circuit at a quantum processor and subsequent measurement readout twirling by the one or more systems, computer-implemented methods and/or computer program products described herein. Accordingly, based on use of measurement outcomes, an expectation value can be obtained that can define a curve, wherein one or more parameters of the curve can be employed to obtain the one or more elements characterizing the noise of the quantum gate, with SPAM noise being dropped from the one or more parameters. These processes can be useful in fields of finance, biology, chemistry, materials science, pharmacology and/or drug-delivery using a quantum processor, without being limited thereto. More particularly, in one or more embodiments, these processes can be employed to define a PTM of the quantum gate, thus allowing for error mitigation of a result of execution of the quantum gate (which again can be an n-qubit non-Clifford gate). Accordingly, the one or more embodiments described herein provide useful and practical applications of computers, thus providing enhanced (e.g., improved and/or optimized) quantum circuit execution at a quantum processor and enhanced measurement outcomes from the quantum processor. Overall, such computerized tools can constitute a concrete and tangible technical improvement in the fields of quantum processing and/or quantum dynamics, without being limited thereto.

Furthermore, one or more embodiments described herein can be employed in a real-world system based on the disclosed teachings. For example, one or more embodiments described herein can function in combination with a physical quantum computer having a physical quantum processor. In response to one or more waveforms generated by a waveform generator of the quantum computer, physical quantum qubit hardware of the quantum processor can produce signals and/or changes in state of the qubit hardware, resulting in ability to measure such signals and/or changes in state of the qubit hardware. The measurements, e.g., the measurement outcomes, can be thereafter employed for various inference actions relative to sample quantum data corresponding to one or more quantum circuits having been executed on the quantum computer by way of operation of the waveform generator.

Moreover, one or more embodiments described herein can be implemented in one or more domains to enable scaled quantum processing. Indeed, use of a system, computer-implemented method and/or computer program product as described herein can be scalable, such as where plural quantum gates (e.g., input quantum gates) can be evaluated, processed (e.g., modified) and/or executed at a quantum processor at least partially at a same time as one another. These plural quantum gates can arise from one or more quantum circuits. Accordingly, scaling can be enabled for more than one quantum circuit at least partially in parallel with one another.

These scalings can be made possible by use of independent sets of physical qubits for each first quantum gate. That is, a quantum processor can comprise hardware for plural physical qubits. In view thereof, a qubit mapping can be determined for a single quantum processor for operation of various quantum circuits (e.g., relative to various quantum gates) at least partially in parallel with one another. Furthermore, the classical processing employed corresponding to the plural quantum gates also can be performed at least partially in parallel with one another. That is, the processing for pre-execution modification of quantum circuits, post-measurement outcome curve fitting, and post-curve fitting noise characterization element determination can be performed at a classical computer and can be performed relative to plural quantum gates at least partially in parallel with one another.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to execution of non-Clifford quantum gates, as compared to existing systems and/or techniques. Systems, computer-implemented methods and/or computer program products providing performance of these processes are of great utility in the fields of quantum circuit operation and/or quantum computing more generally and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically perform quantum circuit encoding, load a quantum register, perform quantum calculations, generate a waveform and/or measure a state of qubit as the one or more embodiments described herein can provide these processes. Moreover, neither can the human mind nor a human with pen and paper conduct one or more of these processes, as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is next provided.

A system, comprising: a memory that stores computer executable components; and a processor that executes the computer executable components stored in the memory, wherein the computer executable components comprise: a quantum circuit generation component that generates a quantum circuit comprising a series of one or more instances of a quantum gate of interest, wherein the quantum circuit generation component further generates the quantum circuit having each instance of the quantum gate of interest being bounded by a pair of Pauli gates, and wherein each pair of Pauli gates comprises two of the same bounding Pauli gate; a selection component that randomly selects, separately for each odd-numbered instance, of the series of one or more instances of the quantum gate of interest, the respective bounding Pauli gate to employ from a set of Pauli gates of a random set selection of a first set of Pauli gates or a second set of Pauli gates, and randomly selects, separately for each even numbered instance, of the series of one or more instances of the quantum gate of interest, the respective bounding Pauli gate from the other of the first set of Pauli gates or the second set of Pauli gates that was not randomly selected for the directly preceding odd-numbered instance in the series of one or more instances of the quantum gate of interest; and a finalization component that, based on one or more parameters of a curve, to which an expectation value, resulting from a measurement outcome of execution of the quantum circuit at a quantum system, is fitted, generates an element characterizing noise of the quantum gate of interest.

The system of the preceding paragraph, further comprising: an execution component that executes the quantum circuit at a quantum processor of the quantum system, resulting in the measurement outcome.

The system of any preceding paragraph, wherein the quantum gate of interest is a 2-qubit, non-Clifford quantum gate.

The system of any preceding paragraph, wherein the selection component randomly selects the bounding Pauli gate for each odd-numbered instance, of the series of one or more instances of the quantum gate of interest, using a 50% probability of selection from the first set of Pauli gates and 50% probability of selection from the second set of Pauli gates, and wherein the selection component randomly selects the bounding Pauli gate for any instance, of the series of one or more instances of the quantum gate of interest, using an even probability distribution for all Pauli gates of the set of Pauli gates from which selection is made.

The system of any preceding paragraph, wherein each of the Pauli gates of the first set of Pauli gates commute with a rotation axis of the quantum gate of interest, and wherein each of the Pauli gates of the second set of Pauli gates anti-commute with the rotation axis of the quantum gate of interest.

The system of any preceding paragraph, further comprising: a state preparation component that selects an initial quantum state for the quantum circuit based on a rotation axis A⊗B of the quantum gate of interest, wherein A, B∈{X, Y, Z}.

The system of any preceding paragraph, further comprising: a readout twirling component that directs performance of readout twirling of a state-based Pauli gate at the quantum system to result in output of the measurement outcome by the quantum system; and an insertion component that selects the state-based Pauli gate as Pᵢ or Pⱼ from a state-based set of Pauli gates where Pᵢ and Pⱼ∝(A⊗B)Pᵢ both commute or anti-commute with a rotation axis A⊗B of the quantum gate of interest, wherein A, B∈{X, Y, Z}.

The system of any preceding paragraph, wherein the finalization component generates the element absent employment of an amplitude parameter of the curve, resulting in the element being non-biased by state preparation and measurement noise related to operation of the quantum gate of interest.

The system of any preceding paragraph, further comprising: a primary iteration component that directs the quantum circuit generation component, selection component and finalization component to perform their respective operations for one or more additional quantum circuits each having a series of a same number of one or more instances of the quantum gate of interest as the quantum circuit.

The system of any preceding paragraph, further comprising: a secondary iteration component that directs the quantum circuit generation component, selection component, finalization component and primary iteration component to perform their respective operations for one or more further quantum circuits each having a series of a second same number of one or more instances of the quantum gate of interest as the quantum circuit, wherein the second same number is different than the same number; and a state preparation component that selects a second quantum state, different from a first quantum state of the quantum circuit, and, based on a rotation axis A⊗B of the quantum gate of interest, wherein A, B∈{X, Y, Z}, and wherein the state preparation component further directs the quantum circuit generation component, selection component, finalization component, primary iteration component and secondary iteration component to perform their respective operations relative to the second quantum state.

A computer-implemented method, comprising: generating, by a system operatively coupled to a processor, a quantum circuit comprising a series of one or more instances of a quantum gate of interest and further having each instance of the quantum gate of interest being bounded by a pair of Pauli gates, wherein each pair of Pauli gates comprises two of the same bounding Pauli gate; randomly selecting, by the system, separately for each odd-numbered instance, of the series of one or more instances of the quantum gate of interest, the respective bounding Pauli gate to employ from a set of Pauli gates of a random set selection of a first set of Pauli gates or a second set of Pauli gates; randomly selecting, by the system, separately for each even numbered instance, of the series of one or more instances of the quantum gate of interest, the respective bounding Pauli gate from the other of the first set of Pauli gates or the second set of Pauli gates that was not randomly selected for the directly preceding odd-numbered instance in the series of one or more instances of the quantum gate of interest; and, based on one or more parameters of a curve, to which an expectation value, resulting from a measurement outcome of execution of the quantum circuit at a quantum system, is fitted, generating, by the system, an element characterizing noise of the quantum gate of interest.

The computer-implemented method of the preceding paragraph, further comprising: executing, by the system, the quantum circuit at a quantum processor of the quantum system, resulting in the measurement outcome; and directing, by the system, performance of readout twirling of a state-based Pauli gate at the quantum system to result in output of the measurement outcome by the quantum system.

The computer-implemented method of any preceding paragraph, further comprising: selecting, by the system, the state-based Pauli gate as Pᵢ or Pⱼ from a state-based set of Pauli gates where Pᵢ and Pⱼ∝(A⊗B)Pᵢ both commute or anti-commute with a rotation axis A⊗B of the quantum gate of interest, wherein A, B∈{X, Y, Z}.

The computer-implemented method of any preceding paragraph, further comprising: randomly selecting, by the system, the bounding Pauli gate for each odd-numbered instance, of the series of one or more instances of the quantum gate of interest, using a 50% probability of selection from the first set of Pauli gates and 50% probability of selection from the second set of Pauli gates; and randomly selecting, by the system, the bounding Pauli gate for any instance, of the series of one or more instances of the quantum gate of interest, using an even probability distribution for all Pauli gates of the set of Pauli gates from which selection is made.

The computer-implemented method of any preceding paragraph, wherein each of the Pauli gates of the first set of Pauli gates commute with a rotation axis of the quantum gate of interest, and wherein each of the Pauli gates of the second set of Pauli gates anti-commute with the rotation axis of the quantum gate of interest.

A computer program product facilitating a process to characterize a noisy quantum gate, the computer program product comprising a computer readable storage medium having program instructions embodied therewith, the program instructions executable by a processor to cause the processor to: generate, by the processor, a quantum circuit comprising a series of one or more instances of a quantum gate of interest and further having each instance of the quantum gate of interest being bounded by a pair of Pauli gates, wherein each pair of Pauli gates comprises two of the same bounding Pauli gate; randomly select, by the processor, separately for each odd-numbered instance, of the series of one or more instances of the quantum gate of interest, the respective bounding Pauli gate to employ from a set of Pauli gates of a random set selection of a first set of Pauli gates or a second set of Pauli gates; randomly select, by the processor, separately for each even numbered instance, of the series of one or more instances of the quantum gate of interest, the respective bounding Pauli gate from the other of the first set of Pauli gates or the second set of Pauli gates that was not randomly selected for the directly preceding odd-numbered instance in the series of one or more instances of the quantum gate of interest; and, based on one or more parameters of a curve, to which an expectation value, resulting from a measurement outcome of execution of the quantum circuit at a quantum system, is fitted, generate, by the processor, an element characterizing noise of the quantum gate of interest.

The computer program product of the preceding paragraph, wherein the program instructions are further executable by the processor to cause the processor to: execute, by the processor, the quantum circuit at a quantum processor of the quantum system, resulting in the measurement outcome; and direct, by the processor, performance of readout twirling of a state-based Pauli gate at the quantum system to result in output of the measurement outcome by the quantum system.

The computer program product of any preceding paragraph, wherein the program instructions are further executable by the processor to cause the processor to: select, by the processor, the state-based Pauli gate as Pᵢ or Pⱼ from a state-based set of Pauli gates where Pᵢ and Pⱼ∝(A⊗B)Pᵢ both commute or anti-commute with a rotation axis A⊗B of the quantum gate of interest, wherein A, B∈{X, Y, Z}.

The computer program product of any preceding paragraph, wherein the program instructions are further executable by the processor to cause the processor to: randomly select, by the processor, the bounding Pauli gate for each odd-numbered instance, of the series of one or more instances of the quantum gate of interest, using a 50% probability of selection from the first set of Pauli gates and 50% probability of selection from the second set of Pauli gates; and randomly select, by the processor, the bounding Pauli gate for any instance, of the series of one or more instances of the quantum gate of interest, using an even probability distribution for all Pauli gates of the set of Pauli gates from which selection is made.

The computer program product of any preceding paragraph, wherein each of the Pauli gates of the first set of Pauli gates commute with a rotation axis of the quantum gate of interest, and wherein each of the Pauli gates of the second set of Pauli gates anti-commute with the rotation axis of the quantum gate of interest.

Description—Characterizing Noisy Non-Clifford Gates Through Partial and/or Alternating Pauli Twirling

Discussion now turns to a summary applicable to either of characterization of noise of quantum gates, such as non-Clifford gates, through partial Pauli twirling and/or through alternating Pauli twirling. Indeed, both processes can be performed on a same quantum gate. That is, discussion turns now more generally to one or more embodiments encompassing any of the non-limiting systems of FIGS. 1, 2, 10 and/or 11, and associated processes of the respective figures related to these non-limiting systems.

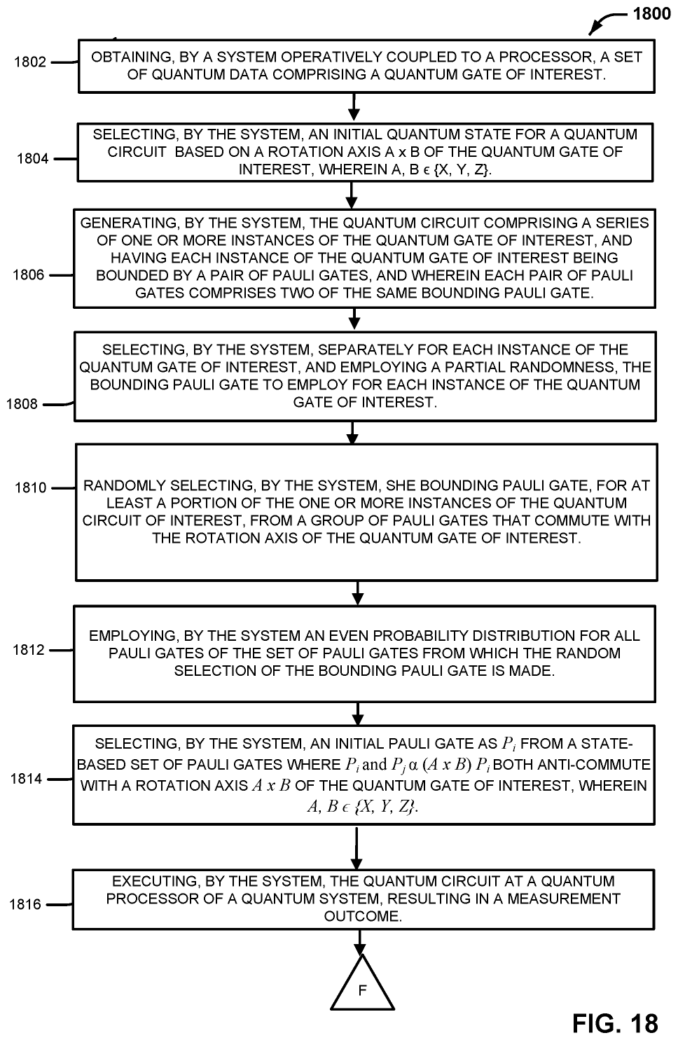

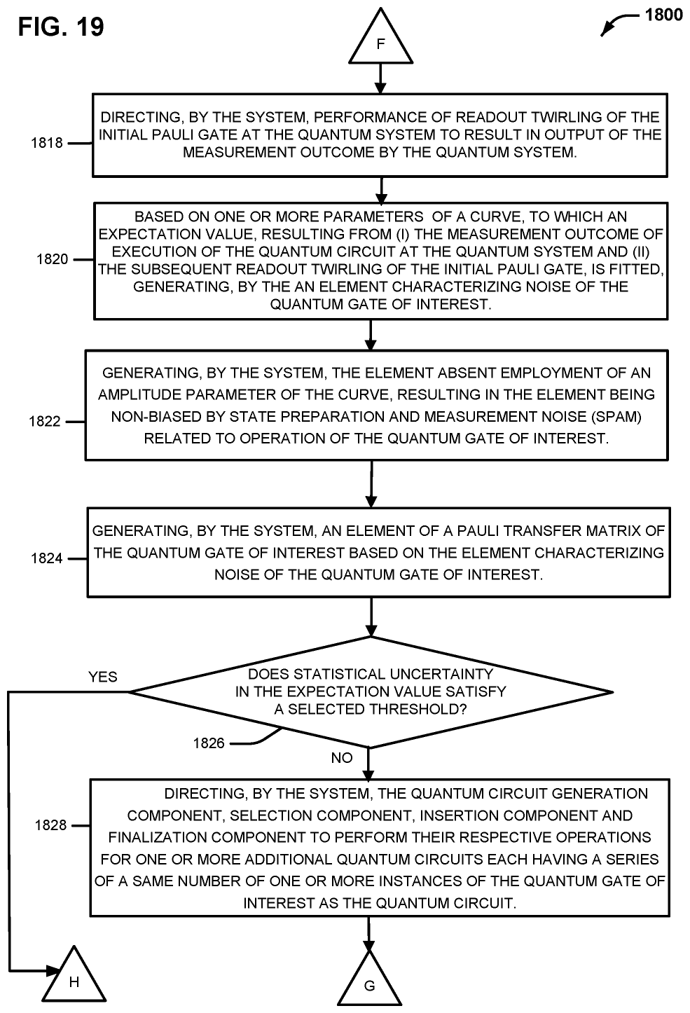

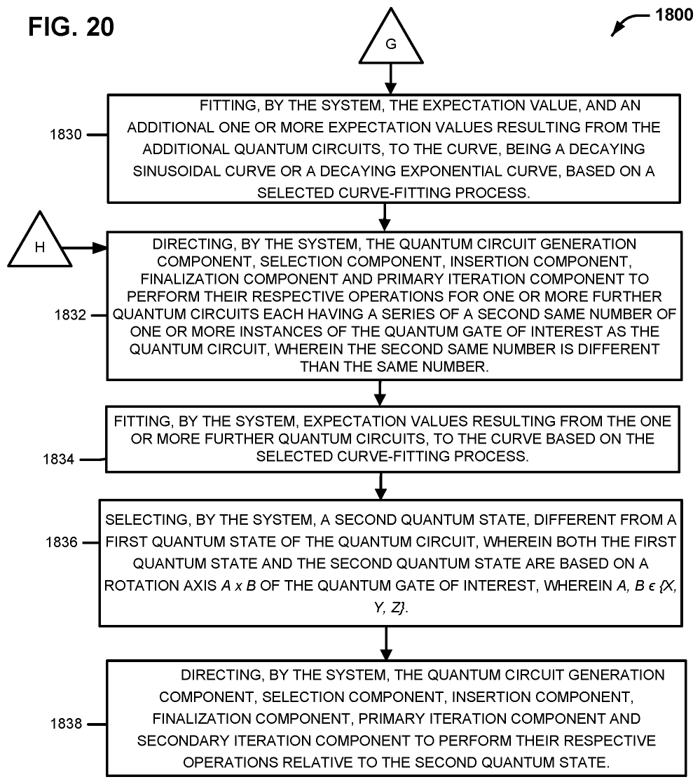

As a summary of this general concept, discussion next turns to FIGS. 18-20, illustrating a flow diagram of an example, non-limiting method 1800 that can provide a process to obtain an error mitigated measurement outcome of operation of a quantum processor, in accordance with one or more embodiments described herein, such as the non-limiting system 200 of FIG. 2 or the non-limiting system 1200 of FIG. 12. While the non-limiting method 1800 is described relative to the non-limiting system 200 of FIG. 2 or the non-limiting system 1200 of FIG. 12, the non-limiting method 1800 can be applicable also to other systems described herein, such as the non-limiting system 100 of FIG. 1 or the non-limiting system 1100 of FIG. 11. Repetitive description of like elements and/or processes employed in respective embodiments is omitted for sake of brevity.

At 1802, the non-limiting method 1800 can comprise obtaining, by a system operatively coupled to a processor (e.g., state preparation component 212, 1212), a set of quantum data (e.g., set of quantum data 240, 1240) comprising a quantum gate of interest (e.g., quantum gate of interest 401, 1401).

At 1804, the non-limiting method 1800 can comprise selecting, by the system (e.g., state preparation component 212, 1212), an initial quantum state for a quantum circuit (e.g., quantum circuit 402, 1402) based on a rotation axis A⊗B of the quantum gate of interest, wherein A, B∈{X,Y,Z}.

At 1806, the non-limiting method 1800 can comprise generating, by the system (e.g., quantum circuit generation component 214, 1214), the quantum circuit comprising a series of one or more instances of the quantum gate of interest, and having each instance of the quantum gate of interest being bounded by a pair of Pauli gates (e.g., pair 403, 1403 of Pauli gates), and wherein each pair of Pauli gates comprises two of the same bounding Pauli gate (e.g., P, P′, etc. or as defined by schematic 1410; e.g., set 500, 510).

At 1808, the non-limiting method 1800 can comprise selecting, by the system (e.g., selection component 216, 1216), separately for each instance of the quantum gate of interest, and employing a partial randomness, the bounding Pauli gate to employ for each instance of the quantum gate of interest.

At 1810, the non-limiting method 1800 can comprise randomly selecting, by the system (e.g., selection component 216, 1216), the bounding Pauli gate, for at least a portion of the one or more instances of the quantum circuit of interest, from a group of Pauli gates that commute with the rotation axis of the quantum gate of interest.

At 1812, the non-limiting method 1800 can comprise employing, by the system (e.g., selection component 216, 1216) an even probability distribution for all Pauli gates of the set of Pauli gates from which the random selection of the bounding Pauli gate is made.

At 1814, the non-limiting method 1800 can comprise selecting, by the system (e.g., insertion component 218, 1218), an initial Pauli gate as Pᵢ from a state-based set of Pauli gates (e.g., from Table 550) where Pᵢ and Pⱼ∝(A⊗B)Pᵢ both anti-commute with a rotation axis A⊗B of the quantum gate of interest, wherein A, B∈{X, Y, Z}.

At 1816, the non-limiting method 1800 can comprise executing, by the system (e.g., execution component 220, 1220), the quantum circuit at a quantum processor (e.g., quantum processor 606) of a quantum system (e.g., quantum system 601), resulting in a measurement outcome (e.g., measurement outcome 282, 1282).

At 1818, the non-limiting method 1800 can comprise directing, by the system (e.g., readout twirling component 222, 1222), performance of readout twirling of the initial Pauli gate (e.g., Pᵢ) at the quantum system to result in output of the measurement outcome by the quantum system.

At 1820, the non-limiting method 1800 can comprise, based on one or more parameters (e.g., curve parameters 752) of a curve (e.g., curve 750), to which an expectation value (e.g., expectation value 284, 1284), resulting from (i) the measurement outcome of execution of the quantum circuit at the quantum system and (ii) the subsequent readout twirling of the initial Pauli gate, is fitted, generating, by the system (e.g., finalization component 228, 1228) an element (e.g., noise characterization element 754) characterizing noise of the quantum gate of interest.

At 1822, the non-limiting method 1800 can comprise generating, by the system (e.g., finalization component 228, 1228), the element absent employment of an amplitude (a) parameter of the curve, resulting in the element being non-biased by state preparation and measurement noise (SPAM) related to operation of the quantum gate of interest.

At 1824, the non-limiting method 1800 can comprise generating, by the system (e.g., finalization component 228, 1228), an element (e.g., PTM element 286) of a Pauli transfer matrix of the quantum gate of interest based on the element characterizing noise of the quantum gate of interest.

At 1826, the non-limiting method 1800 can comprise determining, by the system (e.g., primary iteration component 224, 1224), whether statistical uncertainty in the expectation value (e.g., expectation value 284, 1284; f(d)) satisfies an uncertainty acceptability threshold (e.g., uncertainty acceptability threshold 720). If yes, the non-limiting method 1800 can proceed to step 1832. If no, the non-limiting method 800 can proceed to step 1828.

At 1828, the non-limiting method 1800 can comprise, directing, by the system (e.g., primary iteration component 224, 1224), the quantum circuit generation component, selection component, insertion component and finalization component to perform their respective operations for one or more additional quantum circuits each having a series of a same number of one or more instances of the quantum gate of interest as the quantum circuit.

At 1830, the non-limiting method 1800 can comprise, fitting, by the system (e.g., curve fitting component 226, 1226), the expectation value, and an additional one or more expectation values resulting from the additional quantum circuits, to the curve, being a decaying sinusoid curve or decaying exponential curve, based on a selected curve-fitting process.

At 1832, the non-limiting method 1800 can comprise directing, by the system (e.g., secondary iteration component 230, 1230), the quantum circuit generation component, selection component, insertion component, finalization component and primary iteration component to perform their respective operations for one or more further quantum circuits each having a series of a second same number of one or more instances of the quantum gate of interest as the quantum circuit, wherein the second same number is different than the same number.

At 1834, the non-limiting method 1800 can comprise fitting, by the system (e.g., curve fitting component 226, 1226), expectation values resulting from the one or more further quantum circuits, to the curve based on the selected curve-fitting process.

At 1836, the non-limiting method 1800 can comprise selecting, by the system (e.g., state preparation component 212, 1212), a second quantum state, different from a first quantum state of the quantum circuit, wherein both the first quantum state and the second quantum state are based on a rotation axis A⊗B of the quantum gate of interest, wherein A, B∈{X, Y, Z}.

At 1838, the non-limiting method 1800 can comprise directing, by the system (e.g., state preparation component 212, 1212), the quantum circuit generation component, selection component, insertion component, finalization component, primary iteration component and secondary iteration component to perform their respective operations relative to the second quantum state.

Additional Summary—Characterizing Noisy Non-Clifford Gates Through Partial and/or Alternating Pauli Twirling

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

In summary, the one or more embodiments described herein can provide a system, computer-implemented method and/or computer program product to characterize noise of a quantum gate can comprise a memory that stores, and a processor that executes, computer executable components that perform operations comprising generating a quantum circuit comprising a series of one or more instances of a quantum gate, wherein each instance is bounded by a pair of Pauli gates comprising two of the same bounding Pauli gate, selecting, separately for each instance, and employing a partial randomness, the bounding Pauli gate to employ, selecting an initial Pauli gate as Pᵢ from a state-based set of Pauli gates where Pᵢ and Pⱼ∝(A⊗B)Pᵢ both anti-commute with a rotation axis A⊗B of the quantum gate, wherein A, B∈{X, Y, Z}, and, characterizing the noise based on one or more parameters of a curve, to which an expectation value, resulting from (i) a measurement of execution of the quantum circuit and (ii) readout twirling of the initial Pauli gate, is fitted.

A benefit of the system, computer-implemented method and/or computer program product can be accurate determination of Pauli transfer matrix elements corresponding to a quantum channel comprising a non-Clifford gate, such as an n-qubit non-Clifford gate and/or for gates of the form R_{ZZ}(θ) for angle |θ|<π/2 natively. Further, many Trotter/Floquet circuits for simulating quantum dynamics naturally call for such R_{ZZ}(θ) gates. These Pauli transfer matrix elements can be employed to characterize the noisy non-Clifford gate, thus allowing for operation of the respective quantum channel.

Another benefit of the system, computer-implemented method and/or computer program product can be an ability to characterize non-Clifford gates, such as partial CNOT gates or partially-entangling R_{ZZ}(θ)=e^{-iθ/2 z⊗z} gates for arbitrary angles θ in a quantum circuit, through use of the Pauli transfer matrix elements for such non-Clifford gates being determinable through use of the one or more embodiments described herein. These gates can be employed in a variety of applications, such as simulating quantum dynamics. These gates can be realized on a quantum computer with the realization having higher fidelity than realization of 2-qubit Clifford gates, such as CNOTs, because such non-Clifford gates are shorter than CNOTs. Accordingly, the system, computer-implemented method and/or computer program product can provide for use of previously inaccessible, native gates.

Still another benefit of the system, computer-implemented method and/or computer program product can be an ability to generate one or more elements characterizing noise of the quantum gate of interest, from which one or more Pauli transfer matrix (PTM) elements of a Pauli transfer matrix of the quantum gate of interest. That is, based on one or more parameters of the curve to which the expectation values are fitted, the one or more embodiments described herein can then yield combinations of Pauli transfer matrix elements for the noisy gate of interest. An amplitude a of the curve is the only fit parameter that depends on state preparation and measurement (SPAM) noise, and this parameter gets discarded due to non-use in equations representing the Pauli transfer matrix (PTM) elements for the noisy quantum gate of interest, which are instead based on one or more of a decay rate (r), frequency (ω) and/or phase (δ). Accordingly, the PTM element results are not biased by SPAM noise.

Yet another benefit of the system, computer-implemented method and/or computer program product can generally be an improvement in the functioning of a quantum computer. This improvement over existing computerized technologies and/or quantum computerized technologies improves the function of a quantum computer with respect to noise caused by execution of the quantum computer. Indeed, for to a non-limiting system comprising both a classical system as described herein and a quantum system as described herein (e.g., comprising a quantum computer), such non-limiting system can be self-improving through primary characterization of noise that is caused by execution of a selected quantum gate and through secondary use of one or more aspects of the characterization to further execute the selected quantum gate with no such noise or reduced such noise.

More particularly, the benefit can comprise an ability to improve the efficiency of using a quantum computer by reducing the noise being caused by employment of the quantum computer. That is, through use of the system, computer-implemented method and/or computer program product, noise that is caused by execution of a particular quantum gate can be characterized. Using the characterization of the noise, operation of that same selected quantum gate can be transformed to operate at the same quantum computer with less noise that was characterized and/or absent one or more elements of the noise that was characterized. Such amended operation can comprise, but is not limited to, use of one or more different waveforms defined by one or more additional and/or altered quantum gates, order of quantum gates, etc. to cause one or more different changes (e.g., of energy states, rotations, etc.) of one or more physical qubits of a quantum processor of the quantum computer.

As a result, the speed of a use, efficiency of use, and/or accuracy and/or precision of one or more states and/or rotations to which one or more qubits of the quantum computer are caused to enter, can be increased by use of the characterizations resulting from use of the system, computer-implemented method and/or computer program product. As a secondary result, the measurement readouts obtained from the quantum computer, based directly on readout of the one or more states and/or rotations to which the one or more qubits of the quantum computer are caused to enter, can in turn be improved to be more accurate and/or precise, in turn leading to one or more expectation values being determined with improved speed, efficiency, accuracy and/or precision.

Indeed, in view of the one or more embodiments described herein, a practical application of the one or more systems, computer-implemented methods and/or computer program products described herein can be the obtaining of one or more elements characterizing noise of a quantum gate, such as a non-Clifford gate, based on execution of a shaped quantum circuit at a quantum processor and subsequent measurement readout twirling by the one or more systems, computer-implemented methods and/or computer program products described herein. Accordingly, based on use of measurement outcomes, an expectation value can be obtained that can define a curve, wherein one or more parameters of the curve can be employed to obtain the one or more elements characterizing the noise of the quantum gate, with SPAM noise being dropped from the one or more parameters. These processes can be useful in fields of finance, biology, chemistry, materials science, pharmacology and/or drug-delivery using a quantum processor, without being limited thereto. More particularly, in one or more embodiments, these processes can be employed to define a PTM of the quantum gate, thus allowing for error mitigation of a result of execution of the quantum gate (which again can be an n-qubit non-Clifford gate). Accordingly, the one or more embodiments described herein provide useful and practical applications of computers, thus providing enhanced (e.g., improved and/or optimized) quantum circuit execution at a quantum processor and enhanced measurement outcomes from the quantum processor. Overall, such computerized tools can constitute a concrete and tangible technical improvement in the fields of quantum processing and/or quantum dynamics, without being limited thereto.

Furthermore, one or more embodiments described herein can be employed in a real-world system based on the disclosed teachings. For example, one or more embodiments described herein can function in combination with a physical quantum computer having a physical quantum processor. In response to one or more waveforms generated by a waveform generator of the quantum computer, physical quantum qubit hardware of the quantum processor can produce signals and/or changes in state of the qubit hardware, resulting in ability to measure such signals and/or changes in state of the qubit hardware. The measurements, e.g., the measurement outcomes, can be thereafter employed for various inference actions relative to sample quantum data corresponding to one or more quantum circuits having been executed on the quantum computer by way of operation of the waveform generator.

Moreover, one or more embodiments described herein can be implemented in one or more domains to enable scaled quantum processing. Indeed, use of a system, computer-implemented method and/or computer program product as described herein can be scalable, such as where plural quantum gates (e.g., input quantum gates) can be evaluated, processed (e.g., modified) and/or executed at a quantum processor at least partially at a same time as one another. These plural quantum gates can arise from one or more quantum circuits. Accordingly, scaling can be enabled for more than one quantum circuit at least partially in parallel with one another. Furthermore, both processes can be performed on a same gate and/or different gates at least partially in parallel with one another.

These scalings can be made possible by use of independent sets of physical qubits for each first quantum gate. That is, a quantum processor can comprise hardware for plural physical qubits. In view thereof, a qubit mapping can be determined for a single quantum processor for operation of various quantum circuits (e.g., relative to various quantum gates) at least partially in parallel with one another. Furthermore, the classical processing employed corresponding to the plural quantum gates also can be performed at least partially in parallel with one another. That is, the processing for pre-execution modification of quantum circuits, post-measurement outcome curve fitting, and post-curve fitting noise characterization element determination can be performed at a classical computer and can be performed relative to plural quantum gates at least partially in parallel with one another.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to execution of non-Clifford quantum gates, as compared to existing systems and/or techniques. Systems, computer-implemented methods and/or computer program products providing performance of these processes are of great utility in the fields of quantum circuit operation and/or quantum computing more generally and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically perform quantum circuit encoding, load a quantum register, perform quantum calculations, generate a waveform and/or measure a state of qubit as the one or more embodiments described herein can provide these processes. Moreover, neither can the human mind nor a human with pen and paper conduct one or more of these processes, as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is next provided.

A system, comprising: a memory that stores computer executable components; and a processor that executes the computer executable components stored in the memory, wherein the computer executable components comprise: a quantum circuit generation component that generates a quantum circuit comprising a series of one or more instances of a quantum gate of interest, wherein the quantum circuit generation component further generates the quantum circuit having each instance of the quantum gate of interest being bounded by a pair of Pauli gates, and wherein each pair of Pauli gates comprises two of the same bounding Pauli gate; a selection component that selects, separately for each instance of the quantum gate of interest, and employing a partial randomness, the bounding Pauli gate to employ for each instance of the quantum gate of interest; an insertion component that selects an initial Pauli gate as Pᵢ from a state-based set of Pauli gates where Pᵢ and Pⱼ∝(A⊗B)Pᵢ both anti-commute with a rotation axis A⊗B of the quantum gate of interest, wherein A, B∈{X, Y, Z}; and a finalization component that, based on one or more parameters of a curve, to which an expectation value, resulting from (i) a measurement outcome of execution of the quantum circuit at a quantum system and (ii) subsequent readout twirling of the initial Pauli gate, is fitted, generates an element characterizing noise of the quantum gate of interest.

The system of the preceding paragraph, further comprising: an execution component that executes the quantum circuit at a quantum processor of the quantum system, resulting in the measurement outcome.

The system of any preceding paragraph, wherein the quantum gate of interest is a 2-qubit, non-Clifford quantum gate.

The system of any preceding paragraph, further comprising: a readout twirling component that directs performance of the readout twirling of the initial Pauli gate at the quantum system to result in output of the measurement outcome by the quantum system.

The system of any preceding paragraph, wherein the finalization component generates the element absent employment of an amplitude parameter of the curve, resulting in the element being non-biased by state preparation and measurement noise related to operation of the quantum gate of interest.

The system of any preceding paragraph, wherein the finalization component further generates an element of a Pauli transfer matrix of the quantum gate of interest based on the element characterizing noise of the quantum gate of interest.

The system of any preceding paragraph, wherein the selection component randomly selects the bounding Pauli gate, for at least a portion of the one or more instances of the quantum circuit of interest, from a group of Pauli gates that commute with the rotation axis of the quantum gate of interest, and wherein the selection component employs an even probability distribution for all Pauli gates of the set of Pauli gates from which the random selection of the bounding Pauli gate is made.

The system of any preceding paragraph, further comprising: a primary iteration component that directs the quantum circuit generation component, selection component, insertion component and finalization component to perform their respective operations for one or more additional quantum circuits each having a series of a same number of one or more instances of the quantum gate of interest as the quantum circuit.

The system of any preceding paragraph, further comprising: a curve fitting component that fits the expectation value, and an additional one or more expectation values resulting from the additional quantum circuits, to a decaying sinusoid curve or decaying exponential curve based on a selected curve-fitting process.

The system of any preceding paragraph, further comprising: a secondary iteration component that directs the quantum circuit generation component, selection component, insertion component, finalization component and primary iteration component to perform their respective operations for one or more further quantum circuits each having a series of a second same number of one or more instances of the quantum gate of interest as the quantum circuit, wherein the second same number is different than the same number; and a state preparation component that selects a second quantum state, different from a first quantum state of the quantum circuit, wherein both the first quantum state and the second quantum state are based on the rotation axis A⊗B of the quantum gate of interest, and wherein the state preparation component further directs the quantum circuit generation component, selection component, insertion component, finalization component, primary iteration component and secondary iteration component to perform their respective operations relative to the second quantum state.

A computer-implemented method, comprising: generating, by a system operatively coupled to a processor, a quantum circuit comprising a series of one or more instances of a quantum gate of interest, and further having each instance of the quantum gate of interest being bounded by a pair of Pauli gates, wherein each pair of Pauli gates comprises two of the same bounding Pauli gate; selecting, by the system, separately for each instance of the quantum gate of interest, and employing a partial randomness, the bounding Pauli gate to employ for each instance of the quantum gate of interest; selecting, by the system, an initial Pauli gate as Pᵢ from a state-based set of Pauli gates where Pᵢ and Pⱼ∝(A⊗B)Pᵢ both anti-commute with a rotation axis A⊗B of the quantum gate of interest, wherein A, B∈{X, Y,Z}; and, based on one or more parameters of a curve, to which an expectation value, resulting from (i) a measurement outcome of execution of the quantum circuit at a quantum system and (ii) subsequent readout twirling of the initial Pauli gate, is fitted, generating, by the system, an element characterizing noise of the quantum gate of interest.

The computer-implemented method of the preceding paragraph, further comprising: executing, by the system, the quantum circuit at a quantum processor of the quantum system, resulting in the measurement outcome; and directing, by the system, performance of the readout twirling of the initial Pauli gate at the quantum system to result in output of the measurement outcome by the quantum system.

The computer-implemented method of any preceding paragraph, further comprising: generating, by the system, the element absent employment of an amplitude parameter of the curve, resulting in the element being non-biased by state preparation and measurement noise related to operation of the quantum gate of interest.

The computer-implemented method of any preceding paragraph, further comprising: generating, by the system, an element of a Pauli transfer matrix of the quantum gate of interest based on the element characterizing noise of the quantum gate of interest.

The computer-implemented method of any preceding paragraph, further comprising: randomly selecting, by the system, the bounding Pauli gate, for at least a portion of the one or more instances of the quantum circuit of interest, from a group of Pauli gates that commute with the rotation axis of the quantum gate of interest, and employing, by the system, an even probability distribution for all Pauli gates of the set of Pauli gates from which the random selection of the bounding Pauli gate is made.

A computer program product facilitating a process to characterize a noisy quantum gate, the computer program product comprising a computer readable storage medium having program instructions embodied therewith, the program instructions executable by a processor to cause the processor to: generate, by the processor, a quantum circuit comprising a series of one or more instances of a quantum gate of interest, and further having each instance of the quantum gate of interest being bounded by a pair of Pauli gates, wherein each pair of Pauli gates comprises two of the same bounding Pauli gate; select, by the processor, separately for each instance of the quantum gate of interest, and employing a partial randomness, the bounding Pauli gate to employ for each instance of the quantum gate of interest; select, by the processor, an initial Pauli gate as Pᵢ from a state-based set of Pauli gates where Pᵢ and Pⱼ∝(A⊗B)Pᵢ both anti-commute with a rotation axis A⊗B of the quantum gate of interest, wherein A, B∈{X, Y, Z}; and, based on one or more parameters of a curve, to which an expectation value, resulting from (i) a measurement outcome of execution of the quantum circuit at a quantum system and (ii) subsequent readout twirling of the initial Pauli gate, is fitted, generate, by the processor, an element characterizing noise of the quantum gate of interest.

The computer-implemented method of the preceding paragraph, wherein the program instructions are further executable by the processor to cause the processor to: execute, by the processor, the quantum circuit at a quantum processor of the quantum system, resulting in the measurement outcome; and direct, by the processor, performance of the readout twirling of the initial Pauli gate at the quantum system to result in output of the measurement outcome by the quantum system.

The computer-implemented method of any preceding paragraph, wherein the program instructions are further executable by the processor to cause the processor to: generate, by the processor, the element absent employment of an amplitude parameter of the curve, resulting in the element being non-biased by state preparation and measurement noise related to operation of the quantum gate of interest.

The computer-implemented method of any preceding paragraph, wherein the program instructions are further executable by the processor to cause the processor to: generate, by the processor, an element of a Pauli transfer matrix of the quantum gate of interest based on the element characterizing noise of the quantum gate of interest.

The computer-implemented method of any preceding paragraph, wherein the program instructions are further executable by the processor to cause the processor to: randomly select, by the processor, the bounding Pauli gate, for at least a portion of the one or more instances of the quantum circuit of interest, from a group of Pauli gates that commute with the rotation axis of the quantum gate of interest, and employ, by the processor, an even probability distribution for all Pauli gates of the set of Pauli gates from which the random selection of the bounding Pauli gate is made.

### Computing Environment Description

Turning next to FIG. 21, a detailed description is provided of additional context for the one or more embodiments described herein at FIGS. 1-20.

FIG. 21 and the following discussion are intended to provide a brief, general description of a suitable computing environment 2100 in which one or more embodiments described herein at FIGS. 1-20 can be implemented. For example, various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 2100 contains an example of an environment for the execution of at least some of the computer code involved in performing the inventive methods, such as translation of an original source code based on a configuration of a target system by the quantum gate noise characterization code 2180. In addition to block 2180, computing environment 2100 includes, for example, computer 2101, wide area network (WAN) 2102, end user device (EUD) 2103, remote server 2104, public cloud 2105, and private cloud 2106. In this embodiment, computer 2101 includes processor set 2110 (including processing circuitry 2120 and cache 2121), communication fabric 2111, volatile memory 2112, persistent storage 2113 (including operating system 2122 and block 2180, as identified above), peripheral device set 2114 (including user interface (UI), device set 2123, storage 2124, and Internet of Things (IoT) sensor set 2125), and network module 2115. Remote server 2104 includes remote database 2130. Public cloud 2105 includes gateway 2140, cloud orchestration module 2141, host physical machine set 2142, virtual machine set 2143, and container set 2144.

COMPUTER 2101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 2130. As is well understood in the art of computer technology, and depending upon the technology, performance of a computer-implemented method may be distributed among multiple computers and/or between multiple locations. On the other hand, in this presentation of computing environment 2100, detailed discussion is focused on a single computer, specifically computer 2101, to keep the presentation as simple as possible. Computer 2101 may be located in a cloud, even though it is not shown in a cloud in FIG. 21. On the other hand, computer 2101 is not required to be in a cloud except to any extent as may be affirmatively indicated.

PROCESSOR SET 2110 includes one, or more, computer processors of any type now known or to be developed in the future. Processing circuitry 2120 may be distributed over multiple packages, for example, multiple, coordinated integrated circuit chips. Processing circuitry 2120 may implement multiple processor threads and/or multiple processor cores. Cache 2121 is memory that is located in the processor chip package and is typically used for data or code that should be available for rapid access by the threads or cores running on processor set 2110. Cache memories are typically organized into multiple levels depending upon relative proximity to the processing circuitry. Alternatively, some, or all, of the cache for the processor set may be located “off chip.” In some computing environments, processor set 2110 may be designed for working with qubits and performing quantum computing.

Computer readable program instructions are typically loaded onto computer 2101 to cause a series of operational steps to be performed by processor set 2110 of computer 2101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 2121 and the other storage media discussed below. The program instructions, and associated data, are accessed by processor set 2110 to control and direct performance of the inventive methods. In computing environment 2100, at least some of the instructions for performing the inventive methods may be stored in block 2180 in persistent storage 2113.

COMMUNICATION FABRIC 2111 is the signal conduction path that allows the various components of computer 2101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 2112 is any type of volatile memory now known or to be developed in the future. Examples include dynamic type random access memory (RAM) or static type RAM. Typically, the volatile memory is characterized by random access, but this is not required unless affirmatively indicated. In computer 2101, the volatile memory 2112 is located in a single package and is internal to computer 2101, but, alternatively or additionally, the volatile memory may be distributed over multiple packages and/or located externally with respect to computer 2101.

PERSISTENT STORAGE 2113 is any form of non-volatile storage for computers that is now known or to be developed in the future. The non-volatility of this storage means that the stored data is maintained regardless of whether power is being supplied to computer 2101 and/or directly to persistent storage 2113. Persistent storage 2113 may be a read only memory (ROM), but typically at least a portion of the persistent storage allows writing of data, deletion of data and re-writing of data. Some familiar forms of persistent storage include magnetic disks and solid-state storage devices. Operating system 2122 may take several forms, such as various known proprietary operating systems or open-source Portable Operating System Interface type operating systems that employ a kernel. The code included in block 2180 typically includes at least some of the computer code involved in performing the inventive methods.

PERIPHERAL DEVICE SET 2114 includes the set of peripheral devices of computer 2101. Data communication connections between the peripheral devices and the other components of computer 2101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 2123 may include components such as a display screen, speaker, microphone, wearable devices (such as goggles and smart watches), keyboard, mouse, printer, touchpad, game controllers, and haptic devices. Storage 2124 is external storage, such as an external hard drive, or insertable storage, such as an SD card. Storage 2124 may be persistent and/or volatile. In some embodiments, storage 2124 may take the form of a quantum computing storage device for storing data in the form of qubits. In embodiments where computer 2101 is required to have a large amount of storage (for example, where computer 2101 locally stores and manages a large database) then this storage may be provided by peripheral storage devices designed for storing very large amounts of data, such as a storage area network (SAN) that is shared by multiple, geographically distributed computers. IoT sensor set 2125 is made up of sensors that can be used in Internet of Things applications. For example, one sensor may be a thermometer and another sensor may be a motion detector.

NETWORK MODULE 2115 is the collection of computer software, hardware, and firmware that allows computer 2101 to communicate with other computers through WAN 2102. Network module 2115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 2115 are performed on the same physical hardware device. In other embodiments (for example, embodiments that utilize software-defined networking (SDN)), the control functions and the forwarding functions of network module 2115 are performed on physically separate devices, such that the control functions manage several different network hardware devices. Computer readable program instructions for performing the inventive methods can typically be downloaded to computer 2101 from an external computer or external storage device through a network adapter card or network interface included in network module 2115.

WAN 2102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 2103 is any computer system that is used and controlled by an end user (for example, a customer of an enterprise that operates computer 2101) and may take any of the forms discussed above in connection with computer 2101. EUD 2103 typically receives helpful and useful data from the operations of computer 2101. For example, in a hypothetical case where computer 2101 is designed to provide a recommendation to an end user, this recommendation would typically be communicated from network module 2115 of computer 2101 through WAN 2102 to EUD 2103. In this way, EUD 2103 can display, or otherwise present, the recommendation to an end user. In some embodiments, EUD 2103 may be a client device, such as thin client, heavy client, mainframe computer, desktop computer and so on.

REMOTE SERVER 2104 is any computer system that serves at least some data and/or functionality to computer 2101. Remote server 2104 may be controlled and used by the same entity that operates computer 2101. Remote server 2104 represents the machine that collects and stores helpful and useful data for use by other computers, such as computer 2101. For example, in a hypothetical case where computer 2101 is designed and programmed to provide a recommendation based on historical data, then this historical data may be provided to computer 2101 from remote database 2130 of remote server 2104.

PUBLIC CLOUD 2105 is any computer system available for use by multiple entities that provides on-demand availability of computer system resources and/or other computer capabilities, especially data storage (cloud storage) and computing power, without direct active management by the scale. The direct and active management of the computing resources of public cloud 2105 is performed by the computer hardware and/or software of cloud orchestration module 2141. The computing resources provided by public cloud 2105 are typically implemented by virtual computing environments that run on various computers making up the computers of host physical machine set 2142, which is the universe of physical computers in and/or available to public cloud 2105. The virtual computing environments (VCEs) typically take the form of virtual machines from virtual machine set 2143 and/or containers from container set 2144. It is understood that these VCEs may be stored as images and may be transferred among and between the various physical machine hosts, either as images or after instantiation of the VCE. Cloud orchestration module 2141 manages the transfer and storage of images, deploys new instantiations of VCEs and manages active instantiations of VCE deployments. Gateway 2140 is the collection of computer software, hardware, and firmware that allows public cloud 2105 to communicate through WAN 2102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 2106 is similar to public cloud 2105, except that the computing resources are only available for use by a single enterprise. While private cloud 2106 is depicted as being in communication with WAN 2102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 2105 and private cloud 2106 are both part of a larger hybrid cloud.

### Additional Closing Information

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function. In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented at least partially in parallel with one or more other program modules. Generally, program modules include routines, programs, components and/or data structures that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), and/or microprocessor-based or programmable consumer and/or industrial electronics. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform” and/or “interface” can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random-access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A system, comprising:
a memory that stores computer executable components; and
a processor that executes the computer executable components stored in the memory, wherein the computer executable components comprise:
a quantum circuit generation component that generates a quantum circuit comprising a series of one or more instances of a quantum gate of interest, wherein the quantum circuit generation component further generates the quantum circuit having each instance of the quantum gate of interest being bounded by a pair of Pauli gates, and wherein each pair of Pauli gates comprises two of the same bounding Pauli gate;
a selection component that randomly selects, separately for each instance of the quantum gate of interest, the bounding Pauli gate to employ for each instance of the quantum gate of interest;
an insertion component that inserts, according to a determined probability, an initial Pauli gate, that is based on an initial quantum state of the quantum circuit, into the quantum circuit prior to the series of one or more instances of the quantum gate of interest; and
a finalization component that, based on one or more parameters of a curve, to which an expectation value, resulting from a measurement outcome of execution of the quantum circuit at a quantum system, is fitted, generates an element characterizing noise of the quantum gate of interest.

2. The system of claim 1, further comprising:
an execution component that executes the quantum circuit at a quantum processor of the quantum system, resulting in the measurement outcome.

3. The system of claim 1, wherein the quantum gate of interest is a 2-qubit, non-Clifford quantum gate.

4. The system of claim 1,
wherein the selection component randomly selects the bounding Pauli gate from a group of Pauli gates that commute with a rotation axis of the quantum gate of interest, and
wherein the insertion component inserts the initial Pauli gate according to a 50% probability.

5. The system of claim 1, further comprising:
a state preparation component that selects the initial quantum state based on a rotation axis A⊗B of the quantum gate of interest,
wherein the insertion component selects the initial Pauli gate (Pᵢ) from a set of Pauli gates where Pᵢ and Pⱼ∝(A⊗B)Pᵢ both anti-commute with the rotation axis A⊗B, and
wherein A, B∈{X, Y, Z}.

6. The system of claim 1, further comprising:
a readout twirling component that directs performance of readout twirling of the initial Pauli gate at the quantum system to result in output of the measurement outcome by the quantum system.

7. The system of claim 1, wherein the finalization component generates the element absent employment of an amplitude parameter of the curve, resulting in the element being non-biased by state preparation and measurement noise related to operation of the quantum gate of interest.

8. The system of claim 1, further comprising:
a primary iteration component that directs the quantum circuit generation component, selection component, insertion component and finalization component to perform their respective operations for one or more additional quantum circuits having a series of a same number of one or more instances of the quantum gate of interest as the quantum circuit.

9. The system of claim 8, further comprising:
a curve fitting component that fits the expectation value, and an additional one or more expectation values resulting from the additional quantum circuits, to the curve being a decaying sinusoid curve based on a selected curve-fitting process.

10. The system of claim 8, further comprising:
a secondary iteration component that directs the quantum circuit generation component, selection component, insertion component, finalization component and primary iteration component to perform their respective operations for one or more further quantum circuits each having a series of a second same number of one or more instances of the quantum gate of interest as the quantum circuit,
wherein the second same number is different than the same number; and
a state preparation component that selects a second initial quantum state, different from the initial quantum state, and, based on a rotation axis A⊗B of the quantum gate of interest,
wherein A, B∈{X, Y, Z}, and
wherein the state preparation component further directs the quantum circuit generation component, selection component, insertion component, finalization component, primary iteration component and secondary iteration component to perform their respective operations relative to the second initial quantum state.

11. A computer-implemented method, comprising:
generating, by a system comprising a processor, a quantum circuit comprising a series of one or more instances of a quantum gate of interest, and having each instance of the quantum gate of interest being bounded by a pair of Pauli gates, wherein each pair of Pauli gates comprises two of the same bounding Pauli gate;
randomly selecting, by the system, separately for each instance of the quantum gate of interest, the bounding Pauli gate to employ for each instance of the quantum gate of interest;
inserting, by the system, according to a determined probability, an initial Pauli gate, that is based on an initial quantum state of the quantum circuit, into the quantum circuit prior to the series of one or more instances of the quantum gate of interest; and
based on one or more parameters of a curve, to which an expectation value, resulting from a measurement outcome of execution of the quantum circuit at a quantum system, is fitted, generating, by the system, an element characterizing noise of the quantum gate of interest.

12. The computer-implemented method of claim 11, further comprising:
executing, by the system, the quantum circuit at a quantum processor of the quantum system; and
directing, by the system, performance of readout twirling of the initial Pauli gate at the quantum system to result in output of the measurement outcome by the quantum system.

13. The computer-implemented method of claim 11, further comprising:
randomly selecting, by the system, the bounding Pauli gate from a group of Pauli gates that commute with a rotation axis of the quantum gate of interest; and
inserting, by the system, the initial Pauli gate according to a 50% probability.

14. The computer-implemented method of claim 11, further comprising:
selecting, by the system, the initial quantum state based on a rotation axis A⊗B of the quantum gate of interest; and
selecting, by the system, the initial Pauli gate (Pᵢ) from a set of Pauli gates where Pᵢ and Pⱼ∝(A⊗B)Pᵢ both anti-commute with the rotation axis A⊗B,
wherein A, B∈{X, Y,Z}.

15. The computer-implemented method of claim 11, further comprising:
generating, by the system, the element absent employment of an amplitude parameter of the curve, resulting in the element being non-biased by state preparation and measurement noise related to operation of the quantum gate of interest.

16. A computer program product facilitating a process to characterize a noisy quantum gate, the computer program product comprising a computer readable storage medium having program instructions embodied therewith, the program instructions executable by a processor to cause the processor to:
generate, by the processor, a quantum circuit comprising a series of one or more instances of a quantum gate of interest, and having each instance of the quantum gate of interest being bounded by a pair of Pauli gates, wherein each pair of Pauli gates comprises two of the same bounding Pauli gate;
randomly select, by the processor, separately for each instance of the quantum gate of interest, the bounding Pauli gate to employ for each instance of the quantum gate of interest;
insert, by the processor, according to a determined probability, an initial Pauli gate, that is based on an initial quantum state of the quantum circuit, into the quantum circuit prior to the series of one or more instances of the quantum gate of interest; and
based on one or more parameters of a curve, to which an expectation value, resulting from a measurement outcome of execution of the quantum circuit at a quantum system, is fitted, generate, by the processor, an element characterizing noise of the quantum gate of interest.

17. The computer program product of claim 16, wherein the program instructions are further executable by the processor to cause the processor to:
execute, by the processor, the quantum circuit at a quantum processor of the quantum system; and
direct, by the processor, performance of readout twirling of the initial Pauli gate at the quantum system to result in output of the measurement outcome by the quantum system.

18. The computer program product of claim 16, wherein the program instructions are further executable by the processor to cause the processor to:
randomly select, by the processor, the bounding Pauli gate from a group of Pauli gates that commute with a rotation axis of the quantum gate of interest; and
insert, by the processor, the initial Pauli gate according to a 50% probability.

19. The computer program product of claim 16, wherein the program instructions are further executable by the processor to cause the processor to:
select, by the processor, the initial quantum state based on a rotation axis A⊗B of the quantum gate of interest; and
select, by the processor, the initial Pauli gate (Pᵢ) from a set of Pauli gates where Pᵢ and Pⱼ∝(A⊗B)Pᵢ both anti-commute with the rotation axis A⊗B,
wherein A, B∈{X, Y, Z}.

20. The computer program product of claim 16, wherein the program instructions are further executable by the processor to cause the processor to:
generate, by the processor, the element absent employment of an amplitude parameter of the curve, resulting in the element being non-biased by state preparation and measurement noise related to operation of the quantum gate of interest.
